(19) United States
(12) Patent Application Publication
(10) Pub. No.: US 2025/0204139 A1
(43) Pub. Date: Jun. 19, 2025

(54) DRYING AND CRYSTALLIZING PEROVSKITE LAYERS FROM SOLVENT COATED FILMS

(71) Applicant: Caelux Corporation, Baldwin Park, CA (US)

(72) Inventors: Ernest F. Hasselbrink, Jr., Monrovia, CA (US); Deepak Krishna Krishnan, Simi Valley, CA (US); Mason Lee Terry, San Dimas, CA (US)

(21) Appl. No.: 18/986,070

(22) Filed: Dec. 18, 2024

Related U.S. Application Data
(60) Provisional application No. 63/611,408, filed on Dec. 18, 2023.

(51) Int. Cl. H10K 30/40; B05B 17/06; B05C 5/02; B05C 11/06; C03C 17/42; C23C 14/08; C23C 14/58; H10K 30/57; H10K 71/10

(52) U.S. Cl. CPC H10K 30/40; B05B 17/06; B05C 5/0254; B05C 11/06; C03C 17/42; C23C 14/085; C23C 14/086; C23C 14/58; H10K 30/57; C03C 2217/94; C03C 2218/112; C03C 2218/117; C03C 2218/15; C03C 2218/33; C03C 2218/345; H10K 71/191

(57) ABSTRACT

Techniques for drying and crystallizing a film of crystalline material, such as a perovskite, from a solution are disclosed.

### CROSS-REFERENCE TO RELATED APPLICATION

This application claims the benefit of priority to Provisional Application No. 63/611,408, filed Dec. 18, 2023, the contents of which are hereby incorporated by reference.

### BACKGROUND

Photovoltaic (PV) devices and light-emitting devices utilizing perovskites are being actively explored by many researchers and by some commercial entities as potential replacements for those based on silicon, CdTe, and III-V compounds, such as GaAs. An advantage of perovskites are their relatively low material and processing costs of solution-based perovskite semiconductors compared to these alternatives.

In various examples, perovskite semiconducting materials are created via a process with a first step of depositing a thin film of a solution containing a precursor or precursors onto a large-format substrate, followed by a step in which the solvent is evaporated. This evaporation process increases the concentration of solute to a point that initiates nucleation, then crystal growth and ripening to form the perovskite. Additional solvent removal may be necessary as well, and/or annealing of the perovskite, to create desirable characteristics for use in devices.

### SUMMARY

This specification describes methods for drying and crystallizing a perovskite layer from a solvent coated film. The specification further describes drying modules that include one or more gas slots, with suction slots adjacent in some cases, to facilitate the drying and crystallization process. The perovskite layers formed using these methods can be used in perovskite solar modules, including tandem silicon-perovskite solar modules. More generally, the drying and crystallization techniques described herein, and the apparatus for implementing the techniques, can be used for forming non-perovskite crystalline films from solutions too.

When forming a layer of a perovskite by crystalizing the perovskite from a solution containing a precursor, each phase of the crystallization process (e.g., nucleation, ripening, annealing) may have different temperature-dependent kinetic rates, and therefore different preferred drying rates (e.g., times varying from tens of milliseconds to seconds) to achieve high-performance devices. This is because grain boundary orientation, composition of crystals and grain boundaries, morphology, and defects such as pinholes can all strongly affect device performance; and these factors are strongly affected by the kinetics of the crystallization process which are strongly affected by the time-dependent solvent and solute concentrations (including, e.g., the distribution of crystal nucleate sizes) and the temperature of the thin film, and the rate of diffusion of solvent through the thin film, amongst other variables. Reliable manufacture of high-quality perovskite films can benefit from precise control of both reaction kinetic rates and mass transfer rates, for the entire time from film deposition to the conclusion of annealing.

In examples, the techniques described in this specification are used for forming a perovskite layer in a tandem silicon-perovskite solar module having a bottom silicon solar cell and a top perovskite solar cell. The perovskite solar cell typically has a higher bandgap than the silicon solar cell so preferentially absorbs radiation at different wavelengths compared to the silicon solar cell. For example, the perovskite solar cell may have a bandgap of about 1.7 electron volts (“eV”) and the silicon solar cell may have a bandgap of about 1.1 eV. Accordingly, the perovskite solar cell can convert shorter wavelengths of light to electricity more efficiently than the silicon solar cell. Alternatively, or additionally, the perovskite solar cell may be transparent to longer wavelengths of light compared to the silicon solar cell, which may allow the underlying silicon solar cell to absorb and convert such longer wavelengths of light to electricity. Together, the perovskite solar cell and the silicon solar cell may be capable of efficiently converting a wider spectrum of light to electricity than a single solar cell (i.e., there may be less thermalization loss in a tandem cell than in a single cell solar module resulting in a higher full spectrum efficiency). The addition of perovskite solar cells can improve the resultant solar modules by decreasing cost, improving performance per weight of the module, improve overall performance of the module, and the like.

The silicon solar cell may be a monocrystalline or multi-crystalline silicon solar cell. The silicon solar cell may be a component of a conventional solar panel. The solar panel may have a back sheet on which the silicon solar cell is disposed. An encapsulant may cover the top of the silicon solar cell to prevent it from being exposed to dust and moisture. The solar panel may also have a top glass sheet that provides additional protection to the silicon solar cell.

The perovskite solar cell may be deposited on the bottom surface of the top glass sheet. This may differ from the construction of conventional tandem solar modules in which a perovskite cell is merely disposed on top of a silicon wafer. Depositing the perovskite solar cell on the bottom surface of the top glass sheet may allow manufacturers to incorporate perovskite solar cells into their conventional silicon solar panels with no re-tooling or process changes. Instead, such manufacturers can merely substitute a conventional glass sheet with the perovskite glass sheet. This disclosure may refer to the perovskite glass sheet as “active glass.”

The perovskite solar cell includes a first transparent conducting oxide (“TCO”) layer deposited on the top glass sheet, a hole transport layer (“HTL”) deposited on the first TCO layer, a perovskite layer deposited on the HTL, an electron transport layer (“ETL”) deposited on the perovskite layer, and a second TCO layer deposited on the ETL. The second TCO layer includes IZTO (e.g., the layer can be composed entirely of IZTO). The first and second TCO layers are electrical terminals for the perovskite solar cell. The ETL and HTL facilitate electron and hole transport, respectively, while inhibiting hole and electron transport, respectively. The perovskite layer absorbs light to generates charge carriers, which results in a voltage and current flow across the terminals of the perovskite solar cell.

In general, the techniques described here can be implemented in the manufacture of any perovskite solar cell, including those cells for single-junction solar modules (e.g., a perovskite-only solar module) and for dual junction solar modules (e.g., a perovskite junction with a silicon junction). In certain examples, the perovskite solar cell and the silicon solar cell are electrically isolated from each other, and each cell may have its own terminals. That is, the tandem solar module may be a 4-terminal module. The perovskite solar cell and the silicon solar cell can be connected in series or parallel by connecting the terminals in the appropriate manner. In the case of a series connection, the perovskite solar cell and the silicon solar cell may be current-matched. In the case of a parallel connection, the perovskite solar cell and the silicon solar cell may be voltage matched. In some examples, the dual junction solar module is a two terminal (2T) module.

In general, in a first aspect, the disclosure features a method for forming a layer of a perovskite material on a substrate, the method including: depositing a layer of a solution onto a surface of the substrate, the solution comprising a solvent and a perovskite precursor; after depositing the layer of solution, moving the substrate in a downstream direction relative to a gas slot; while causing relative movement between the substrate and the gas slot, blowing a curtain of gas towards the surface of the layer of the solution using the gas slot to provide conditions sufficient to facilitate mass transfer of the solvent from the layer of solution in a zone to crystallize a perovskite material from the perovskite precursor to form the layer of the perovskite downstream from the gas slot, wherein the gas slot is configured so that entrained or emitted gas flow upstream of the gas slot (at the undried upstream film) is at least twice as low (e.g., 3× or more lower, 4× or more lower, 5× or more lower, 10× or more lower, 20× or more lower) as entrained gas flow downstream from the gas slot.

In general, in another feature, the disclosure features a method for forming a layer of a crystalline material on a substrate, the method including: depositing a layer of a solution onto a surface of the substrate, the solution including a solvent and a precursor; after depositing the layer of solution, moving the substrate in a downstream direction relative to a gas slot; while causing relative movement between the substrate and the gas slot, blowing a curtain of gas towards the surface of the layer of the solution using the gas slot to provide conditions sufficient to facilitate mass transfer of the solvent from the layer of solution in a zone to crystallize the crystalline material from the precursor to form the layer of the crystalline material downstream from the gas slot, wherein the gas slot is configured so that entrained or emitted gas flow upstream of the gas slot (at the undried upstream film) is at least twice as low (e.g., 3× or more lower, 4× or more lower, 5× or more lower, 10× or more lower, 20× or more lower) as entrained gas flow downstream from the gas slot.

In general, in another feature, the disclosure features a method for forming a layer of a perovskite material on a substrate, the method including: depositing a layer of a solution onto a surface of the substrate, the solution including a solvent and a perovskite precursor; after depositing the layer of solution, moving the substrate in a downstream direction relative to a plurality of gas slots; while causing relative movement between the substrate and the gas slots, blowing curtains of gas towards the surface of the layer of the solution using the gas slots to provide conditions sufficient to facilitate mass transfer of the solvent from the layer of solution in a zone to crystallize a perovskite material from the perovskite precursor to form the layer of the perovskite downstream from the gas slot.

In general, in another feature, the disclosure features a method for forming a layer of a crystalline material on a substrate, the method including: depositing a layer of a solution onto a surface of the substrate, the solution including a solvent and a precursor; after depositing the layer of solution, moving the substrate in a downstream direction relative to a plurality of gas slots; while causing relative movement between the substrate and the gas slots, blowing curtains of gas towards the surface of the layer of the solution using the gas slots to provide conditions sufficient to facilitate mass transfer of the solvent from the layer of solution in a zone to crystallize the crystalline material from the precursor to form the layer of the crystalline material downstream from the gas slot.

In general, in another feature, the disclosure features a method for forming a layer of a perovskite material on a substrate, the method including: depositing a layer of a solution onto a surface of the substrate, the solution including a solvent and a perovskite precursor; after depositing the layer of solution, moving the substrate in a downstream direction relative to a gas slot and a suction channel adjacent the gas slot; while causing relative movement between the substrate and the gas slots, blowing a curtain of gas towards the surface of the layer of the solution using the gas slot and removing gas adjacent the surface to provide conditions sufficient to facilitate mass transfer of the solvent from the layer of solution in a zone to crystallize a perovskite material from the perovskite precursor to form the layer of the perovskite downstream from the gas slot.

In general, in another feature, the disclosure features a method for forming a layer of a crystalline material on a substrate, the method including: depositing a layer of a solution onto a surface of the substrate, the solution including a solvent and a precursor; after depositing the layer of solution, moving the substrate in a downstream direction relative to a gas slot and a suction channel adjacent the gas slot; while causing relative movement between the substrate and the gas slots, blowing a curtain of gas towards the surface of the layer of the solution using the gas slot and removing gas adjacent the surface to provide conditions sufficient to facilitate mass transfer of the solvent from the layer of solution in a zone to crystallize the crystalline material from the precursor to form the layer of the crystalline material downstream from the gas slot.

In general, in another feature, the disclosure features a system, including: a platen for supporting a substrate; a coating module for coating a layer of a solution including a precursor and a solvent onto the substrate; a drying module including a gas slot, the drying module being position relative to the platen to deliver a curtain of gas to the layer of the solution during operation of the system; and an electronic controller arranged to control relative motion between the gas slot and the platen during operation of the system to provide conditions sufficient to facilitate mass transfer of the solvent from the layer of solution in a zone to crystallize a material from the precursor to form a layer of crystalline material downstream from the gas slot, wherein the drying module is configured so that entrained gas flow upstream of the gas slot is lower than entrained gas flow downstream from the gas slot.

In general, in another feature, the disclosure features a system, including: a platen for supporting a substrate; a coating module for coating a layer of a solution including a precursor and a solvent onto the substrate; a drying module including a plurality of gas slots, the drying module being position relative to the platen to deliver a curtain of gas to the layer of the solution during operation of the system; and an electronic controller arranged to control relative motion between the gas slots and the platen during operation of the system to provide conditions sufficient to facilitate mass transfer of the solvent from the layer of solution in a zone to crystallize a material from the precursor to form a layer of crystalline material downstream from the gas slot.

In general, in another feature, the disclosure features a system, including: a platen for supporting a substrate; a coating module for coating a layer of a solution including a precursor and a solvent onto the substrate; a drying module including a gas slot and a suction channel adjacent the gas slot, the drying module being position relative to the platen to deliver a curtain of gas to the layer of the solution and remove gas from adjacent the surface of the layer during operation of the system; and an electronic controller arranged to control relative motion between the gas slot and the platen during operation of the system to provide conditions sufficient to facilitate mass transfer of the solvent from the layer of solution in a zone to crystallize a material from the precursor to form a layer of crystalline material downstream from the gas slot.

Additional aspects and advantages of the present disclosure will become readily apparent to those skilled in this art from the following detailed description, wherein only illustrative embodiments of the present disclosure are shown and described. As will be realized, the present disclosure is capable of other and different embodiments, and its several details are capable of modifications in various obvious respects, all without departing from the disclosure. Accordingly, the drawings and description are to be regarded as illustrative in nature, and not as restrictive.

### BRIEF DESCRIPTION OF THE DRAWINGS

FIG. 1 schematically illustrates an example tandem, 4-terminal, silicon-perovskite solar cell in cross-section;

FIG. 2 is a flow chart of a fabrication process for forming a perovskite photovoltaic;

FIG. 3 is a flowchart of operation 310 of FIG. 2;

FIG. 4 is a flowchart of operation 340 of FIG. 2;

FIG. 5A flow chart of operation 350 of FIG. 2;

FIG. 5B is a flow chart of operation 360 of FIG. 2;

FIG. 5C is a flow chart of a fabrication process for forming a perovskite layer;

FIG. 6 is a schematic diagram of an example system for coating and drying a solution containing perovskite precursors onto a substrate;

FIG. 7 is a schematic diagram of an example of a gas slot;

FIG. 8A is a schematic diagram of a portion of an example gas slot shown in cross-section;

FIG. 8B is a plot of the mass transfer coefficient as a function of substrate position for the example gas slot shown in FIG. 8A;

FIG. 9 is a schematic diagram illustrating 3D “fingers” that are undesirable variations in film thickness that can result from instabilities while drying a film;

FIG. 10A is a schematic diagram of a portion of another example gas slot shown in cross-section;

FIG. 10B is a plot of the mass transfer coefficient as a function of substrate position for the example gas slot shown in FIG. 10A;

FIG. 11A is a schematic diagram of a portion of another example gas slot shown in cross-section;

FIG. 11B is a plot of the mass transfer coefficient as a function of substrate position for the example gas slot shown in FIG. 11A;

FIG. 12A is a schematic diagram of a portion of another example gas slot shown in cross-section;

FIG. 12B is a plot of the mass transfer coefficient as a function of substrate position for the example gas slot shown in FIG. 12A;

FIG. 13A is a schematic diagram of a portion of a further example gas slot module shown in cross-section;

FIG. 13B is a plot of the mass transfer coefficient as a function of substrate position for the example gas slot module shown in FIG. 13A;

FIG. 14A is a schematic diagram of a portion of another example gas slot module shown in cross-section;

FIG. 14B is a plot of the mass transfer coefficient as a function of substrate position for the example gas slot module shown in FIG. 14A;

FIG. 15A is a schematic diagram of a portion of another example gas slot module shown in cross-section;

FIG. 15B is a schematic diagram of a portion of another example gas slot module shown in cross-section;

FIG. 15C is a schematic diagram of a portion of another example gas slot module shown in cross-section;

FIG. 16 is a schematic diagram of a portion of another example gas slot module shown in cross-section that includes optical monitoring;

FIG. 17 is a flow chart of an example process for manufacturing a tandem solar module;

FIGS. 18-21 show examples of different electrical network connections for different types of silicon-perovskite hybrid solar modules;

FIG. 22A is a schematic diagram of an example station for forming a perovskite layer including a slot die coater and a QUASAR;

FIG. 22B is a plot of the mass transfer coefficient as a function of substrate position for the example gas slot module shown in FIG. 22A;

FIGS. 23A-23B show examples of apparatuses for generating a perovskite layer including use of an antisolvent and without use of an antisolvent;

FIG. 24 shows an example computer system that is programmed or otherwise configured to implement methods provided herein; In the drawings, like symbols denote like elements.

### DETAILED DESCRIPTION

While various examples are shown and described herein, it will be obvious to those skilled in the art that they are examples only. Numerous variations, changes, and substitutions may occur to those skilled in the art without departing from the inventive subject matter. It should be understood that various alternatives to the examples described herein may be employed.

Whenever the term “at least,” “greater than,” or “greater than or equal to” precedes the first numerical value in a series of two or more numerical values, the term “at least,” “greater than” or “greater than or equal to” applies to each of the numerical values in that series of numerical values. For example, greater than or equal to 1, 2, or 3 is equivalent to greater than or equal to 1, greater than or equal to 2, or greater than or equal to 3.

Whenever the term “no more than,” “less than,” or “less than or equal to” precedes the first numerical value in a series of two or more numerical values, the term “no more than,” “less than,” or “less than or equal to” applies to each of the numerical values in that series of numerical values. For example, less than or equal to 3, 2, or 1 is equivalent to less than or equal to 3, less than or equal to 2, or less than or equal to 1.

A “gas slot” refers to a device to which pressurized gas is delivered to its inlets, and at its exit delivers a long thin jet of gas (e.g., the jet extends at least 10 times in the long direction than the thin direction). A gas slot can also be referred to as an “air knife” although the gas is not necessarily air despite the word “air” in its common name. The delivered gas (and the ambient environment into which it issues) may be composed of any gas, including but not limited to nitrogen, argon, oxygen, chemical vapors and mixtures thereof;

The term “solar cell,” as used herein, generally refers to a device that uses the photovoltaic effect to generate electricity from light.

The term “tandem,” as used herein, refers to a solar module with two solar cells that are stacked on top of one another.

The term “4-terminal,” as used herein, refers to a tandem solar module in which the top and bottom solar cells each have two accessible terminals.

The term “perovskite,” as used herein, generally refers to a material with a crystal structure similar to calcium titanium oxide and one that is suitable for use in perovskite solar cells. The general chemical forum for a perovskite material is ABX₃. Examples of perovskite materials include methylammonium lead trihalide (i.e., CH₃NH³PbX₃, where X is a halogen ion such as iodide, bromide, or chloride) and formamidinium lead trihalide (i.e., H₂NCHNH₂PbX₃, where X is a halogen ion such as iodide, bromide, or chloride).

The term “monocrystalline silicon,” as used herein, generally refers to silicon with a crystal structure that is homogenous throughout the material. The orientation, lattice parameters, and electronic properties of monocrystalline silicon may be constant throughout the material. Monocrystalline silicon may be doped with phosphorus or boron, for example, to make the silicon n-type or p-type respectively.

The term “polycrystalline silicon,” as used herein, generally refers to silicon with an irregular grain structure.

The terms “passivated emitter rear contact (PERC) solar cell,” as used herein, generally refer to a solar cell with an extra dielectric layer on the rear-side of the solar cell. This dielectric layer may act to reflect unabsorbed light back to the solar cell for a second absorption attempt and may additionally passivate the rear surface of the solar cell, increasing the solar cell's efficiency.

The terms “heterojunction with intrinsic thin layer solar cell (HIT) solar cell,” as used herein, generally refer to a solar cell that is composed of a monocrystalline silicon wafer surrounded by ultra-thin amorphous silicon layers. One amorphous silicon layer may be n-doped, while the other may be p-doped.

The terms “an interdigitated back contact cell (IBC),” as used herein, generally refer to a solar cell including two or more electrical contacts disposed on the back side of the solar cell (e.g., on the side opposite the incident light). The two or more electrical contacts can be disposed adjacent to alternatingly n- and p-doped regions of the solar cell. An IBC may include a high-quality absorber material configured to permit carrier migration over a long distance.

The terms “bandgap” and “band gap,” as used herein, generally refer to the energy difference between the top of the valence band and the bottom of the conduction band in a material.

The term “electron transport layer” (“ETL”), as used herein, generally refers to a layer of material that facilitates electron transport and inhibits hole transport in a solar cell. Electrons may be majority carriers in an ETL, while holes may be minority carriers. An ETL may be made of one or more n-type layers. The one or more n-type layers may include an n-type exciton blocking layer. The n-type exciton blocking layer may have a wider band gap than the photoactive layer of the solar cell (e.g., the perovskite layer) but a conduction band that is closely matched to the conduction band of the photoactive layer. This may allow electrons to easily pass from the photoactive layer to the ETL.

The n-type layer may be a metal oxide, a metal sulfide, a metal selenide, a metal telluride, amorphous silicon, an n-type group IV semiconductor (e.g., germanium), an n-type group III-V semiconductor (e.g., gallium arsenide), an n-type group II-VI semiconductor (e.g., cadmium selenide), an n-type group I-VII semiconductor (e.g., cuprous chloride), an n-type group IV-VI semiconductor (e.g., lead selenide), an n-type group V-VI semiconductor (e.g., bismuth telluride), or an n-type group II-V semiconductor (e.g., cadmium arsenide), any of which may be doped (e.g., with phosphorus, arsenic, or antimony) or undoped. The metal oxide may be an oxide of titanium, tin, zinc, niobium, tantalum, tungsten, indium, gallium, neodymium, palladium, cadmium, or an oxide of a mixture of two or more of such metals. The metal sulfide may be a sulfide of cadmium, tin, copper, zinc or a sulfide of a mixture of two or more of such metals. The metal selenide may be a selenide of cadmium, zinc, indium, gallium or a selenide of a mixture of two or more of such metals. The metal telluride may be a telluride of cadmium, zinc, cadmium or tin, or a telluride of a mixture of two or more of said metals. Other n-type materials may alternatively be employed, including organic and polymeric electron transporting materials, and electrolytes. Suitable examples include, but are not limited to, a fullerene or a fullerene derivative (e.g., phenyl-C61-butyric acid methyl ester, C60, etc.) or an organic electron transporting material including perylene or a derivative thereof.

The term “hole transport layer” (“HTL”), as used herein, generally refers to a layer of material that facilitates hole transport and inhibits electron transport in a solar cell. Holes may be majority carriers in an HTL, while electronics may be minority carriers. An HTL may be made of one or more p-type layers. The one or more p-type layers may include a p-type exciton blocking layer. The p-type exciton blocking layer may have a valence band that is closely matched to the valence band of the photoactive layer (e.g., the perovskite layer) of the solar cell. This may allow holes to easily pass from the photoactive layer to the HTL.

The p-type layer may be made of a molecular hole transporter, a polymeric hole transporter, or a copolymer hole transporter. For example, the p-type layer may be one or more of the following: nickel oxide, thiophenyl, phenelenyl, dithiazolyl, benzothiazolyl, diketopyrrolopyrrolyl, ethoxydithiophenyl, amino, triphenyl amino, carbozolyl, ethylene dioxythiophenyl, dioxythiophenyl, or fluorenyl. Additionally or alternatively, the p-type may include spiro-OMeTAD (2,2′,7,7′-tetrakis-(N,N-di-p-methoxyphenylamine)-9,9′-spirobifluorene)), P3HT (poly(3-hexylthiophene)), PCPDTBT (Poly[2,1,3-benzothiadiazole-4,7-diyl[4,4-bis(2-ethylhexyl)-4H-cyclopenta[2,1-b: 3,4-b′]dithiophene-2,6-diyl]]), PVK (poly(N-vinylcarbazole)), poly(3-hexylthiophene), poly[N,N-diphenyl-4-methoxyphenylamine-4′,4″-diyl], sexithiophene, 9,10-bis(phenylethynyl) anthracene, 5,12-bis(phenylethynyl) naphthacene, diindenoperylene, 9,10-diphenylanthracene, PEDOT-TMA, PEDOT:PSS, perfluoropentacene, perylene, poly(p-phenylene oxide), poly(p-phenylene sulfide), quinacridone, rubrene, 4-(dimethylamino)benzaldehyde diphenylhydrazone, 4-(dibenzylamino)benzaldehyde-N,Ndiphenylhydrazone or phthalocyanines.

The methods and systems for forming a perovskite layer described in this specification can be used to form any type of solar module that includes a perovskite layer, including tandem solar cells. For example, the tandem solar module can be a tandem CdTe-perovskite solar module. In another example, the tandem solar module can be a dye sensitized solar cell-perovskite solar cell module.

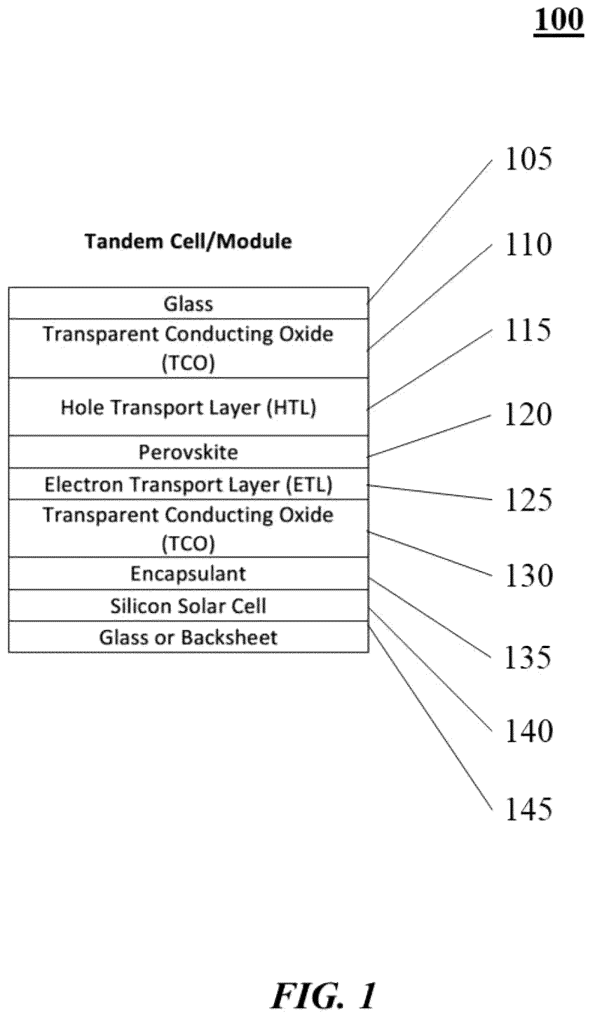

Referring to FIG. 1, an example of a tandem, 4-terminal, silicon-perovskite solar module 100 includes a top glass sheet 105, a first TCO layer 110, an HTL 115, a perovskite layer 120, an ETL 125, a second TCO layer 130, an encapsulant 135, a silicon solar cell 140, and a back sheet 145.

The top glass sheet 105 protects underlying layers of the solar module 100 from dust and moisture. The top glass sheet 105, and the solar module 100 as a whole, may have a form factor that corresponds to a conventional silicon solar panel. For example, the top glass sheet 105 may have a form factor that corresponds to a 32-cell, 36-cell, 48-cell, 60-cell, 72-cell, 96-cell, or 144-cell silicon solar panel. The top glass sheet 105 may have a thickness of at least about 2.0 millimeters (mm), 2.5 mm, 3.0 mm, 3.5 mm, 4.0 mm, 4.5 mm, 5.0 mm, or more. The top glass sheet 105 may have a thickness of at most about 5.0 mm, 4.5 mm, 4.0 mm, 3.5 mm, 3.0 mm, 2.5 mm, 2.0 mm, or less. The top glass sheet 105 may be transparent so as to allow light to access the underlying solar cells. In some cases, the top surface of the top glass sheet 105 may be covered with polydimethylsiloxane (“PDMS”) (e.g., 1:10 alumina PDMS, textured 1:50 alumina PDMS, or textured PDMS), which may improve light trapping and refractive index matching. In some cases, the top surface of the top glass sheet 105 may be covered with an anti-reflective coating. In some cases, the bottom surface of the top glass sheet 105 may be textured in order to enable more light scattering back into the perovskite layer 120.

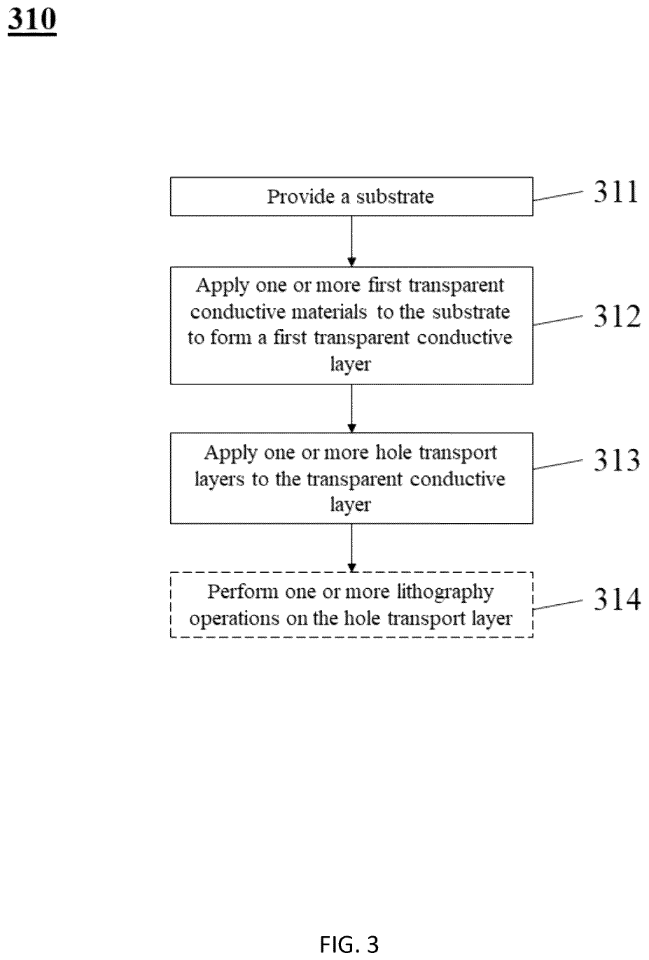

Together, the first TCO layer 110, the HTL 115, the perovskite layer 120, the ETL 125, and the second TCO layer 130 form a perovskite solar cell. The perovskite solar cell may be disposed on the bottom surface of the top glass sheet 105 through fabrication methods that are described in reference to FIG. 3 through FIG. 5B. The perovskite solar cell may have a higher bandgap than the silicon solar cell 140. For example, the perovskite solar cell may have a bandgap of about 1.30, 1.31, 1.32, 1.33, 1.34, 1.35, 1.36, 1.37, 1.38, 1.39, 1.40, 1.41, 1.42, 1.43, 1.44, 1.45, 1.46, 1.47, 1.48, 1.49, 1.50, 1.51, 1.52, 1.53, 1.54, 1.55, 1.56, 1.57, 1.58, 1.59, 1.60, 1.61, 1.62, 1.63, 1.64, 1.65, 1.66, 1.67, 1.68, 1.69, 1.70, 1.71, 1.72, 1.73, 1.74, 1.75, 1.76, 1.77, 1.78, 1.79, 1.80, 1.81, 1.82, 1.83, 1.84, 1.85, 1.86, 1.87, 1.88, 1.89, 1.90, 1.91, 1.92, 1.93, 1.94, 1.95, 1.96, 1.97, 1.98, 1.99, 2.00, 2.01, 2.02, 2.03, 2.04, 2.05, 2.06, 2.07, 2.08, 2.09, 2.10, or greater electron volts (“eV”). In contrast, the silicon solar cell may have a bandgap of about 1.1 eV. Accordingly, the perovskite solar cell may be capable of efficiently converting shorter wavelengths of light to electricity. The perovskite solar cell may be transparent to longer wavelengths of light, which may allow the underlying silicon solar cell to absorb and convert such longer wavelengths of light to electricity. Together, the perovskite solar cell and the silicon solar cell may be capable of efficiently converting a wider spectrum of light to electricity than a single solar cell.

In some examples, the first TCO layer 110 is disposed directly on the top glass sheet 105. Depositing the first TCO layer 110 directly on the top glass sheet 105 may prevent damage to the HTL 115 and the perovskite layer 120. The first TCO layer 110 may serve as the positive terminal or cathode of the perovskite solar cell. The first TCO layer 110 may have a thickness of at least about 100 nanometers (nm), 200 nm, 300 nm, 400 nm, 500 nm, 600 nm, 700 nm, 800 nm, 900 nm, 1 micrometer, or more. The first TCO layer 110 may have a thickness of at most about 1 micrometer, 900 nm, 800 nm, 700 nm, 600 nm, 500 nm, 400 nm, 300 nm, 200 nm, 100 nm, or less. The first TCO layer 110 may be made of indium tin oxide (ITO). The first TCO layer 110 may be made of doped ITO. The TCO layer may have a resistance of at least about 1, 2, 3, 4, 5, 6, 7, 8, 9, 10, 11, 12, 13, 14, 15, 16, 17, 18, 19, 20, 21, 22, 23, 24, 25, or more Ohm/square meter. The TCO layer may have a resistance of at most about 25, 24, 23, 22, 21, 20, 19, 18, 17, 16, 15, 14, 13, 12, 11, 10, 9, 8, 7, 6, 5, 4, 3, 2, 1, or less Ohm/square meter.

The HTL 115 is disposed on the TCO layer 110. The HTL 115 facilitates the transport of holes from the perovskite layer 120 to the first TCO layer 110. In certain examples, the HTL layer facilitates hole transport without significantly compromising transparency and conductivity. In contrast, in certain cases, the HTL 115 may inhibit electron transport. In some examples, the HTL 115 is made of one or more nickel oxide layers. In certain examples, the HTL 115 is made of another appropriate p-type material described in this disclosure. The HTL 115 may have a thickness of about 5 nm or more (e.g., 10 nm or more, 20 nm or more, 50 nm or more, 100 nm or more, 200 nm or more, 300 nm or more, 400 nm or more, 500 nm or more, 600 nm or more, 700 nm or more, 800 nm or more, 900 nm or more, 1 micrometer or more). The HTL 115 may have a thickness of about 1 micrometer or less (e.g., 900 nm or less, 800 nm or less, 700 nm or less, 600 nm or less, 500 nm or less, 400 nm or less, 300 nm or less, 200 nm or less, 100 nm or less).

The perovskite layer 120 is disposed on the HTL 115. The perovskite layer 120 is the photoactive layer of the perovskite solar cell. That is, the perovskite layer 120 absorbs light in a certain wavelength range and generate holes and electrons that subsequently diffuse into the HTL 115 and the ETL 125, respectively. In some examples, the perovskite layer 120 is made of methylammonium lead triiodide, methylammonium lead tribromide, methylammonium lead trichloride, or any combination thereof. In other embodiments, the perovskite layer 120 is made of formamidinium lead triiodide, formamidinium lead tribromide, formamidinium lead trichloride, or any combination thereof. In certain examples, the perovskite layer 120 is made of cesium lead triiodide, cesium lead tribromide, cesium lead trichloride, or any combination thereof. The perovskite layer may be a triple cation perovskite material with formamidinium, methylammonium, and cesium cations in different ratios. Incorporating cesium into the perovskite lattice provides enhanced thermodynamic stability. The bandgap of the perovskite layer 120 may be varied by adjusting the halide content of the methylammonium lead trihalide or formamidinium lead trihalide. The perovskite layer 120 may have a thickness of about 250 nm or more (e.g., 300 nm or more, 400 nm or more, 500 nm or more, 600 nm or more, 700 nm or more, 800 nm or more, 900 nm or more, 1 micrometer or more, 1.25 micrometers or more, 1.5 micrometers or more, 1.75 micrometers or more, 2 micrometers, or more). The perovskite layer 120 may have a thickness of about 4 micrometers or less (e.g., 3 microns or less, 2 microns or less, 1.75 micrometers or less, 1.5 micrometers or less, 1.25 micrometers or less, 1 micrometer or less, 900 nm or less, 800 nm or less, 700 nm or less, 600 nm or less, 500 nm or less).

The ETL 125 is disposed on the perovskite layer 120. The ETL 125 facilitates the transport of electrons from the perovskite layer 120 to the second TCO layer 130 and can do so without significantly compromising transparency and conductivity. In contrast, in certain examples, the ETL 115 may inhibit electron transport. In some cases, the ETL 125 is made of phenyl-C61-butyric acid methyl ester (“PCBM”). In certain examples, the ETL 125 is made of another appropriate n-type material described in this disclosure (e.g., C60). The ETL 115 may have a thickness of about 10 nm or more (e.g., 20 nm or more, 30 nm or more, 40 nm or more, 50 nm or more, 60 nm or more, 70 nm or more, 80 nm or more, 90 nm or more, 100 nm or more, 200 nm or more, 300 nm or more, 400 nm or more, 500 nm or more). The ETL 115 may have a thickness of about 800 nm or less (e.g., 700 nm or less, 600 nm or less, 500 nm or less, 400 nm or less, 300 nm or less, 200 nm or less, 100 nm or less, 90 nm or less, 80 nm or less, 70 nm, 60 nm or less, 50 nm or less, 40 nm or less, 30 nm or less, 20 nm or less). The interface between the ETL and the perovskite layer can be important to the performance of the perovskite layer. The surface of the perovskite layer can be hydrophilic to enable good coverage of a hydrophilic ETL (e.g., PCBM). The combination of environment (e.g., low humidity, e.g., <15%, low temperature, e.g., from 18 to 24 degrees Celsius) and solvent compatibility may impact the quality of the perovskite layer-ETL connection.

The second TCO layer 130 is disposed on the ETL 125. The second TCO layer 130 serves as the negative terminal or anode of the perovskite solar cell. The second TCO layer 130 may have a thickness of about 100 nm or more (e.g., 200 nm or more, 300 nm or more, 400 nm or more, 500 nm or more, 600 nm or more, 700 nm or more, 800 nm or more, 900 nm or more, 1 micrometer or more). In some examples, the second TCO layer 130 has a thickness of about 1 micrometer or less (e.g., 900 nm or less, 800 nm or less, 700 nm or less, 600 nm or less, 500 nm or less, 400 nm or less, 300 nm or less, 200 nm or less, 100 nm or less).

In some examples, the second TCO layer 110 can include indium zinc-tin oxide (IZTO), e.g., amorphous IZTO (a-IZTO). For example, the second TCO layer 110 can be composed entirely of IZTO. IZTO can have high light transmission at certain wavelengths, e.g., compared to ITO. For example, an IZTO TCO layer can have transmission at 700 nm or 80% or more (e.g., 82% or more, 85% or more, 88% or more, 90% or more, 92% or more, 95% or more, 96% or more, 97% or more, 98% or more, e.g., 99% or less) for normally incident light. The IZTO TCO layer can have transmission at 800 nm or 80% or more (e.g., 82% or more, 85% or more, 88% or more, 90% or more, 92% or more, 95% or more, 96% or more, 97% or more, 98% or more, e.g., 99% or less) for normally incident light. IZTO TCO layer can have transmission at 900 nm or 80% or more (e.g., 82% or more, 85% or more, 88% or more, 90% or more, 92% or more, 95% or more, 96% or more, 97% or more, 98% or more, e.g., 99% or less) for normally incident light.

The IZTO TCO layer can have such light transmission properties while having relative low sheet resistivity. For example, an IZTO TCO layer can have a transmission at 700 nm or 80% or more (e.g., 82% or more, 85% or more, 88% or more, 90% or more, 92% or more, 95% or more, 96% or more, 97% or more, 98% or more, e.g., 99% or less) for normally incident light and the second electrically conducting layer has a mean resistivity of 35 Ohm/sq. or less (e.g., 34 Ohm/sq. or less, 32 Ohm/sq. or less, 30 Ohm/sq. or less, 28 Ohm/sq. or less, 26 Ohm/sq. or less, 24 Ohm/sq. or less, e.g., 20 Ohm/sq. or more, 22 Ohm/sq. or more, 24 Ohm/sq. or more, 25 Ohm/sq. or more).

As described further below, IZTO layers can be deposited at lower temperatures that other TCO materials, such as ITO. ITO films are typically deposited onto heated substrates (e.g., to a temperature >200 degrees Celsius, with 300° C.-350° C. being common). Moreover, after deposition, annealing is used to improve conductivity and optical properties (e.g., transmission). Anneal temperatures can be 300° C.-350° C. Many perovskite materials are susceptible to elevated temperatures, e.g., they can degrade at temperatures of 100° C. or more (e.g., 120° C. or more). In contrast, IZTO can exhibit good film properties (e.g., low sheet resistance and/or high light transmission transmission) when deposited at temperatures of 120° C. or less (e.g., 100° C. or less, 80° C. or less, 60° C. or less, 50° C. or less, 40° C. or less, 30° C. or less, such as at room temperature).

IZTO is typically an amorphous structure as-deposited. In contrast, ITO is often a crystalline structure with vertical grain boundaries. These vertical grain boundaries may provide an easier pathway for water to diffuse through which can affect the perovskite negatively (e.g., H₂O leads to degradation of the perovskite structure). Amorphous IZTO does not have grain boundaries, hence can exhibit higher resistance to H₂O diffusion compared to crystalline TCO's, such as ITO.

The encapsulant 135 is disposed between the second TCO layer 130 of the perovskite solar cell and the silicon solar cell 140. The encapsulant 135 may reduce exposure of the perovskite solar cell and the silicon solar cell 140 to dust and moisture. The encapsulant 135 may electrically isolate the perovskite solar cell from the silicon solar cell 140. The encapsulant 135 may have a high refractive index (e.g., a refractive index greater than 1.4) that matches the refractive index of the TCO layer 130 of the perovskite solar cell and the top silicon nitride or TCO layer of the silicon solar cell 140. Thus, use of a high refractive index material may decrease transmission losses between the TCO layer 130, encapsulant 135, and silicon solar cell 140, resulting in improved current density of the solar module 100. The user of a high refractive index material may also improve light trapping. The high refractive index material may be ethylene-vinyl-acetate (“EVA”), thermal plastic polyolefin (“TPO”), PDMS, silicone, paraffin, or the like. The encapsulant may be the TCO layer. For example, the TCO layer may cover the perovskite layer such that the TCO layer protects the perovskite layer from external conditions (e.g., water, oxygen, etc.). In this example, the reliability of the integrated tandem module can be improved through use of the TCO layer as the encapsulant. The encapsulant may include ethylene-vinyl-acetate (“EVA”), thermal plastic polyolefin (“TPO”), PDMS, silicone, paraffin, or the like. The encapsulation layer may isolate both the perovskite solar cell and the silicon solar cell from the surrounding environment. For example, the encapsulant may encapsulate both the perovskite layer and the silicon layer simultaneously. The encapsulant layer may be configured to prevent volatilization of one or more components of the perovskite layer. For example, the encapsulant can minimize loss of organic cations (e.g., methylammonium, formamidinium, etc.) due to heating of the perovskite layer. In another example, the encapsulant can reduce the egress of chemical species from the perovskite layer such as lead iodide or other lead halides, the egress of which can result in degraded reliability of the integrated tandem module. The encapsulant may be treated to have sufficient cross linking to protect the perovskite layer from water, oxygen, volatilization of the organic compounds of the perovskite layer, or the like, or any combination thereof. The encapsulant may have a cross linked percentage of at least about 50, 60, 70, 80, 90, 95, or more percent. The encapsulant may have a cross linked percentage of at most about 95, 90, 80, 70, 60, 50, or less percent.

In general, the silicon solar cell 140 may be a p-type silicon solar cell with a p-type substrate covered by a thin n-type layer (“emitter”), or it may be an n-type silicon solar cell with an n-type substrate covered by a thin p-type emitter. The silicon solar cell 140 may be a monocrystalline silicon solar cell, a polycrystalline silicon solar cell, a PERC silicon solar cell, a HIT silicon solar cell, an interdigitated back contact cell (IBC), or the like.

The silicon solar cell 140 may have a back sheet 145. The back sheet 145 may seal the solar module 100 to prevent moisture ingress. In some cases, the back sheet 145 may be a glass sheet with a top surface and a bottom surface. The top surface of the glass sheet may have a highly reflective coating or textured surface in to further increase light trapping or scattering back in the silicon solar cell 140 and the perovskite layer 120. The glass sheet may be transparent. The glass sheet may be substantially transparent. The transparency of the glass sheet may facilitate bifacial operation of the solar cell. For example, the solar cell can be configured to absorb light from both sides of the solar cell.

The perovskite solar cell and the silicon solar cell 140 may be electrically isolated from each other, and each cell may have its own terminals. That is, the tandem solar module may be a 4-terminal module. The perovskite solar cell and the silicon solar cell 140 may be connected in series or parallel by connecting the terminals in the appropriate manner. In the case of a series connection, the perovskite solar cell and the silicon solar cell may be current-matched. In the case of a parallel connection, the perovskite solar cell and the silicon solar cell may be voltage matched. Laser scribing can be used to achieve the current matching or voltage matching, e.g., by connecting individually scribed perovskite solar cells in series or parallel to achieve a desired voltage or current. Parallel or series connection between the perovskite solar cells and the silicon solar cell can be made via busbars/electrodes before module lamination. This allows rapid and easy introduction into any existing silicon manufacturing process.

The solar module 100 may have a power conversion efficiency of 25% or more (e.g., 26% or more, 27% or more, 28% or more, 29% or more, 30% or more, such as 33% or less, 32% or less, 31% or less).

### Solar Module Fabrication

The first TCO layer 110 and the second TCO layer 130 may serve as electrical contacts for the perovskite solar cell while maintaining the semi-transparency of the perovskite solar cell so that the underlying silicon solar cell 140 can still absorb light. A physical vapor deposition (PVD) process may be used to fabricate the first TCO layer 110 and the second TCO layer 130. The PVD process may be tuned such that the resulting TCO layer is transparent to light (e.g., light with a wavelength from 300 nanometers (“nm”) to 1200 nm for the second TCO layer). For example, a plasma pressure and deposition power of the PVD process may be tuned accordingly. For example, the argon pressure can be at about 1 to about 5 millitorr, and the deposition power can be about 20 watts to about 1,000 watts. Additionally, the thickness of the first TCO layer 110 and the second TCO layers 130 can be set to achieve such transparency. Such transparency may allow the underlying silicon solar cell 140 to receive as much light as possible at wavelengths at which it is absorbed that was not already absorbed by the perovskite layer 120, which typically absorbs light with a wavelength from 300 nm to 700 nm.

In fabricating the second TCO layer 130, the PVD process may tend to create defects in the ETL 125 and the perovskite layer 120 due the ultraviolet light and argon/oxygen ions generated by the plasma during the process. Such defects may degrade the performance of the perovskite layer 120 as an electron-hole pair absorber. For example, the perovskite layer 120 may exhibit a lower open circuit voltage and a lower fill factor as the result of such defects. It may be beneficial to minimize the creation of such defects.

In some examples, the damage described above can be reduced (e.g., minimized) by first creating a buffer layer of IZTO on the ETL 125 through a low-power PVD process. The power during the low-power plasma PVD process may be at most about 0.60 Watts per square centimeter (“W/cm2”) or less (e.g., 0.55 W/cm2 or less, 0.50 W/cm2 or less, 0.45 W/cm2 or less, 0.40 W/cm2 or less, 0.35 W/cm2 or less, 0.30 W/cm2 or less, 0.25 W/cm2 or less, 0.20 W/cm2 or less, 0.15 W/cm2 or less, 0.10 W/cm2 or less, 0.05 W/cm2 or less) s per square centimeter (“W/cm2”). Depending on the size of the panel, the low-power PVD process can be at a total power of about 10 Watts or more (e.g., 20 Watts or more, 30 Watts or more, 40 Watts or more, 50 Watts or more, 60 Watts or more, 70 Watts or more, 80 Watts or more, 90 Watts or more, 100 Watts or more, 110 Watts or more, 120 Watts or more, 130 Watts or more, 140 Watts or more, 150 Watts or more). The total power can be about 200 Watts or less (e.g., 180 Watts or less, 160 Watts or less, 150 Watts or less, 140 Watts or less, 130 Watts or less, 120 Watts or less, 110 Watts or less, 100 Watts or less, 90 Watts or less, 80 Watts or less, 70 Watts or less, 60 Watts or less, 50 Watts or less).

The buffer layer may be at least about 5 or more nm (e.g., 10 or more nm, 15 or more nm, 20 or more nm, 25 or more nm, 30 or more nm, 35 or more nm, 40 or more nm, 45 or more nm, 50 or more nm, 55 or more nm, 60 or more nm, 65 or more nm, 70 or more nm, 75 or more nm, 80 or more nm, 85 or more nm, 90 or more nm, 95 or more nm, 100 or more nm) thick. The buffer layer may be at most about 100 or fewer nm (e.g., 95 or fewer nm, 90 or fewer nm, 85 or fewer nm, 80 or fewer nm, 75 or fewer nm, 70 or fewer nm, 65 or fewer nm, 60 or fewer nm, 55 or fewer nm, 50 or fewer nm, 45 or fewer nm, 40 or fewer nm, 35 or fewer nm, 30 or fewer nm, 25 or fewer nm, 20 or fewer nm, 15 or fewer nm, 10 or fewer nm, 5 or fewer nm) thick. The ultraviolet damage is often generated by high power ions that penetrate deep into the bulk of the ETL 125 and the perovskite layer 120, breaking or damaging molecular bonds and causing degradation in both the open circuit voltage and series resistance. The use of a low-power PVD to create the buffer layer may block (at least partially) high energy ions in subsequent process steps from reaching the ETL 125 and the perovskite layer 125.

A bulk layer of TCO may be deposited on the buffer layer of TCO at a deposition energy of at most 1.00, 0.95, 0.90, 0.85, 0.80, 0.75, 0.70, 0.65, 0.60, 0.55, 0.50, 0.45, or less W/cm2.

In some cases, an ultrathin layer of silver may be deposited at the interface between the ETL 125 and the TCO layer through an evaporation, sputtering, or atomic layer deposition. The ultrathin layer of silver may be at most about 20, 19, 18, 17, 16, 15, 14, 13, 12, 11, 10, 9, 8, 7, 6, 5, 4, 3, 2, or 1 angstroms thick. The ultrathin layer of silver may act as a barrier against ultraviolet light or plasma during PVD of the IZTO layer. In some cases, a post-anneal may be performed on the second TCO layer to partially repair some of the damage caused by the ultraviolet light or plasma during the PVD process. The post-anneal may be performed at 100-140 degrees Celsius for 2 to 4 minutes.

A bulk layer of TCO may be deposited on the buffer layer of TCO at a deposition energy of at most 0.90 W/cm2, 0.85, 0.80, 0.75, 0.70, 0.65, 0.60, 0.55, 0.50, 0.45, or less W/cm2.

Conventionally, the physical vapor deposition process described above can be performed in a chamber that has a shutter disposed between the sputtering source and the target substrate. The shutter may quickly actuate (i.e., open and close) in order to shield the target substrate from the sputtering source for short periods of time. The abrupt nature of the shutter may result in the sensitive perovskite and transport layers being damaged by ion impacts and exposure to UV radiation. Additionally, the entire target substrate is subjected to the whole sequence of TCO deposition, which may be minutes long to achieve a thickness on the order of 300-900 nm to meet sheet resistance and transmission targets. As such, the physical vapor deposition process may intrinsically cause larger than expected ion and UV damage to the target substrate, which may result in defects and recombination sites in the layers of the target substrate, degrading its electrical performance as an electron-hole pair absorber layer.

To address the shortcomings of conventional physical vapor deposition processes, the TCO layers 110 and 130 may instead be fabricated in an inline manufacturing process. The inline manufacturing process may be performed in multiple process chambers where deposition of selected target materials occurs. A conveyor belt can transport the target substrate between the multiple process chambers. The inline manufacturing process may provide for the deposition of TCO layers while maintaining low resistivity, good transmission, and uniform thickness of the perovskite solar cell. The inline manufacturing process can be a vertical or horizontal process.

The inline manufacturing process may reduce the defects formed in the ETL 125 and the perovskite layer 120 due the ultraviolet light and argon/oxygen ions generated by the plasma during the TCO physical vapor deposition process. Utilization of a moving conveyor belt in the multiple process chambers may reduce the defects formed in the ETL 125 and the perovskite layer 120. The multiple chamber system may minimize the amount of time the target substrate is exposed to plasma deposition. The target substrate may only be exposed to deposition in certain chambers. For example, the target substrate may not be exposed to deposition in a buffer chamber, whereas the target substrate is exposed to deposition in process chambers where the first and second TCO layers are fabricated. In some embodiments, a target substrate containing the top glass sheet 105, the first TCO layer 110, the HTL 115, the perovskite layer 120, and the ETL 125 is loaded onto the conveyor belt of the inline PVD manufacturing tool. The conveyor transports the target substrate into a target chamber, with the ETL layer 125 facing the TCO source for TCO deposition. Depending on the desired thickness and composition of the second TCO layer and the throughput of the TCO source, there may be one or multiple target substrates inside the chamber at a time or multiple chambers with a single target substrate. Each chamber may be separated by gates to minimize cross-contamination and to minimize damage due to plasma exposure. In some cases, the target substrate passes through a first deposition chamber for deposition of a buffer layer of ITO. Then the substrate passes through a buffer chamber, and finally through a second deposition chamber for deposition of a bulk layer of ITO. The buffer chamber may prevent cross-contamination between the first deposition chamber and the second deposition chamber if, for example, the composition or deposition parameters of the two ITO layers are different.

To further reduce direct exposure to deposition, a moving target substrate on the conveyor belt ensures that each portion of the target substrate is only subject to direct exposure to deposition until that portion of the target substrate moves past the deposition area. The amount of time each portion of the target substrate is exposed to direct deposition depends on the speed of the conveyor belt. The speed of the conveyor belt can be adjusted to minimize the amount of time each portion of the substrate is subjected to direct exposure while still ensuring each layer is sufficiently deposited on the target substrate. The moving conveyor belt provides a more gradual deposition profile on the target substrate, in contrast to the more abrupt profile generated by a conventional shutter.

The multiple chambers may also include shields, or other blocking obstacles, between chambers to ensure ions and UV exposure in other chambers are blocked when the target substrate enters a chamber with no deposition. The multiple chambers may also include shields around the deposition area to block ions and UV radiation from areas of the substrate that are not directly exposed to the deposition. Further, the multiple chamber system allows for TCO layer deposition at uniform thickness and at much lower plasma power without compromising deposition duration.

The inline manufacturing process can also implement the techniques mentioned above (e.g., optimizing process parameters like gas flow/pressure, deposition power, thickness and materials, use of a buffer layer, lowering deposition energy, use of an ultrathin layer of silver, and use of an annealing process) when fabricating the second TCO layer to further reduce the defects formed in the ETL 125 and the perovskite layer 120. The process limits the number of defects both at the interface between the second TCO layer 130 and the ETL 125, and in the bulk of the ETL 125 and the perovskite layer 120. Other examples of process parameters may include, but are not limited to, chemical formation parameters (e.g., solvent composition, presence or absence of additives, one-operation formulations, two-operation formulations, etc.), ultrasonic spray on process parameters (e.g., spray volume, spray speed, ultrasonic power, lateral speed of the substrate, nozzle height, nozzle width, nozzle angle, environmental factors, humidity, atmospheric composition, temperature, etc.), post application treatment parameters (e.g., dry duration, rinse duration, exterior environmental parameters, solvent chemistry, anneal time, anneal temperature, etc.), transport layer application parameters (e.g., application type, surface conditions, layer thickness, layer conformality, etc.), or the like, or any combination thereof.

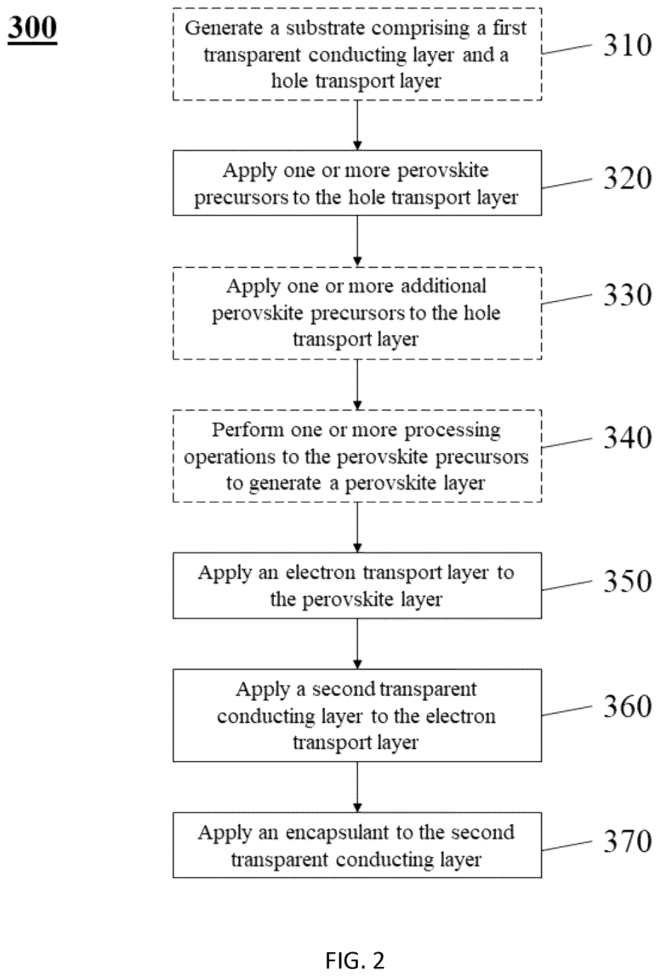

FIG. 2 is a flow chart of a fabrication process 300 for forming a perovskite photovoltaic. The process 300 may optionally include generating a substrate including a first transparent conducting layer and a hole transport layer (310). In some cases, a pre-formed substrate may instead be provided.

The fabrication process 300 includes applying one or more perovskite precursors to the hole transport layer (320). The applying can be performed by chemical vapor deposition (CVD), plasma enhanced CVD, atomic layer deposition, spin coating, dip coating, doctor blading, drop casting, centrifugal casting, chemical solution deposition, sol-gel deposition, plating, physical vapor deposition, thermal evaporation, molecular beam epitaxy, sputtering, pulsed laser deposition, cathodic arc deposition, ultrasonic spray-on, inkjet printing, or the like, or any combination thereof. The applying can include the application of a single perovskite precursor at a time. For example, a first perovskite precursor can be evaporated onto the hole transport layer, and subsequently a second perovskite precursor can be sprayed onto the first precursor. The applying may include applying a plurality of precursors at one time. For example, an inkjet printer can apply a solution including a plurality of precursors. The process 300 may optionally include applying one or more additional perovskite precursors to the hole transport layer (330). The additional perovskite layers may be applied in the same way as in operation 320. For example, a first precursor can be deposited by physical vapor deposition, and subsequently a second precursor can be deposited by physical vapor deposition. Alternatively, the additional perovskite layer may be applied in a different way from operation 320. For example, a first perovskite precursor can be deposited by physical vapor deposition while a second perovskite precursor can be deposited by ultrasonic spray. Operation 330 may be repeated a plurality of times. For example, a plurality of additional perovskite precursors can be applied to the hole transport layer in a plurality of operations.

The ultrasonic spray-on application may include the use of a plurality of spray nozzles. The ultrasonic spray-on process may include the use of a single spray nozzle. For example, the single spray nozzle can be configured to raster across the application area to provide coverage of the area. A plurality of different types of spray nozzles may be tested for formation of a predetermined uniformity and/or thickness of the film deposited by the spray nozzle, and an optimal spray nozzle may be selected from the plurality of different types of spray nozzles. Once an optimal spray nozzle is selected, a plurality of that type of nozzle may be used in the ultrasonic spray-on application. The plurality of nozzles may form a bank of nozzles configured to spray over a large area to improve throughput and efficiency. The bank of nozzles may be a strip of nozzles (e.g., a line of nozzles across a single dimension), a two-dimensional arrangement of nozzles (e.g., nozzles distributed over a rectangular shape), a three-dimensional arrangement of nozzles (e.g., a plurality of nozzles distributed in three dimensions). The spray nozzles may be adjusted to dispense at an angle. The angle may be at least about 1, 2, 3, 4, 5, 6, 7, 8, 9, 10, 11, 12, 13, 14, 15, 20, 25, 30, 35, 40, 45, 50, 55, 60, 65, 70, 75, 80, 85, 90, or more degrees off of a parallel line from the substrate. The angle may be at most about 90, 85, 80, 75, 70, 65, 60, 55, 50, 45, 40, 35, 30, 25, 20, 15, 14, 13, 12, 11, 10, 9, 8, 7, 6, 5, 4, 3, 2, 1, or less degrees off of a parallel line from the substrate. The angle may be configured to reduce or eliminate the precursor missing the substrate and fouling other components of the manufacturing process. Use of an ultrasonic spray-on application can enable a roll to roll inline fabrication process. In the roll to roll inline fabrication process, a series of nozzle banks can each sequentially add different layers to a substrate, the substrate can be processed (e.g., annealed, laser scribed, etc.), and a finished photovoltaic cell can be generated on a single line. Using a roll to roll process can result in significant improvements in cost and speed of production as compared to step by step manufacture processes.

The one or more perovskite precursors can include one or more lead halides (e.g., lead fluoride, lead chloride, lead bromide, lead iodide, etc.), lead salts (e.g., lead acetates, lead oxides, etc.), other metal salts (e.g., manganese halides, tin halides, metal oxides, metal halides, etc.), organohalides (e.g., formamidinium chloride, formamidinium bromide, formamidinium iodide, methylammonium chloride, methylammonium bromide, methylammonium iodide, butylammonium halides, etc.), alkali metal salts (e.g., alkali metal halides, etc.), alkali earth metal salts (e.g., alkali earth metal halides, etc.), perovskite nanoparticles, or the like, or any combination thereof. A plurality of perovskite precursors can be used as the one or more perovskite precursors. For example, both methylammonium iodide and butylammonium iodide can be used as perovskite precursors. In this example, the methylammonium iodide can be at about a 1:99, 10:90, 20:80, 30:70, 40:60, 50:50, 60:40, 70:30, 80:20, 10:90, or 99:1 ratio with the butylammonium iodide. In another example, mixtures of lead halides can be used as a portion of the perovskite precursors. Using different mixtures of lead halides may permit tuning of the bandgap of the perovskite layer. For example, using different mixtures of lead (II) bromide and lead (II) iodide can result in different bandgaps. Using different amounts of lead (II) chloride can affect the crystal stability of the perovskite layer and can prevent phase segregation within the layer. The amount of lead (II) chloride added may be greater than the amount of lead (II) bromide added by weight. The amount of lead (II) chloride added may be less than the amount of lead (II) bromide added by weight. The amount of lead (II) chloride added may be the same as the amount of lead (II) bromide added by weight. The amount of lead (II) iodide soluble in a solution may be related to the amount of lead (II) bromide and lead (II) chloride in the solution. For example, adding in more lead (II) bromide and lead (II) chloride to a solution of lead (II) iodide can improve solubility of the lead (II) iodide and result in decreased particulate in the perovskite layer.

The one or more perovskite precursors may be one or more perovskite precursor solutions. For example, a lead (II) iodide solution in a solution of dimethyl sulfoxide can be a perovskite precursor. A perovskite precursor may be in a solution of at least about 0.1, 0.5, 1, 2, 3, 4, 5, 6, 7, 8, 9, 10, 11, 12, 13, 14, 15, 20, 25, 30, 35, 40, 45, 50, 55, 60, 65, 70, 75, 80, 85, 90, 95, 99, or more weight percent perovskite precursor. A perovskite precursor may be in a solution of at most about 99, 95, 90, 85, 80, 75, 70, 65, 60, 55, 50, 45, 40, 35, 30, 25, 20, 15, 14, 13, 12, 11, 10, 9, 8, 7, 6, 5, 4, 3, 2, 1, 0.5, 0.1, or less weight percent perovskite precursor. In some examples, the concentration of precursor in the solution is in a range from 20 wt. % to 80 wt. % (e.g., 30 wt. % to 60 wt. %, 40 wt. % to 50 wt. %). The solution may include one or more solvents. Examples of solvents include, but are not limited to, polar solvents (e.g., water, dimethyl sulfoxide, dimethylformamide, ethers, esters, acetates, acetone, etc.), non-polar solvents (e.g., hexanes, toluene, etc.), or the like, or any combination thereof. Proper mixing of the solvent as well as solvent composition can contribute to controlled solvent removal speeds and thus impact grain development as well as bulk defect formation. Tuning the interaction of the coordination strength of a solvent and the evaporation rate of a precursor solution can enable better control of the perovskite film that is formed as well as the reaction kinetics of the formation. For example, a weakly coordinating solvent that quickly evaporations may form a more disordered film but may also result in less residual solvent being present in the film. Mixtures of solvents can improve solute solubility, decrease evaporation rates, improve performance of application methods, and the like. For example, a combination of NMP and DMSO can increase solute solubility and decrease solvent evaporation rates. In this example, the properties of the NMO/DMSO mixture can decrease premature crystallization of perovskite and improve film quality. In another example, adding NMP to DMF can increase spray width of the solution through an ultrasonic spray on apparatus, which can provide greater flexibility in the spray on parameters used.

The one or more perovskite precursors can include one or more additives. The addition of the one or more additives may be configured to reduce and/or eliminate defects within perovskite layers as prepared elsewhere herein. The one or more additives may include one or more recrystallization solvents. The one or more recrystallization solvents may be added to a solution including the one or more perovskite precursors. The one or more recrystallization solvents may be applied after deposition of the one or more perovskite precursors and/or after an annealing of the one or more perovskite precursors. For example, a lead halide precursor can be applied and subsequently a recrystallization solvent can be applied, and the perovskite precursors can be further annealed to orient the lead halide precursor for better methylammonium iodide integration. Examples of recrystallization solvents include, but are not limited to, halobenzenes (e.g., chlorobenzene, bromobenzene, etc.), haloforms (e.g., chloroform, iodoform, etc.), ethers (e.g., diethyl ether), or the like, or any combination thereof.

A variety of parameters may be tuned to provide a predetermined perovskite layer. Examples of parameters include, but are not limited to, perovskite precursor solution application temperature, volume application rate, ultrasonic power of an ultrasonic spray-on instrument, lateral speed of precursor application (e.g., the speed of a substrate moving through an applicator), applicator height (e.g., the distance from an applicator to the substrate, environmental factors (e.g., humidity, reactive gas content, temperature, etc.), wetting surface energy, or the like, or any combination thereof. Any portion of process 300, including the application of the perovskite precursors, may take place in a controlled environment. The controlled environment may have a relative humidity of at least about 10%, 20%, 30%, 40%, 50%, 60%, 70%, 80%, 90%, 99%, or more. The controlled environment may have a relative humidity of at most about 99%, 90%, 80%, 70%, 60%, 50%, 40%, 30%, 20%, 10%, or less. The controlled environment may include a controlled atmosphere. The controlled atmosphere may include inert gasses (e.g., nitrogen, noble gases, etc.). The controlled atmosphere may have an oxygen content of at least about 1 part per million (ppm), 10 ppm, 50 ppm, 100 ppm, 500 ppm, 1,000 ppm, 5,000, ppm, 1%, 5%, 10%, 15%, 20%, or more. The controlled atmosphere may have an oxygen content of at most about 20%, 15%, 10%, 5%, 1%, 5,000 ppm, 1,000 μm, 500 ppm, 100 ppm, 50 ppm, 10 ppm, 1 ppm, or less. The controlled atmosphere may be at a temperature of at least about 15, 20, 25, 30, 35, 40, 45, 50, 55, 60, 65, 70, 75, 80, 85, 90, 95, 100, 105, 110, 115, 120, 125, 130, 135, 140, 145, 150, 160, 170, 180, 190, 200, or more degrees Celsius. The controlled atmosphere may be at a temperature of at most about 200, 190, 180, 170, 160, 150, 145, 140, 135, 130, 125, 120, 115, 110, 105, 100, 95, 90, 85, 80, 75, 70, 65, 60, 55, 50, 45, 40, 35, 30, 25, 20, 15, or less degrees Celsius.

FIG. 3 is a flowchart of operation 310. Operation 310 includes providing a substrate (311), e.g., a transparent substrate. The substrate may include a silicon-based glass (e.g., an amorphous silicon dioxide, a doped silicon dioxide, etc.), a transparent conductive oxide, a ceramic, a chalcogenide glass, a polymer (e.g., a transparent plastic, poly(methyl methacrylate, etc.), or the like, or any combination thereof. The substrate may include a top surface of a solar module. For example, the substrate may be a top glass of a silicon solar panel assembly. The substrate may be textured and/or patterned. For example, the substrate may include nano-scale texturing configured as an antireflective coating and an adhesion surface. In another example, the substrate may include patterning configured to generate photonic channels. In another example, the substrate may include pre-patterned portions with electrodes for removing energy from the solar cell (e.g., a top contact grid layout). The substrate may have an area of at least about 0.1, 0.5, 1, 2, 3, 4, 5, 6, 7, 8, 9, 10, 11, 12, 13, 14, 15, 20, 25, or more square meters. The substrate may have an area of at most about 25, 20, 15, 14, 13, 12, 11, 10, 9, 8, 7, 6, 5, 4, 3, 2, 1, 0.5, 0.1, or fewer square meters. The substrate may be a large format substrate. For example, the substrate can be a 10th generation substrate.

Operation 310 may include applying one or more first transparent conductive materials to the substrate to form a first transparent conductive layer (312). The first transparent conducting layer may include a transparent conductive oxide (e.g., indium tin oxide (ITO), indium zinc oxide, aluminum zinc oxide, indium cadmium oxide, etc.), a transparent conductive polymer (e.g., poly(3,4-ethylenedioxythiophene) (PEDOT), poly(3,4-ethylenedioxythiophene):poly(styrene sulfonate) (PEDOT:PSS), poly(4,4-dioctyl cyclopentadithiophene), etc.), carbon nanotubes, graphene, nanowires (e.g., silver nanowires), metallic grids (e.g., grid contacts including metals), thin films (e.g., thin metal films), conductive grain boundaries, or the like, or any combination thereof. The transparent conducting layer may have a full spectrum transparency of at least about 20%, 30%, 40%, 50%, 60%, 70%, 75%, 80%, 85%, 90%, 95%, 96%, 97%, 98%, 99%, 99.9%, or more. The transparent conducting layer may have a full spectrum transparency of at most about 99.9%, 99%, 98%, 97%, 96%, 95%, 90%, 85%, 80%, 75%, 70%, 60%, 50%, 40%, 30%, 20%, or less. The transparent conducting layer may have a full spectrum transparency in a range as defined by any two of the proceeding values. For example, the transparent conducting layer can have a full spectrum transparency of 75% to 85%. The transparent conducting layer may have a transparency over a spectral band of at least about 20%, 30%, 40%, 50%, 60%, 70%, 75%, 80%, 85%, 90%, 95%, 96%, 97%, 98%, 99%, 99.9%, or more. The transparent conducting layer may have a transparency over a spectral band of at most about 99.9%, 99%, 98%, 97%, 96%, 95%, 90%, 85%, 80%, 75%, 70%, 60%, 50%, 40%, 30%, 20%, or less. For example, the transparent conducting layer can have a transmission of 85% over the wavelength range from 400 nm to 1200 nm. The transparent conducting layer can function as a barrier to the perovskite layer for moisture, gas, dust, and the like. The transparent conducting layer can also prevent the diffusion of ions (e.g., metal ions) which may impact the performance of the perovskite layer. Methods for forming transparent conductive oxide layers are described elsewhere herein. For example, the transparent conducting oxide layers may be formed using the PVD and/or inline manufacturing processes described herein.

Operation 310 may include applying one or more hole transport layers to the transparent conductive layer (313). The one or more hole transport layers may be configured to shuttle holes from an absorbing layer to the transparent conductive layer and out of the solar module. The one or more hole transport layers may include organic molecules (e.g., 2,2′,7,7′-Tetrakis[N,N-di(4-methoxyphenyl)amino]-9,9′-spirobifluorene (Spiro-OMeTAD)), inorganic oxides (e.g., nickel oxide (NiOₓ), copper oxide (CuOₓ), cobalt oxide (CoOₓ), chromium oxide (CrOₓ), vanadium oxide (VOₓ), tungsten oxide (WOₓ), molybdenum oxide (Mo Oₓ), copper aluminum oxide (CuAlO₂), copper chromium oxide (CuCrO₂), copper gallium oxide (CuGaO₂), etc.), inorganic chalcogenides (e.g., copper iodide (CuI), copper indium sulfide (CuInS₂), copper zinc tin sulfide (CuZnSnS₄), cupper barium tin sulfide (CuBaSnS₄), etc.) other inorganic materials (e.g., copper thiocyanate (CuSCN), etc.), organic polymers, or the like, or any combination thereof. For example, a glass substrate covered in indium tin oxide can be coated with nickel oxide to form a hole transport layer on the transparent conducting layer.

In some examples, operation 310 includes performing one or more lithography operations on the hole transport layer (314). The one or more lithography operations may include optical lithography (e.g., (e.g., extreme) ultraviolet lithography, x-ray lithography, laser scribing, etc.), electron beam lithography, ion beam lithography, nanoimprint lithography, other direct writing processes (e.g., dip-pen lithography, inkjet printing), or the like, or any combination thereof. For example, a plurality of features can be inscribed onto the hole transport layer using a laser scribe. The one or more lithography operations may include the addition and/or subtraction of features. For example, features can be cured and made permanent. In another example, features can be formed by the removal of material from the target.

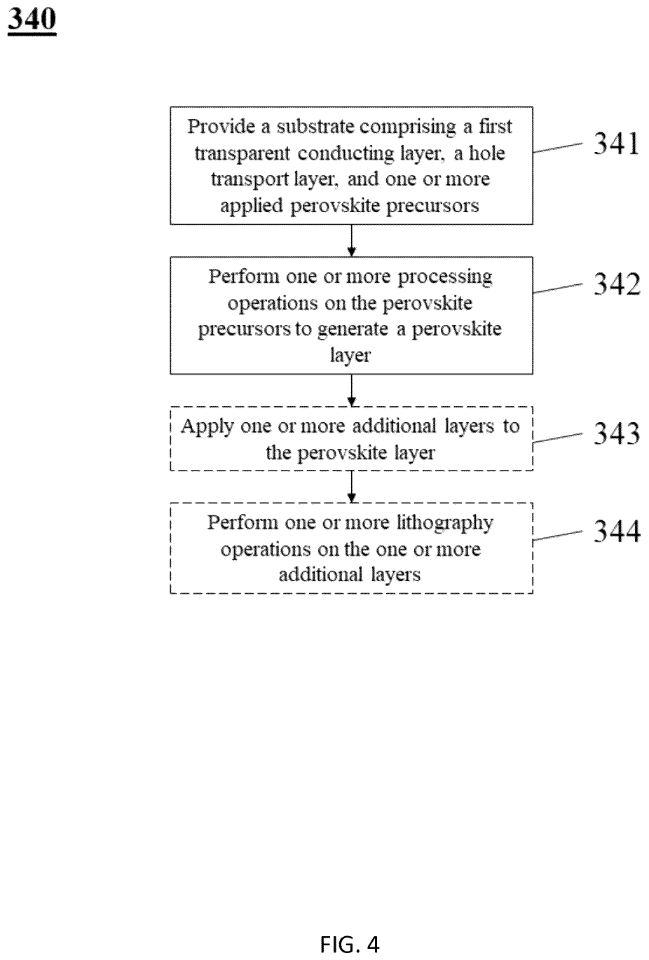

The process 300 includes performing one or more processing operations to the perovskite precursors to generate a perovskite layer (340). FIG. 4 is a flowchart of operation 340 of FIG. 2. Operation 340 may include providing a substrate including a first transparent conducting layer, a hole transport layer, and one or more applied perovskite precursors (341). The substrate may be a result of operations 310-330 of process 300.

Operation 340 includes performing one or more processing operations on the perovskite precursors to generate a perovskite layer (342). The one or more processing operations may include annealing, light exposure (e.g., ultraviolet light exposure), agitation (e.g., vibration), functionalization (e.g., surface functionalization), electroplating, template inversion, or the like, or any combination thereof. For example, a substrate with perovskite precursors can be annealed to form a perovskite layer from the precursors. In another example, perovskite precursors can be annealed and subsequently functionalized. The annealing may be annealing under inert atmosphere (e.g., argon atmosphere, nitrogen atmosphere). The annealing may be under a reactive atmosphere (e.g., an atmosphere including a reagent (e.g., methylammonium)). The annealing may be at a temperature of at least about 15, 20, 25, 30, 35, 40, 45, 50, 55, 60, 65, 70, 75, 80, 85, 90, 95, 100, 105, 110, 115, 120, 125, 130, 135, 140, 145, 150, 160, 170, 180, 190, 200, or more degrees Celsius. The annealing may be at a temperature of at most about 200, 190, 180, 170, 160, 150, 145, 140, 135, 130, 125, 120, 115, 110, 105, 100, 95, 90, 85, 80, 75, 70, 65, 60, 55, 50, 45, 40, 35, 30, 25, 20, 15, or less degrees Celsius. The annealing may be at a temperature range as defined by any two of the proceeding values. For example, the annealing can be at a temperature of 90 to 120 degrees Celsius. The annealing may be for a time of at least about 0.5, 1, 2, 3, 4, 5, 6, 7, 8, 9, 10, 11, 12, 13, 14, 15, 20, 25, 30, 35, 40, 45, 50, 55, 60, 75, 90, 105, 120, or more minutes. The annealing may be for a time of at most about 120, 105, 75, 60, 55, 50, 45, 40, 35, 30, 25, 20, 15, 14, 13, 12, 11, 10, 9, 8, 7, 6, 5, 4, 3, 2, 1, 0.5, or less minutes. The annealing may be for a time range as defined by any two of the proceeding values. For example, the annealing can be for a time of about 5 to about 15 minutes. There may be a plurality of annealing processes applied to the substrate. For example, a substrate can be annealed at a first time and temperature, and subsequently annealed again at a second time and temperature. Such additional annealing processes can reduce the number of defects present in the perovskite layer and improve performance.

Operation 340 can include applying one or more additional layers to the perovskite layer (343). The one or more additional layers may include one or more additional perovskite layers. For example, a second perovskite layer with a different bandgap can be applied to the first perovskite layer. The one or more additional layers may include one or more additional perovskite precursors. For example, iodine gas can be applied to form an iodine layer on a perovskite and/or perovskite precursor layer. The one or more additional layers may include one or more washing operations. A washing operation may include an application of a solvent to the perovskite layer. Examples of solvents include, but are not limited to, water, non-polar organic solvents (e.g., hexanes, toluene, etc.), polar organic solvents (e.g., methanol, ethanol, isopropanol, acetone, etc.), ionic solvents, or the like. The one or more additional layers may include one or more passivating layers. A passivating layer may include a reagent configured to passivate and/or stabilize the perovskite layer. For example, an application of a solution including phenethylammonium iodide can passivate and stabilize the grains of the perovskite layer.

Operation 340 can include performing one or more lithography operations on the one or more additional layers and/or the perovskite layer (344). The one or more lithography operations may be one or more lithography operations as described elsewhere herein. For example, a laser scribe can be used to generate features on a perovskite layer.

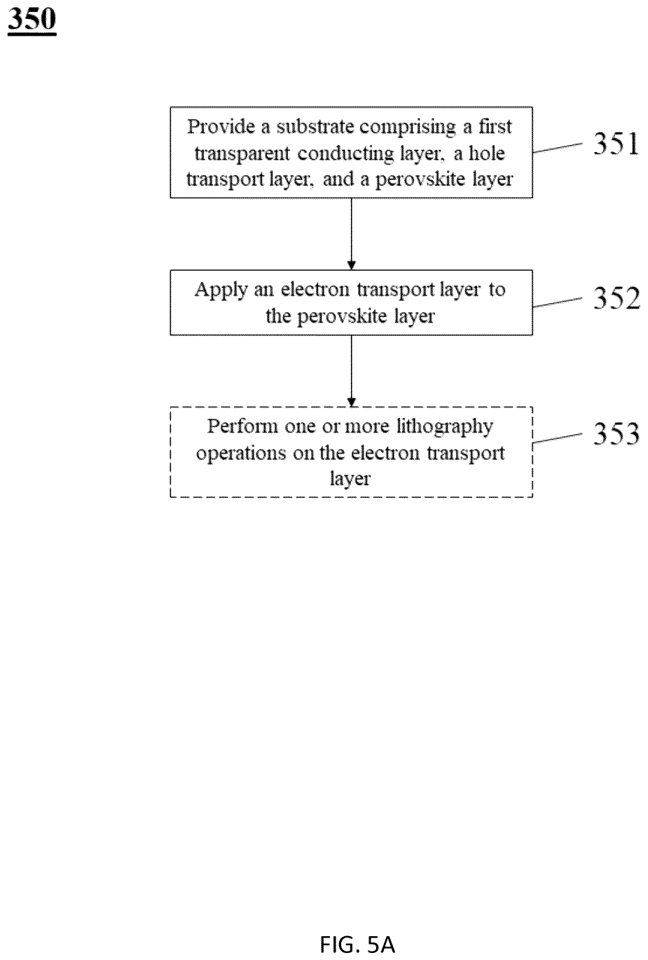

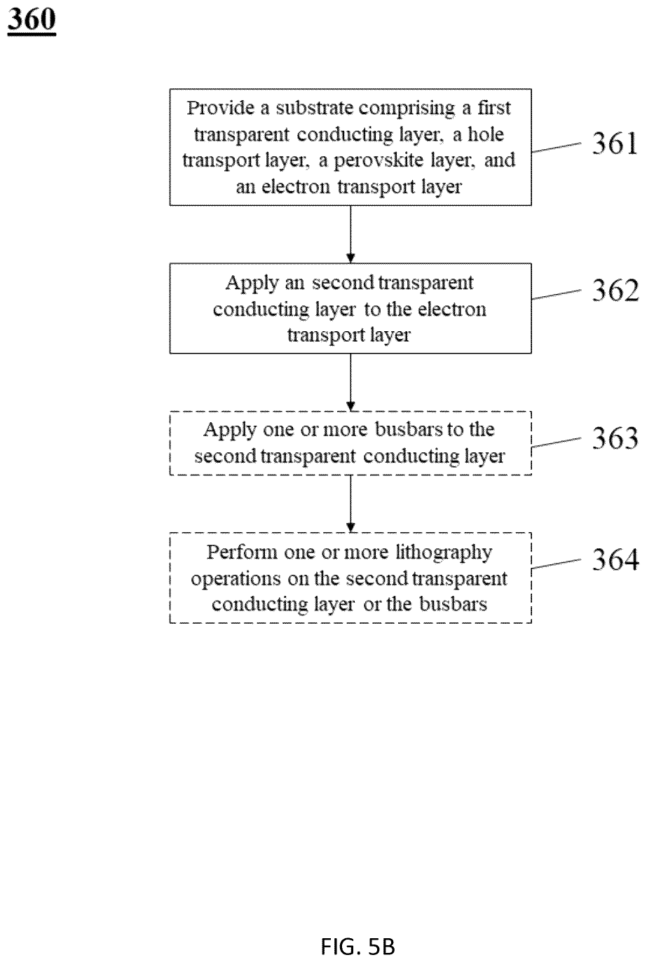

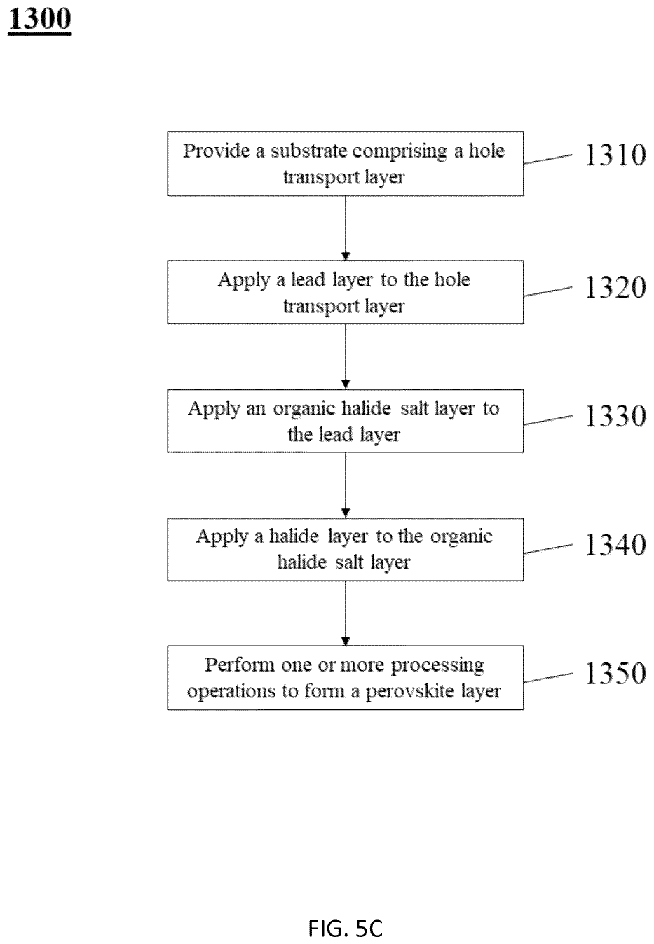

Returning to FIG. 2, the process 300 can include applying an electron transport layer to the perovskite layer (350). FIG. 5A is a flow chart of operation 350 of FIG. 2. Operation 350 may include providing a substrate including a first transparent conducting layer, a hole transport layer, and a perovskite layer (351). The substrate may be a substrate generated by operations 310-340 of FIG. 2.

Operation 350 can include applying an electron transport layer to the perovskite layer (352). The electron transport layer may be applied by methods and systems as described elsewhere herein (e.g., physical vapor deposition, ultrasonic spray-on, etc.). The electron transport layer may include a material with a conduction band minimum less than that of the perovskite layer. For example, if the perovskite layer has a conduction band minimum of −3.9 eV, the electron transport layer may have a conduction band minimum of −4 eV. Examples of electron transport layer materials include, but are not limited to titanium oxide (e.g., TiO₂), zinc oxide, tin oxide, tungsten oxide, indium oxide, niobium oxide, iron oxide, cerium oxide, strontium titanium oxide, zinc tin oxide, barium tin oxide, cadmium selenide, indium sulfide, lead iodide, organic molecules (e.g., phenyl-C61-butyric acid methyl ester (PCBM), poly(3-hexylthiophene-2,5-diyl) (P3HT), etc.), lithium fluoride, buckminsterfullerene (C60), or the like, or any combination thereof. Operation 350 may optionally include performing one or more lithography operations on the electron transport layer (353). The one or more lithography operations may be one or more lithography operations as described elsewhere herein. For example, a laser scribe can be used to generate features on the electron transport layer.

Returning to FIG. 2, the process 300 includes applying a second transparent conducting layer to the electron transport layer (360). FIG. 5B is a flow chart of operation 360 of FIG. 2. Operation 360 can include providing a substrate including a first transparent conducting layer, a hole transport layer, a perovskite layer, and an electron transport layer (371). The substrate may be a substrate generated by operations 310-350 of FIG. 2.

Operation 360 can include applying a second transparent conducting layer to the electron transport layer (362). The second transparent conducting layer may be of the same type as the first transparent conducting layer. For example, both the first and second transparent conducting layers may be indium tin oxide. The second transparent conducting layer may be of a different type as the first transparent conducting layer. The second transparent conducting layer may be deposited as described elsewhere herein (e.g., physical vapor deposition, etc.).

Operation 360 can include applying one or more busbars to the second transparent conducting layer (363). The one or more busbars may be applied as busbars (e.g., preformed busbars are applied to the second transparent conducting layer). For example, a mask can be used to form the busbars from an evaporation process. The one or more busbars may be applied as a solid film and subsequently formed into the busbars. For example, a silver film can be deposited onto the second transparent conductive layer and etched to form the busbars. In another example, a laser scribe can be used to form the busbars from a silver film. Operation 360 may optionally include performing one or more lithography operations on the electron transport layer (364). The one or more lithography operations may be one or more lithography operations as described elsewhere herein. For example, a laser scribe can be used to generate features on the second transparent conducting layer. The busbars may be attached to at least about 2, 3, 4, or more terminals. The busbars may be attached to at most about 4, 3, 2, or less terminals. The terminals may be configured to form a parallel connection with one or more additional photovoltaic modules. The terminals may be configured to form a series connection with one or more additional photovoltaic modules. The terminals may be scribed (e.g., laser scribed). The terminals may be configured to enable connection of a perovskite photovoltaic device with another photovoltaic device prior to a lamination of the two photovoltaic devices. For example, a perovskite photovoltaic device can be connection via two terminals to a silicon photovoltaic device.

Returning to FIG. 2, the process 300 can include applying an encapsulant to the second transparent conducting layer (370). The encapsulant may be configured to reduce or substantially eliminate an exposure of the perovskite layer to one or more reactive species. Examples of reactive species include, but are not limited to, oxygen, water, and polar molecules (e.g., polar volatile organic compounds, acids, etc.). The encapsulant may be substantially transparent. For example, the encapsulant may be transparent in a same region of light as the transparent conducting layer. Examples of encapsulants include, but are not limited to, polymers (e.g., buytl rubber, poly(methyl methacrylate), polycarbonate, polyethylene, polystyrene, thermoplastic olefins, polypropylene, etc.), waxes (e.g., paraffin wax), metals (e.g., iron, copper), semiconductors (e.g., wide bandgap semiconductors (e.g., zinc oxide, titanium oxide)), or the like, or any combination thereof.

The encapsulant may be applied across the second transparent conducting layer (e.g., applied to the whole layer), to a portion of the second transparent conducting layer (e.g., a portion of the layer), to the edges of the second transparent conducting layer (e.g., as a seal over the entire stack of layers), or the like, or any combination thereof. For example, the encapsulant can be applied on the edge of the full stack of layers to prevent moisture and oxygen diffusion into the stack. The encapsulant may be applied to the first conductive layer as well as the second conductive layer. For example, the substrate can include an encapsulant between the substrate and the first conducting layer. Example 3 below describes the use of PDMS as an encapsulant. Other examples of encapsulants include, but are not limited to, HelioSeal™, silicon glue, butyl-based sealants, or the like. For edge encapsulation, the encapsulant may include tape. The tape may be an adhesive backed barrier. The encapsulant may be placed such that the encapsulant ends at least about 1, 2, 3, 4, 5, 6, 7, 8, 9, 10, 11, 12, 13, 14, 15, 16, 17, 18, 19, 20, 21, 22, 23, 24, 25, or more millimeters from the edge. The encapsulant may be place such that the encapsulant ends at most about 25, 24, 23, 22, 21, 20, 19, 18, 17, 16, 15, 14, 13, 12, 11, 10, 9, 8, 7, 6, 5, 4, 3, 2, 1, or fewer millimeters from the edge.

Subsequently to operation 370, the completed stack (e.g., the substrate, perovskite layer, and other layers) may be used as a front panel for an additional photovoltaic module. For example, the completed stack can be configured to be a front junction of a two-junction photovoltaic module. The completed stack may be configured for use as a substrate for an additional stack. For example, the stack can be used as the initial substrate for growth of a silicon photovoltaic module. The stack may be laminated to a second photovoltaic cell. The stack may be laminated at a temperature of at least about 15, 20, 25, 30, 35, 40, 45, 50, 55, 60, 65, 70, 75, 80, 85, 90, 95, 100, 105, 110, 115, 120, 125, 130, 135, 140, 145, 150, 160, 170, 180, 190, 200, or more degrees Celsius. The stack may be laminated at a temperature of at most about 200, 190, 180, 170, 160, 150, 145, 140, 135, 130, 125, 120, 115, 110, 105, 100, 95, 90, 85, 80, 75, 70, 65, 60, 55, 50, 45, 40, 35, 30, 25, 20, 15, or less degrees Celsius.

FIG. 5C is a flow chart of an example fabrication process 1300 for forming a perovskite layer. The process 1300 may be one embodiment of operations 320-340 of FIG. 2. The process 1300 includes providing a substrate, such as those described herein, including a hole transport layer (1310). The substrate may also include a transparent conducting layer as described elsewhere herein. The hole transport layer may be a hole transport layer as described elsewhere herein.

The process 1300 includes applying a lead layer to the hole transport layer (1320). The lead layer may include lead metal (e.g., lead (0)), lead salts (e.g., lead (II) acetate, lead (II) halide, lead (I) salts, etc.), or any combination thereof. For example, a metallic lead layer may be deposited onto the hole transport layer, and a layer of lead (II) acetate may be applied to the lead layer. The lead layer may be deposited as described elsewhere herein. For example, the lead may be deposited by physical vapor deposition. The lead layer may be deposited by the same deposition method and/or deposition machinery as the hole transport layer. For example, the same physical vapor deposition instrument can be used to deposit both the hole transport layer as well as the lead layer.

The process 1300 may include applying an organic halide salt layer to the lead layer (1330). The organic halide may be an organic halide as described elsewhere herein. For example, a mixture of methylammonium iodide, methylammonium chloride, and formamidinium iodide can be applied to the lead layer. The organic halide layer may be applied by a deposition process as described elsewhere herein. For example, the organic halide can be applied by a spin coating process, an ultrasonic spray-on process, or the like.

The process 1300 may include applying a halide layer to the organic halide layer (1340). The halide layer may include halides (e.g., fluorine, chlorine, bromine, iodine, etc.), oxyhalides (e.g., chlorate, etc.), other halide containing compounds, or the like, or any combination thereof. For example, the halide layer may include iodine. In another example, the halide layer may be iodine. The halide layer may be applied to the organic halide salt layer by deposition processes as described elsewhere herein. The halide can be applied as a gas. For example, iodine can be sublimated and applied as a gas to the organic halide salt layer. The halide can be applied evenly across the surface of the organic halide salt layer. To apply the halide uniformly, a variety of different application devices can be used. An example of an application device may be a ‘shower head’ (e.g., an application head including a plurality of holes. Another example of an application device may be a bar with one or more nozzles that can be translated across the surface of the substrate. For example, a bar of the same width as the substrate can be moved across the substrate to deposit an even coat of halide.

The process 1300 may include performing one or more processing operations to form a perovskite layer (1350). The perovskite layer may be a perovskite layer as described elsewhere herein (e.g., a perovskite layer from FIG. 2). The one or more processing operations may be one or more processing operations as described elsewhere herein. For example, the lead layer with a lead acetate layer deposited on top of it, a methylammonium iodide/formamidinium iodide layer, and an iodide layer can be annealed together at a temperature of 90-120 degrees Celsius to form a methylammonium/formamidinium lead iodide perovskite layer. The one or more processing operations may include a wash. The wash may include use of one or more solvents described elsewhere herein. The wash may be configured to remove unreacted precursors from the perovskite layer. For example, an isopropanol wash can be performed to remove residual organic halide salts. The one or more processing operations may include one or more treatments. Examples of treatments include, but are not limited to, application of phenethylammonium iodide, thiocyanate washes, other passivation and/or stabilization processes, or the like, or any combination thereof.

In general, the perovskite layer is formed by coating the substrate surface with a solution composed of a solvent (or solvents) and one or more perovskite precursor. After forming a film of the solution on the surface of a substrate, the film is dried to remove the solvent and initiate a crystallization reaction for forming a layer of the perovskite from the precursor(s). Methods to form and dry perovskite solution thin films include spin-coating, slot-die coating, vacuum drying, infrared or convective hot-air drying, and gas slot drying. Spin coating is a method both for liquid film deposition and drying; it does not readily afford independent control of film thickness and freestream boundary layer thickness. It is also poorly suited for large-format substrates with linear dimension (rectangle-side or diameter) e.g., larger than 30 cm, due to the high rotation rates and therefore dangerous magnitudes of rotational energy needed.

Vacuum drying can be used to achieve uniformity on large-scale devices because any pressure changes are rapidly communicated across large distances (at the speed of sound) and thus the pressure above the devices can be kept uniform. However, common methods to deposit liquid films are generally performed at atmospheric pressure, and therefore transfer from one tool (to perform the deposition) to another tool (to perform the vacuum drying) is typically needed, and the transfer process makes it difficult to control the temperature and minimize drying during the transfer process. Furthermore, vacuum equipment generally tends to be expensive and maintenance expenses are high relative to atmospheric-pressure equipment.

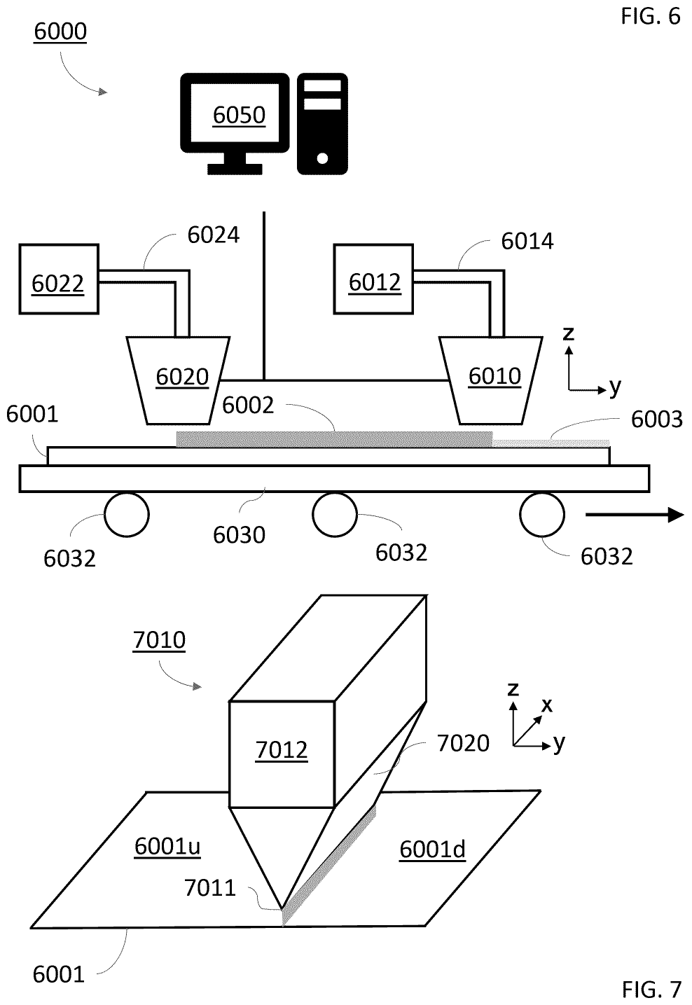

Gas slot drying can be effectively used to dry films on large area substrates at ambient temperature and pressure and are thus amenable to high throughput large scale manufacturing. An example system 6000 for coating and gas slot drying a perovskite precursor solution is shown in FIG. 6. System 6000 includes a platen 6030 supporting a substrate 6001 relative to a coater 6020 and a drying assembly 6010, which includes at least one gas slot (also referred to as an “air knife”). Rollers 6032 move the platen in the y-direction to position the substrate 6001 first under the coater 6020 and then under the drying assembly 6010. Coater 6020 (e.g., a slot die) receives the solution stored in a reservoir 6022 via a conduit 6024 and forms a uniform layer 6002 of the solution on the surface of the substrate 6001. Generally, the thickness of layer 6002 can vary depending on the concentration of precursors in the solution and the target film thickness for the perovskite film. In some examples, the thickness of the solution layer 6002 is in a range from 0.01 mm to 1 mm and the target perovskite film thickness is in a range from 1% to 50% of the solution layer thickness. For instance, the dried perovskite film can have a thickness in a range from 100 nm to 2,000 nm (e.g., 200 nm or more, 300 nm or more, 500 nm or more, 750 nm or more, such as 1,500 nm or less, 1,200 nm or less, 1,000 nm or less).

The drying assembly 6010 is connected to a pump 6012 via conduit 6014 and blows air or other gas such as nitrogen via the one or more gas slots onto the coated surface, drying the solution layer 6002 and forming a layer 6003 of perovskite. The system is controlled by a computer controller 6050, which coordinates operation of the coater 6020, the drying assembly 6010, and the platen's motion. Note that while in the present example, the platen is moved relative to the coater 6020 and drying assembly 6010 which remain stationary, in general either or both may move relative to a fixed reference frame. For example, in certain examples, the platen and substrate may remain stationary while the coater and drying assembly are sequentially moved over the substrate.

Referring to FIG. 7, an example gas slot 7010 includes a plenum housing 7012 and a nozzle 7020 that extends across the substrate 6001 in the x-direction. Gas at pressure is pumped or released to a plenum in the housing 7012 and exits the gas slot in a stream 7011 in the direction of the substrate 6001 through the nozzle 7020. The gas slot 7010 is configured to deliver the gas uniformly across the substrate surface while the substrate 6001 moves relative to the gas slot 7010 in the y-direction. The portion 6001d of the substrate 6001 that has been exposed to the gas slot is considered downstream from the gas slot, while the portion 6001u is considered upstream.

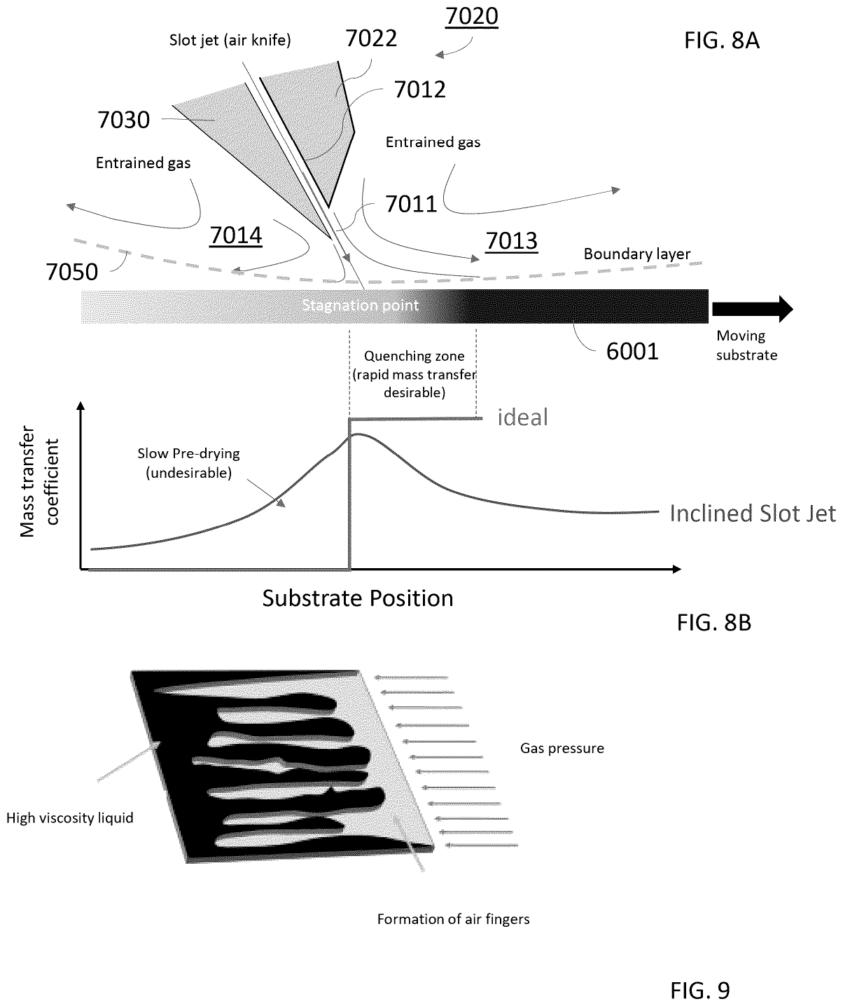

Referring to FIG. 8A, an example of a portion of nozzle 7020 is shown in cross section and includes a first wedge 7022 and a second wedge 7030 that form opposing sides of a channel 7012 through which the pressured gas flows. The first wedge 7022 faces the downstream side of the substrate and the second wedge faces the upstream side-accordingly, the first wedge is referred to as the downstream wedge and the second wedge is the upstream wedge. The internal faces of the wedges are configured so that the channel 7012 is angled non-vertical to the substrate 6001. In this case, the channel is angled to emit the gas stream 7011 with a velocity component in the downstream direction. Two entrained gas streams are formed on either side of gas stream. A downstream entrained gas 7013 flows in the downstream direction. An upstream entrained gas 7014 flows upstream from the gas slot.

Generally, the gas slot (here, and in other examples described below) can be configured so that entrained or emitted gas flow upstream of the gas slot (e.g., at the undried upstream film) is at least twice as low (e.g., 3× or more lower, 4× or more lower, 5× or more lower, 10× or more lower, 20× or more lower) as entrained gas flow downstream from the gas slot. Entrained gas flow can be measured equal distances upstream and downstream from the nozzle (e.g., 1 mm or more from the nozzle, 2 mm or more from the nozzle, 5 mm or more from the nozzle, 10 mm or more from the nozzle, 20 mm or more from the nozzle, such as 50 mm or less from the nozzle, 40 mm or less from the nozzle, 30 mm or less from the nozzle, 20 mm or less from the nozzle). Alternatively, or additionally, entrained gas flow can be determined using computational fluid dynamics.

In general, a liquid thin film composed of solvent(s) containing perovskite precursor solutes are dried by a combination of evaporation and mass transfer. Evaporation is a process in which liquid-phase molecules will migrate into a gas-phase state until equilibrium vapor pressure is established just above the liquid surface. This equilibrium vapor pressure is a strong function of temperature. Mass transfer away from the liquid surface (into any headspace or freestream-flowing gas) occurs ultimately by diffusion, but mass flux can be enhanced with freestream flow, because steep concentration gradients can be induced by formation of a thin boundary layer 7050.

Adopting a point of reference at a location (x, y) on the substrate with a stationary deposited liquid thin film (which is typically less than 1 mm thick, in the z-direction), the rate of flux of solvent from the liquid film into the gas phase above it can be expressed as:

$${J}_{solvent}^{″} = \frac{{D}_{solvent}}{{δ}_{BL}} \cdot ( \frac{{P}_{s olvent , sat} ( {T}_{film} )}{{RT}_{film}} - \frac{{P}_{solvent , fs} ( {T}_{fs} )}{{RT}_{fs}} )$$

Where Dₛₒₗᵥₑₙₜ is the diffusion coefficient of solvent vapor in the ambient freestream gas; δ_{BL} is the thickness of the mass transfer boundary layer formed as the freestream gas blows over the thin film; P_{solvent,sat}(T_{film}) is the saturation pressure of the solvent at T_{film}; P_{solvent,fs}(T_{fs}) is the partial pressure of solvent in the ambient freestream dry gas blowing over the film (typically zero); R is the universal gas constant; T_{fs} is the freestream gas temperature. Being a thin film, it can be assumed that gradients in all of these variables are small over distances in the gas comparable to the thin film's thickness. However, they may vary substantially over larger distances (e.g., cm-scale distances or larger), and concentration of solvent within a film may have gradients due to the limited rate of diffusion of solvent (or antisolvent) through a nearly crystalline film. Furthermore, either by moving the substrate or external apparatus, these variables may change quickly in time, as experienced by the film at position (x, y) on the substrate.

Furthermore, the kinetic rates of crystal nucleate formation may have strong dependencies on solvent properties (and therefore in the case of multi-solvent systems, the relative concentrations of each solvent), and a strong dependence on temperature. Simple thermodynamically favored reactions may have a simple Arrhenius (exponential) dependence on the inverse of absolute temperature (1/T), e.g.,

$${RR}_{f} = f ( {C}_{i} ) exp ( - Ea / {RT}_{film} )$$

where RR_{f} is a forward reaction rate, and f(Cᵢ) is generally a product of powers of reactant concentrations. However, crystallization and grain growth (e.g., Ostwald ripening) may have more complex dependencies on concentrations and temperatures, because solubility increases with temperature.

The variables that appear in all the above example equations have different dependencies on other parameters such as temperature, freestream concentration, and freestream gas flowrate and pressure. Specifically:

Dₛₒₗᵥₑₙₜ, the gas-phase diffusion coefficient, often has a nearly power-law dependence on temperature (e.g., T″ where n is between 1 and 2), or as fitted by application of the Sutherland equation and kinetic theory. In the case of a boundary layer with a temperature difference across it, where the liquid film temperature T_{film} and the freestream gas temperature T_{fs} are different, Sparrow teaches that using a temperature weighted ⅔ by T_{film} and ⅓ by T_{fs} matches experimental data well for most gases.

P_{solvent,sat} typically depends exponentially on the temperature of the liquid film.

δ_{BL}, the mass-transfer boundary layer thickness, often has a power-law dependence on the speed of the flow above the boundary layer and the diffusivity. The power-law exponent depending strongly on whether the gas flow is laminar or turbulent (typically governed by the Reynolds number which involves gas flow speed, a characteristic dimension of the flow, the viscosity) and specifics of the flow configuration. For instance, in the case of laminar flow over a flat plate, the mass transfer boundary layer thickness at a fixed distance downstream of the leading edge is known to scale with the square root of diffusivity and distance, and inversely with the square root of freestream speed. In the case of a stagnation-point flow (impinging normally to a plate), the boundary layer thickness is theoretically constant (when neglecting practical edge and far-away boundary conditions).

RR_{f} a forward reaction rate may depend exponentially on 1/T or some other dependence; and may have complex dependencies on solute and solvent concentrations locally present.

P_{solvent,fs} may be controlled via mass flow controllers and pre-mixing of solvent with a carrier gas.

T_{film} may be controlled by controlling the temperature of a surface onto which the substrate is mounted, and by controlling the temperature of the freestream gas, T_{fs}. It is noted that the mass transfer and heat transfer coefficients from the film to the freestream are highly correlated (with the proportionality being a function of the ratio of mass diffusivity to thermal diffusivity). This is known as the Reynolds Analogy and is taught in undergraduate heat-transfer textbooks. However, although heat/mass transfer coefficients cannot be controlled independently, the heat/mass transfer rates can be independently controlled, by controlling freestream temperature independently of freestream concentrations (of solvents). Generally, the dependence of heat/mass transfer rate on these controllable inputs (T_{fs} and P_{solvent,fs}) is linear.

Noting all these dependences, it is believed that strong temporal control of reaction kinetics can be asserted by controlling the spatial distribution of the following four spatial variables:
T_{film}(x), the film temperature;
T_{fs}(x), the freestream temperature;
δ_{BL}(x), the gas-phase freestream boundary layer thickness;
P_{solvent,fs}(x), the solvent partial pressure in the freestream;
   and a fifth variable U, which denotes the relative speed (e.g., m/s) of the substrate and any apparatus controlling the spatial distribution of the above variables.

FIG. 8B shows a notional example of an ideal temporal profile of temperature and mass transfer rate desirable for high-quality perovskite production. In such a scenario, the mass transfer coefficient is zero prior to the quenching zone. At the quenching zone, the mass transfer coefficient steps to an ideal rate for perovskite crystallization and this rate is maintained through the quenching zone. We note that there are many different perovskite material formulations and an infinite number of stoichiometries, each having its own optimal temporal profiles of temperature and mass transfer rate to achieve the highest-efficiency and most reliable devices. Furthermore, there may be multiple combinations of mass-transfer rate profiles and temperature profiles that achieve similar results. In examples, the operational parameters of the drying module are selected so that the coating occupies the quenching zone for a time in a range from 0.1 seconds to about 10 seconds (e.g., 0.2 seconds or more, 0.5 seconds or more, such as 5 seconds or less, 3 seconds or less, 2 seconds or less, such as about 1 second).

In gas slot 7010, a single linear slot-jet of air or other gas (e.g., inert gas such as nitrogen) is emitted to dry the film as while relative motion at a speed U is induced between the gas slot and the substrate/film. Such a configuration has several shortcomings with respect to its ability to control the aforementioned four spatial parameters. For example, the gas slot 7010 described above can cause unwanted, slow pre-drying of the liquid film while it is far upstream of the gas slot. This flow pattern can result in a broad and relatively slowly varying mass transfer coefficient along the surface of the film being dried. As previously mentioned, each phase of the crystallization process (nucleation, ripening, annealing) may have different temperature-dependent kinetic rates, and therefore different preferred drying rates (times varying from tens of milliseconds to seconds) to achieve high-performance devices; in this case slow drying (with low mass-transfer coefficient) is not ideal.

One approach to reducing this effect is to use a variable speed conveyor to induce the relative motion between the substrate and the gas slot. Sensors can be used for feedback that establishes whether the film dries upstream or downstream of the stagnation point of the gas slot, where the mass transfer coefficient is generally highest. A signal from the sensor can be correlated to device performance and can be used to partially optimize the drying parameters. In this way, the temporal profile of the mass transfer coefficient B(t) experienced by the film at a fixed location x is controlled by establishing a spatially-varying mass transfer coefficient B(x) in the coordinate direction x across the substrate surface, and then increasing substrate speed U, so that B(t)=B(x/U), and the time over which non-optimal slow drying of upstream perovskite occurs is reduced. If the relative motion at speed U is too fast, then the critical phase of drying may occur downstream of the gas slot, where again the mass transfer coefficient is too slow. Thus, there is an optimal speed U for best performance. However, using a single speed, even if optimal, doesn't change the shape of the spatial profile B(x), it can only linearly compress or linearly expand a fixed-shape profile in x by the factor 1/U, and therefore is limited in its ability to achieve the ideal mass-transfer coefficient profile.

Furthermore, simply increasing the air flow rate from the gas slot, or back-pressure upstream of the gas slot, can create difficulties. For example, the flow pattern can change from laminar to turbulent, and from subsonic to sonic choked flow at the gas slot exit when the backpressure is more than about twice the ambient pressure. This creates unsteady flow, shocks, and temperature variations coupled with flow speed, which may make it more difficult to control temperature and mass-transfer profiles independently. Another possible difficulty is that as the stagnation pressure (air pressure at the stagnation point, as shown in FIG. 8B) becomes higher, if the liquid film is not yet crystallized or at least extremely viscous, it can compress the liquid film and push a wave of thicker liquid film upstream of the gas slot. That thicker liquid film is subject to viscous “fingering”, a well-known Saffman-Taylor type instability, created when a lower viscosity fluid (in this case the gas) pushes a higher-viscosity fluid (in this case, the liquid film). The instability creates 3D “fingers” that are undesirable variations in film thickness illustrated in FIG. 9.

In the following examples, configurations of drying modules are described that allow tailored control of the spatial distribution of the four aforementioned controlling variables (in combination with relative motion of a substrate), to better optimize the performance of perovskite films and processing throughput.

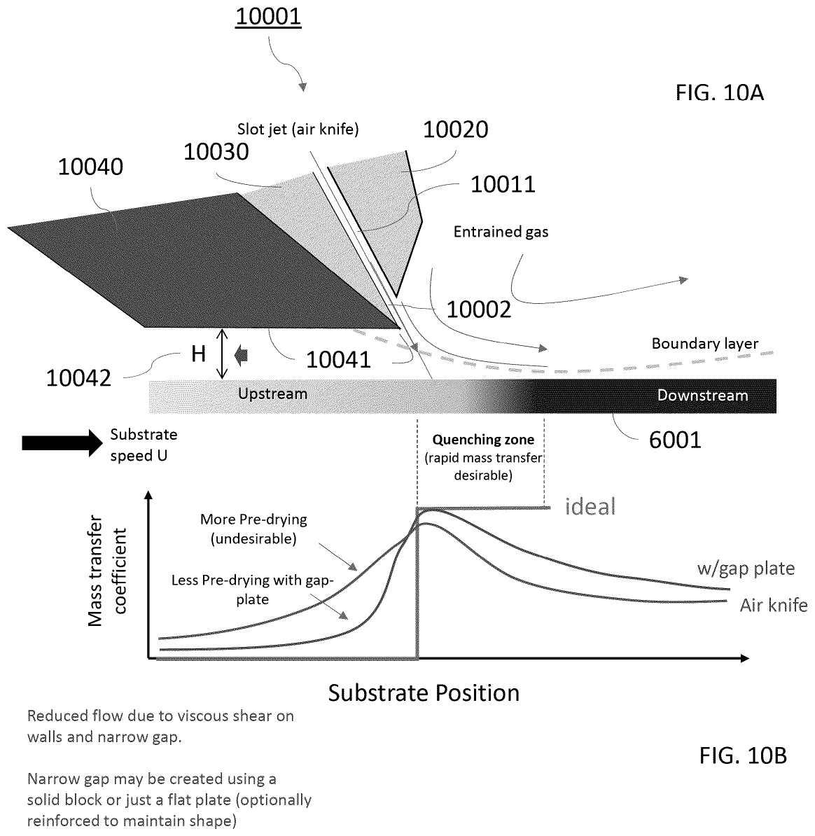

In some examples, the drying module can include a gap plate either upstream and/or downstream from the nozzle channel to influence the flow of entrained gas upstream and/or downstream from the nozzle. For example, a drying module 10001 shown in FIG. 10A includes a channel 10011 form from a downstream wedge 10020 and an upstream wedge 10030. A gap plate 10040 is attached to the upstream wedge 10030. The lower surface 10041 of the gap plate 10040 creates a channel of height H upstream from the edge of wedge 10030 in which the upstream entrained gas is contained. In general, the channel height H and length (in the direction of film relative motion) are selected to provide an appropriate gas flow profile of the entrained gas upstream from the quenching zone. H can be 10 mm or less (e.g., 9 mm or less, 8 mm or less, 7 mm or less, 6 mm or less, 5 mm or less, 4 mm or less, 3 mm or less, 2 mm or less, 1 mm or less). The channel length can be 30 cm or less (e.g., 20 cm or less, 15 cm or less, 12 cm or less, 10 cm or less, 8 cm or less, 5 cm or less, 4 cm or less, 3 cm or less, 2 cm or less, such as 1 cm or more, 2 cm or more, 3 cm or more, 5 cm or more).

FIG. 10B shows a plot of the mass transfer coefficient as a function of substrate position comparing an ideal curve (as discussed previously) to gas slots with and without a gap plate. The use of a gap plate can advantageously decrease the coefficient upstream from the quenching zone compared to a gas slot without a gap plate.

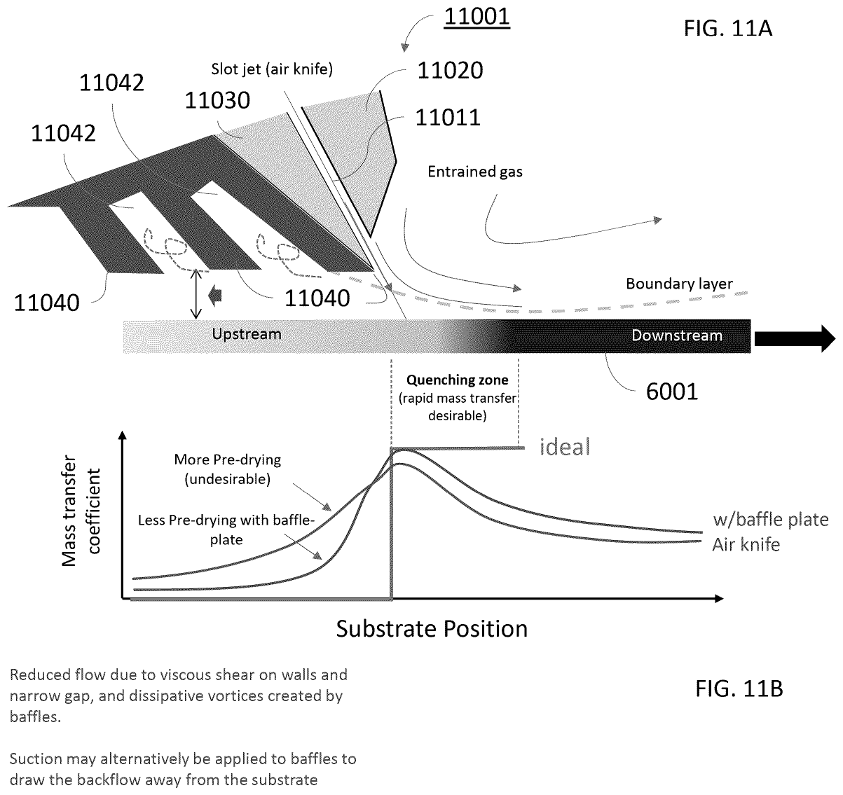

While the gap plate in the drying module creates a channel with a uniform gap upstream from the quenching zone, other implementations are possible. For example, the lower surface of a gap plate can be structured (rather than flat) in a way that controls entrained gas flow in an advantageous way. FIG. 11A, for example, shows a drying module 11001 that includes a channel 11011 form from a downstream wedge 11020 and an upstream wedge 11030. A structured gap plate 11040 is attached to the upstream wedge 11030. The gap plate 11040 includes baffles 11041 that extend at an oblique angle with respect to the substrate 6001. The baffles 11041 are separated by baffle channels 11042. The baffles 11041 and baffle channels 11042 break up laminar air flow of the entrained gas upstream from the quenching zone.

The gap height H between the substrate 6001 and the ends of the baffles 11041 can be 10 mm or less (e.g., 9 mm or less, 8 mm or less, 7 mm or less, 6 mm or less, 5 mm or less, 4 mm or less, 3 mm or less, 2 mm or less, 1 mm or less). The length of the baffles can be any appropriate length (e.g., in a range from 0.5 cm to 10 cm). Generally, the number of baffles can vary depending on the implementation. In some cases, a single baffle can be used. Where multiple baffles are used the length of each baffle can be the same or can be different.

FIG. 11B shows a plot of the mass transfer coefficient as a function of substrate position comparing an ideal curve (as discussed previously) to gas slots with and without a gap plate. The use of a gap plate can advantageously decrease the coefficient upstream from the quenching zone compared to a gas slot without a gap plate.

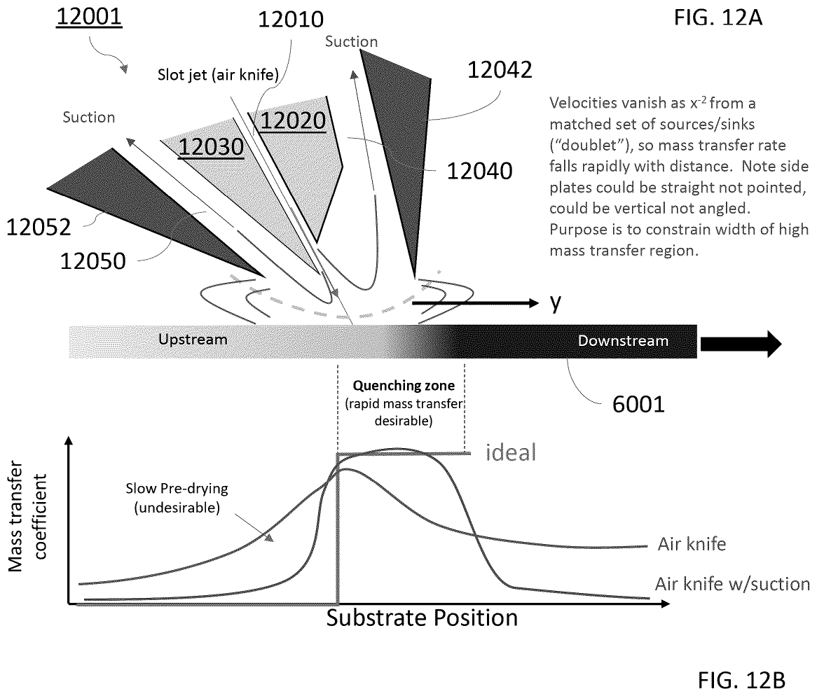

In some examples, a drying module can use suction passages near the orifice of a gas slot nozzle. Generally, a suction passage (or exhaust) can be positioned upstream and/or downstream from the gas slot orifice. The suction flowrate is ideally equal to or greater than the flowrate of gas issued from the gas slot. An example drying module 12001 that includes a gas slot nozzle flanked upstream and downstream by suction channels is shown in FIG. 12A. The nozzle includes a channel 12010 formed by a downstream wedge 12020 and an upstream wedge 12030. A downstream suction channel 12040 is formed by the outer surface of wedge 12020 and a downstream outer shroud 12042. An upstream suction channel 12050 is formed by the outer surface of wedge 12030 and an upstream outer shroud 12052. While the surfaces of the shrouds are at oblique angles with respect to the substrate 6001 plane, other orientations are possible. For instance, one or both of the suction channels can be vertically oriented with respect to the substrate.

Referring also to FIG. 12B, which shows a plot of the mass transfer coefficient for module 12001 as a function of substrate position, placement of the upstream and downstream shrouds defines a quenching zone over which relatively high mass transfer coefficient is desired. Outside of this zone, the mass transfer coefficient drops significantly.

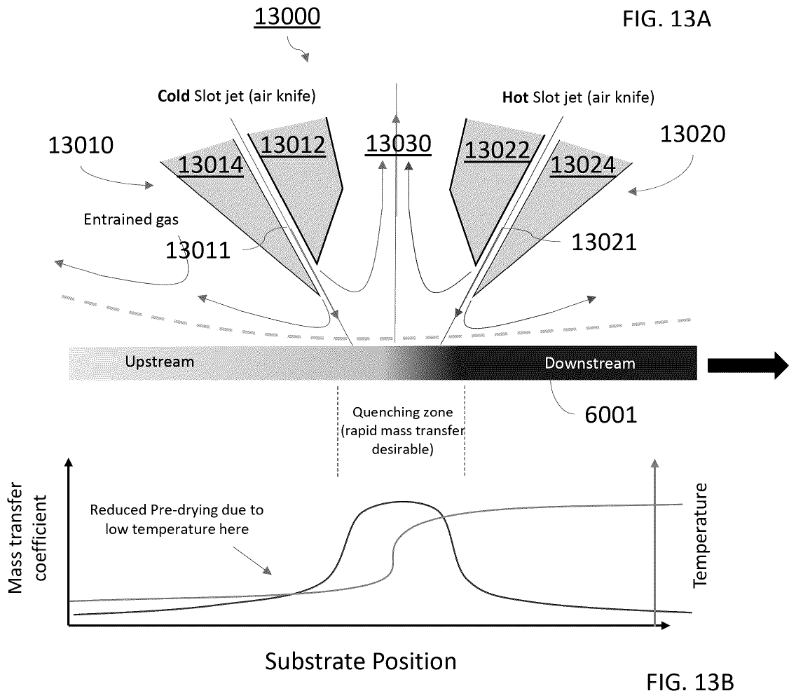

While the foregoing examples of drying modules each feature a single gas slot, implementations are possible that include more than one gas slot. An example module 13000 with two gas slots is shown in FIG. 13A. In particular, this gas slot includes a first nozzle 13010 upstream of a center point of the quenching zone and a second nozzle 13020 downstream.

Gas slot 13010 includes an upstream wedge 13014 and a downstream wedge 13012 forming channel 13011 that is at an oblique angle downstream. Gas slot 13020 includes an upstream wedge 13022 and a downstream wedge 13024 forming channel 13011 that is at an oblique angle upstream. In nozzle 13010, the edge of downstream wedge 13012 is further from the substrate 6001, while in nozzle 13020, the edge of upstream wedge 13022 is further.

The two nozzles are separated by a suction channel 13030, which draws gas emitted by both of the nozzles. Generally, the width of the channel 13030 between the two nozzles can vary depending on the implementation (e.g., the desired size of the quenching zone). This width can be in a range from 0.1 cm to 30 cm (e.g., 1 cm or more, 2 cm or more, 5 cm or more, such as 10 cm or less, 8 cm or less).

Furthermore, the angle of the channels 13011 and 13021 can vary depending on the implementation. Generally, these angles can have the same magnitude or can be different. The angles can be in a range from vertical to +/−80° from vertical. The angles and distance between the two channels can be varied so as to control the location of a stagnation point between them, while also providing the same or different flowrates from each gas slot.

The temperature of the gas delivered by each nozzle can be the same or can be different. In some implementations, one nozzle delivers heated gas and the other delivers gas at ambient temperature or cooler.

FIG. 13B shows a plot of the mass transfer coefficient as a function of substrate position for drying module 13000. Also shown is a plot of the gas temperature as a function of substrate position for an implementation in which upstream nozzle 13010 delivers cooled gas and nozzle 13020 delivers heated gas. Delivering cooler gas upstream from the quenching zone can be advantageous as it can reduce the mass transfer coefficient relative to uncooled gas upstream of the quenching zone. Delivering heated gas at or downstream from the quenching zone can be advantageous as it can ensure a high mass transfer coefficient in the quenching zone and can ensure low residual solvent in the crystalized perovskite downstream from the zone.

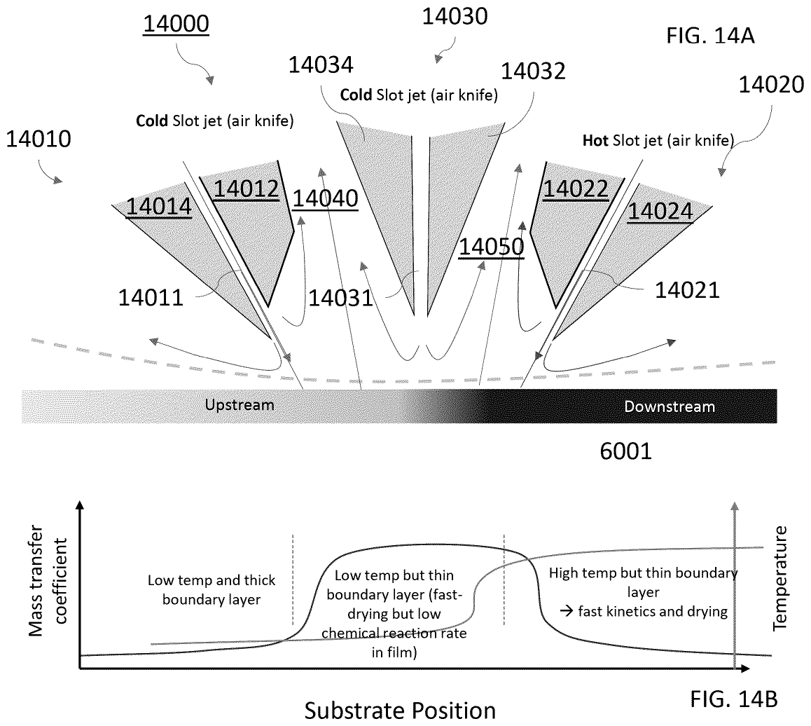

An example of a drying module with gas slots and two suction channels is shown in FIG. 14A. Here, a drying module 14000 includes three nozzles 14010, 14020, and 14030, separated by two suction channels 14040 and 14050. Upstream nozzle 14010 includes a channel 14011 formed by upstream wedge 14012 and downstream wedge 14014. Channel 14011 is inclined relative to the vertical direction in the downstream direction. Downstream nozzle 14020 includes a channel 14021 formed by an upstream wedge 14022 and a downstream wedge 14024. Channel 14021 is inclined relative to the vertical direction in the upstream direction. Central nozzle 14030 includes a channel 14031 separated by a downstream wedge 14032 and an upstream wedge 14034. Channel 14031 is oriented in the vertical direction relative to the substrate 6001. Upstream nozzle 14010 is separated from central nozzle 14030 by exhaust channel 14040 and downstream nozzle 14020 is separated from the central nozzle 14030 by exhaust channel 14050.

Referring also to FIG. 14B which shows a plot of the mass transfer coefficient as a function of substrate position, the air knives are configured to provide a quenching zone for optical drying and crystallization of the perovskite film. Generally, the temperature of the gas delivered from each nozzle, the nozzle orientation, the flow rate, the spacing between each nozzle, and the strength of the vacuum applied to each suction channel is selected to provide the desired profile. For the illustrated curve, cold gas is delivered from nozzles 14010 and 14030, while heated gas is delivered from nozzle 14020.

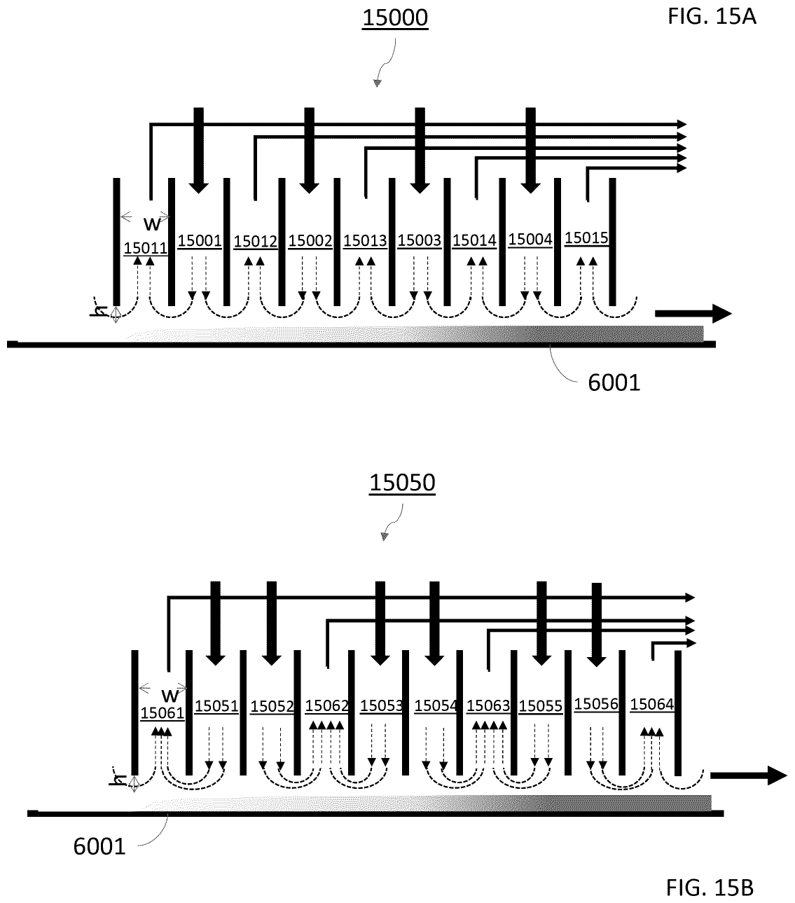

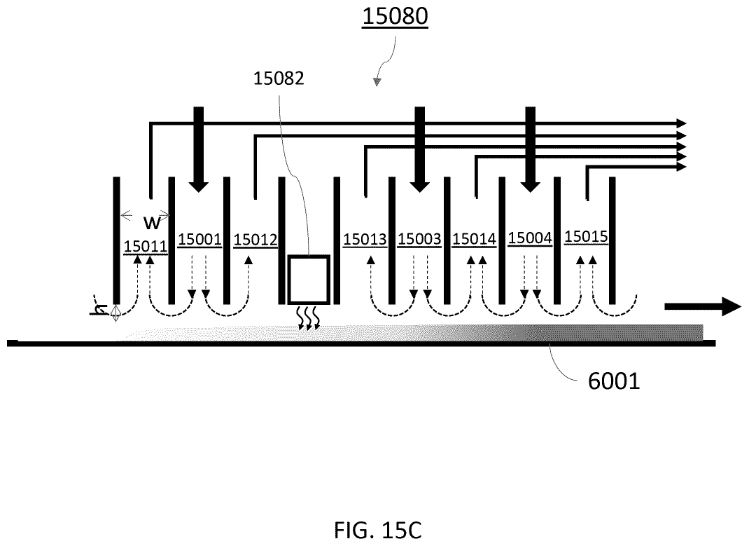

More generally, drying modules composed of any number of gas slot nozzles and suction channels can be used to control solvent mass transfer and crystallization within the quenching zone. For example, as shown in FIG. 15A, an example drying module 15000 includes four gas slots 15001-15004 and five suction channels 15011-15015.

While the foregoing drying module example features a suction channel between each of the nozzles, other configurations are possible. For example, in certain implementations, exhaust channels can be separated by more than one nozzle. Specifically, as shown in FIG. 15B, a drying module 15050 includes six gas slot nozzles 15051-15055 and four suction channels 15061-15064.

Parameters of flow for each gas slot and each suction channel in the drying modules 15000 and 15050 can be operated independent of the others. For example, the flow rate, temperature, and vapor composition of the gas from each gas slot can be independently controlled. The vacuum pressure for each suction channel can be independently controlled. each gas supply passage can have a gas flow rate, temperature, and vapor composition independently controlled relative to the other passages. Moreover, the vacuum channel pressure of each of the exhaust channels can be independently controlled relative to the other exhaust channels. The ambient temperature can also be controlled (e.g., cooled or heated) relative to room temperature. In some implementations, the substrate 6001 can be heated conductively (e.g., by a heating element in the platen). In some cases, the substrate and/or ambient gas can be heated using infra-red radiation.

Generally, drying modules can include additional components that locally influence the evaporation and crystallization processes in a perovskite precursor solution in addition, or alternative, to gas slots and suction channels. For example, one or more elements for locally heating the film can be included. FIG. 15C shows a further example drying module 15080 that includes a heating element 15082 between suction channels 15012 and 15013. Infrared lamps, for example, can be used to locally heat the surface of the film to influence the evaporation/crystallization process.

In some examples, the gas used in one or more of the gas slots can include a solvent (e.g., solvent vapor). Including solvent in the gas stream can further influence the rate of evaporation, nucleation, and/or crystallization of the perovskite film.

Alternatively, or additionally, in certain examples, the gas used in one or more of the gas slots can include an anti-solvent (e.g., anti-solvent vapor). Including anti-solvent in the gas stream can further influence the rate of evaporation, nucleation, and/or crystallization of the perovskite film.

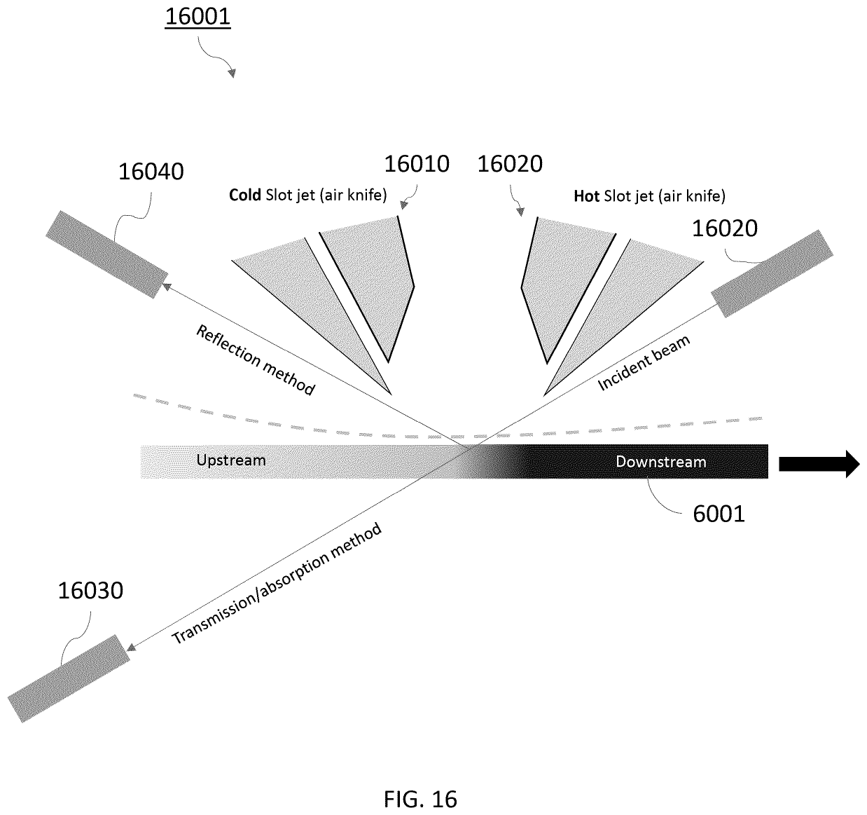

In general, the evaporation and crystallization processes in the vicinity of the drying module (e.g., in and/or downstream from the quenching zone) can be monitored inline. For example, referring to FIG. 16, an optical monitoring module includes a light source 16020 (e.g., a laser or multiple lasers) arranged to illuminate the surface of the coating under a drying module 16001 with light at a glancing incident angle. A first detector 16030 detects transmitted light while a second detector 16040 detects reflected light. Information about the thickness, morphology, and/or composition of the film can be determined based on the intensity and spectrum of the reflected and/or transmitted light. In this example, the drying module 16001 includes two nozzles 16010 and 16012. However, optical monitoring can be used in conjunction with any of the aforementioned examples and other implementations of drying modules. Real-time monitoring of the evaporation and crystallization process can be used to optimize and/or control the drying process for a given precursor and solvent combination, film thickness, etc. For example, monitoring the process optically as described above can be used for feedback to control parameters such as: ambient temperature, gas pressure from each gas slot, gas composition from each gas slot, gas temperature from each gas slot, substrate velocity relative to the drying module, substrate temperature, suction pressure at each suction channel, among other parameters.

In some examples, additional steps are included further to the coating and drying described above. For example, a quench solution may be applied to the precursor solution after coating the substrate. The quench solution may be applied after the precursor is dried (e.g., after the perovskite layer is formed). The quench solution can include an antisolvent (e.g., a solvent that the perovskite precursors are less soluble in than the solvent for the precursor solution). Examples of antisolvents include, but are not limited to polar solvents (e.g., alcohols, acetone, etc.), long-chain non-polar solvents (e.g., octadecene, squalene, etc.), or the like, or any combination thereof. The quench solution may be applied as described elsewhere herein. For example, the quench solution may be applied by ultrasonic spray-on techniques.

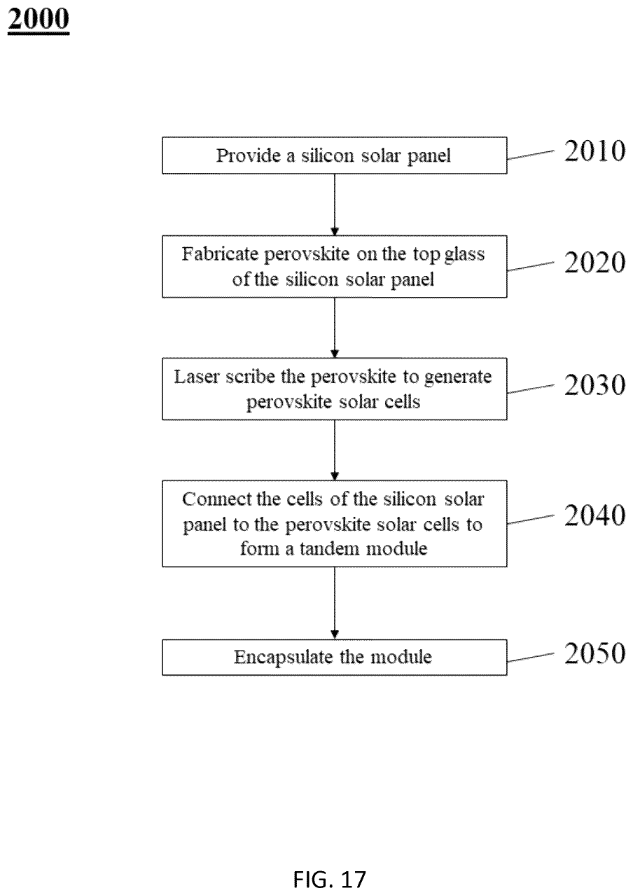

FIG. 17 is a flow chart of a process 2000 for manufacturing a tandem solar module, according to some embodiments of the present disclosure. The method may include providing a silicon solar panel (2010). The silicon solar panel may be as described elsewhere herein. For example, the silicon solar panel may be a front contact solar panel, an integrated back contact solar panel, a shingled solar panel, or the like. The silicon solar panel may have at least about 10, 15, 20, 25, 30, 35, 40, 45, 50, 55, 60, 65, 70, 72, 75, 80, 85, 90, 95, 96, or more solar cells. The silicon solar panel may have at most about 96, 95, 90, 85, 80, 75, 72, 70, 65, 60, 55, 50, 45, 40, 35, 30, 25, 20, 15, 10, or less solar cells. In some embodiments, the silicon solar panel has 60 six-inch solar cells arranged in a 6-by-10 grid. The cells may be connected in series. The cells may each have an open circuit voltage of 0.7V, for a total open circuit voltage of approximately 42V.

The method may further include fabricating perovskite-on-glass as described elsewhere herein (2020). The perovskite-on-glass may have at least about 1, 2, 3, 4, 5, 6, 7, 8, 9, 10, or more layers. The perovskite-on-glass may have at most about 10, 9, 8, 7, 6, 5, 4, 3, 2, or less layers.

The method may further include laser scribing the perovskite-on-glass to form perovskite cells or strips (2030). The fabricating may include use of fabrication techniques as described elsewhere herein. For example, the fabricating can include use of a laser scribe to define the one or more perovskite solar cells. The one or more perovskite solar cells may be a plurality of perovskite solar cells. The one or more perovskite solar cells may be at least about 1, 2, 3, 4, 5, 6, 7, 8, 9, 10, 11, 12, 13, 14, 15, 20, 25, 30, 35, 40, 45, 50, 55, 60, 65, 70, 75, 80, 85, 90, 95, 99, or more perovskite solar cells. The one or more perovskite solar cells may be at most about 99, 95, 90, 85, 80, 75, 70, 65, 60, 55, 50, 45, 40, 35, 30, 25, 20, 15, 14, 13, 12, 11, 10, 9, 8, 7, 6, 5, 4, 3, 2, or less perovskite solar cells. The plurality of perovskite solar cells may be connected in series. The plurality of perovskite solar cells may be connected in parallel. The laser scribing may separate the perovskite layer into a plurality of segments. The plurality of segments may be formed into a plurality of perovskite solar cells. For example, contacts can be applied to the plurality of segments to extract charge from the plurality of segments.

The laser scribing may be configured to generate a plurality of perovskite cells which, when connected together, have a same or substantially same voltage output as the silicon module. The voltage output of the perovskite layer per unit area can be known, and the perovskite layer can be scribed to form perovskite cells of a size to provide a predetermined voltage. For example, a perovskite layer can be scribed to form 5 perovskite sub-modules each including 40 perovskite solar cells to match a silicon solar module that has a same voltage output as the 40 perovskite solar cells. In this example, the 5 perovskite sub-modules can be connected in parallel to increase the current produced by the perovskite layer while maintaining the voltage match with the silicon module.

The method may further include connecting the cells of the silicon solar panel to the perovskite solar cells to form a tandem module (2040). The silicon solar panel and the perovskite solar cells may be in a voltage matched configuration. The voltage matched configuration may be as described elsewhere herein. For example, the silicon solar cells can have the same voltage as the perovskite solar cells. The perovskite solar cells may be connected to one another in parallel. The perovskite solar cells may be connected to one another in series. The perovskite solar cells may be connected such that there are multiple modules in the perovskite layer. For example, rows of the perovskite solar cells can be each connected in series and the connected rows can be connected in parallel. The silicon solar panel and the perovskite solar panel may be connected as described elsewhere herein. For example, the perovskite solar cells can be connected via copper (or another metal, charge collection tape, etc.) terminals to the same junction box as the silicon solar cells.

The method may further include encapsulating the module (2050). The encapsulating may include applying an encapsulant as described elsewhere herein. For example, the encapsulating can include applying a thermal-plastic polyolefin to the perovskite layer. In another example, the encapsulating can include use of a transparent conducting oxide.

The method may include applying a plurality of contacts to the one or more perovskite solar cells to electrically couple the one or more perovskite solar cells. The plurality of contacts may be applied using one or more processes as described elsewhere herein. For example, the plurality of contacts can be evaporated onto the perovskite solar cells. In another example, the plurality of contacts can be lithographically applied to the perovskite solar cells. The method may include applying an encapsulant to the one or more perovskite solar cells. The applying may be as described elsewhere herein. For example, the encapsulant can be applied via evaporation. In another example, the encapsulant can be spread as a viscous solution onto the perovskite solar cell. The encapsulant may be as described elsewhere herein. For example, the encapsulant may be a thermal-plastic polyolefin. The method may include applying an edge seal to the one or more perovskite solar cells. The edge seal may be as described elsewhere herein. For example, the edge seal can be HelioSeal™.

The silicon solar panel and the perovskite solar panel may be electronically coupled to a same junction box. Such coupling to the same junction box may allow for simple integration of the perovskite layer into existing silicon solar modules. Such coupling may also provide for simple installation of the tandem solar module, as there may be a single output from the tandem module instead of multiple outputs.

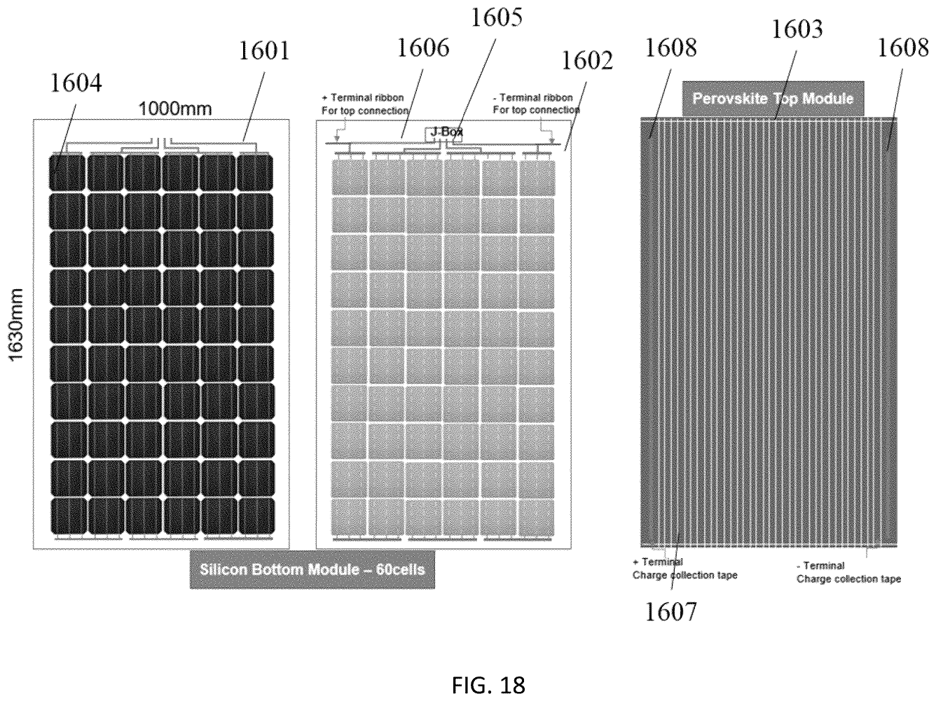

FIGS. 18-21 show examples of different electrical network connections for different types of silicon-perovskite hybrid solar modules. The hybrid silicon-perovskite solar modules may be as described elsewhere herein. FIG. 18 shows an example of the front and back of a silicon solar module 1601 and 1602 as well as a perovskite top module 1603. The silicon solar module may include front busbars 1604. The front bus bars may be configured to connect the various solar cells in the module to a single junction box output 1605. The silicon solar module may include terminals 1606. The terminals may include copper, silver, gold, iron, alloys thereof, charge collection tape, or the like, or any combination thereof. The terminals may be configured to electrically connect with the perovskite top module 1603. For example, the terminals can be configured to electrically connect the perovskite top module to the junction box. The terminals may be configured as to provide a parallel connection between the silicon solar module and the perovskite top module. Alternatively, the terminals may be configured to provide a series connection between the silicon solar module and the perovskite top module. The tandem solar module may include a silicon solar panel. The silicon solar panel may include a plurality of silicon solar cells. The silicon solar panel may include a top glass sheet. The plurality of silicon solar panels may be connected in series and have a first open circuit voltage. The tandem solar module may include a perovskite solar panel disposed on an underside of the top glass sheet of the silicon solar panel. The perovskite solar panel may include a plurality of segments. Each segment of the plurality of segments may include a plurality of laser-scribed strips of perovskite. The plurality of laser-scribed strips of perovskite within a segment may be connected in series to generate a second open circuit voltage that may be substantially the same as the first open circuit voltage. The tandem solar module may include an interconnect connecting the plurality of silicon solar cells and the plurality of segments of the perovskite solar panel in parallel.

The segments can include at least about 2, 3, 4, 5, 6, 7, 8, 9, 10, 11, 12, 13, 14, 15, 20, 25, 30, 35, 40, 45, 50, 55, 60, 65, 70, 75, 80, 85, 90, 100, 125, 150, 175, 200, 250, 300, 400, 500, or more segments. The segments can include at most about 500, 400, 300, 250, 200, 175, 150, 125, 100, 90, 85, 80, 75, 70, 65, 60, 55, 50, 45, 40, 35, 30, 25, 20, 15, 14, 13, 12, 11, 10, 9, 8, 7, 6, 5, 4, 3, 2, or fewer segments. The number of segments can be in a range defined by any two of the proceeding values. For example, the number of segments can be from about 10 to about 200 segments.

The perovskite top module may include one or more channels 1607, as well as one or more terminals 1608. The channels may be generated by methods described elsewhere herein.

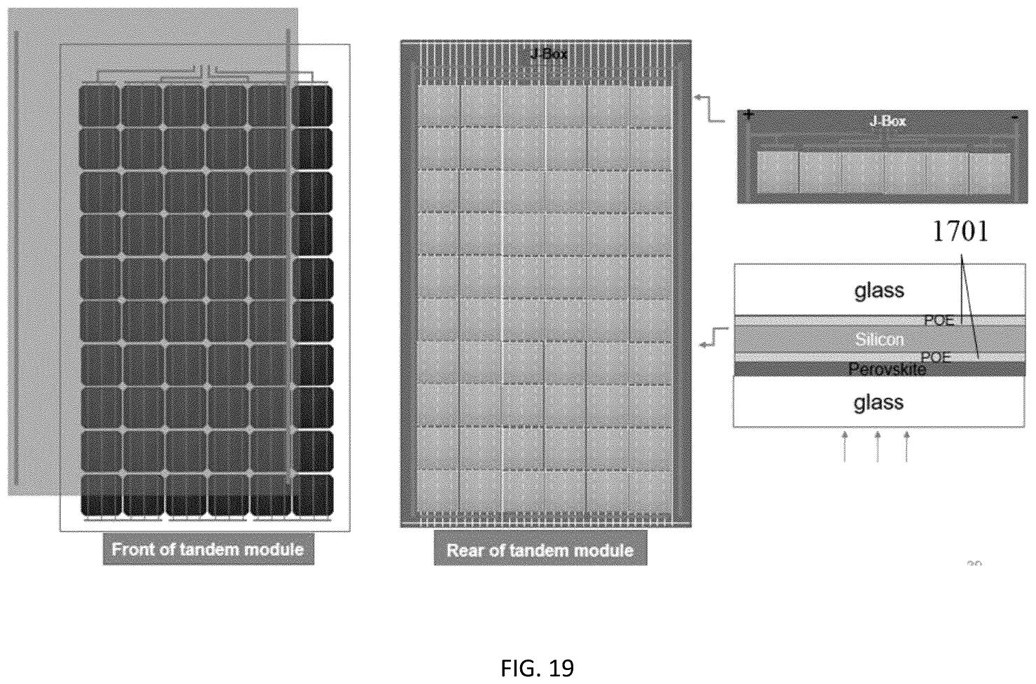

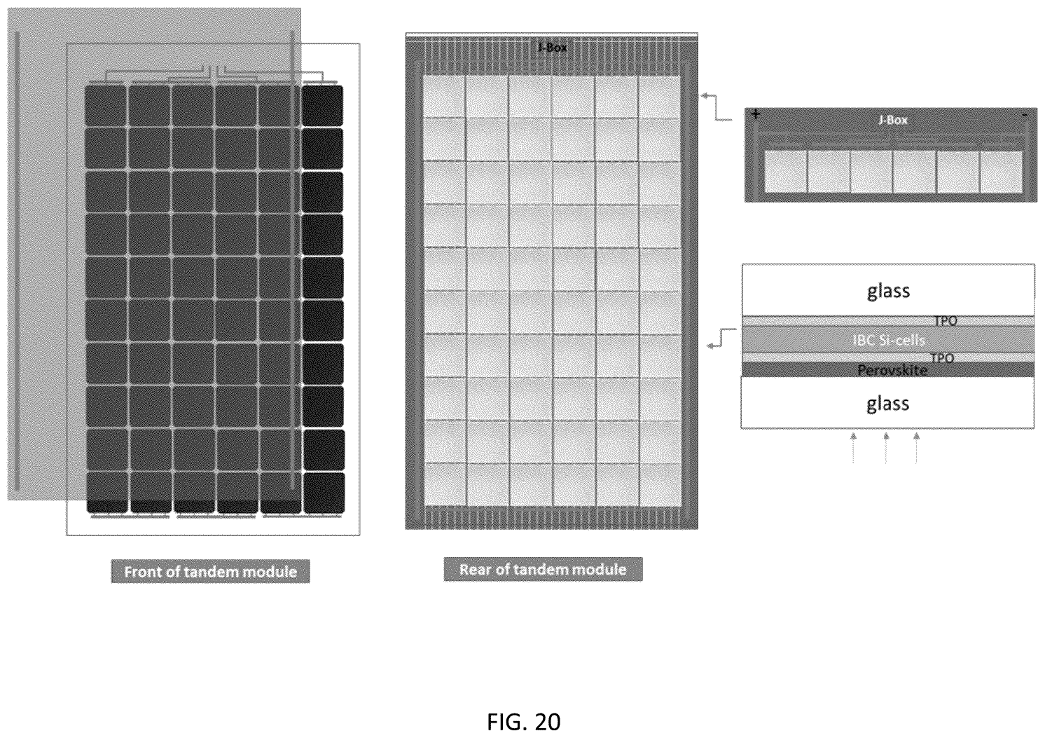

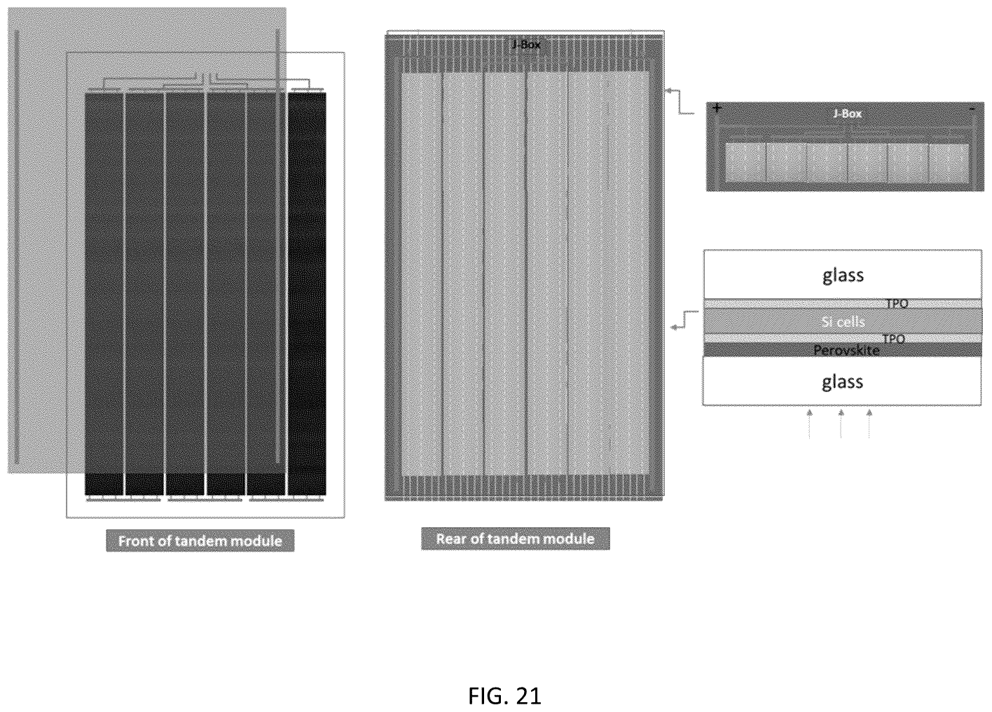

For example, the channels can be cut in with a laser scribe. The channels may be configured to isolate different perovskite solar cells from one another. In this way, a plurality of perovskite solar cells can be formed in the perovskite top module. Additional channels perpendicular to the channels can be used to form a grid of solar cells. For example, a 5 by 40 array of perovskite solar panels can be formed out of the perovskite layer. The perovskite top module may include at least about 1, 2, 3, 4, 5, 6, 7, 8, 9, 10, 11, 12, 13, 14, 15, 20, 25, 30, 35, 40, 45, 50, 55, 60, 65, 70, 75, 80, 85, 90, or more perovskite solar cells. The perovskite top module may include at most about 90, 85, 80, 75, 70, 65, 60, 55, 50, 45, 40, 35, 30, 25, 20, 15, 14, 13, 12, 11, 10, 9, 8, 7, 6, 5, 4, 3, 2, or fewer perovskite solar cells. For example, the perovskite top layer can include 40 solar cells separated by channels. The perovskite solar cells can be at least about 1, 2, 3, 4, 5, 6, 7, 8, 9, 10, 11, 12, 13, 14, 15, 20, 25, 30, 35, 40, 45, 50, or more millimeters wide. The perovskite solar cells can be at most about 50, 45, 40, 35, 30, 25, 20, 15, 14, 13, 12, 11, 10, 9, 8, 7, 6, 5, 4, 3, 2, or less millimeters wide. The perovskite solar cells can be at least about 1, 2, 3, 4, 5, 6, 7, 8, 9, 10, 11, 12, 13, 14, 15, 20, 25, 30, 35, 40, 45, 50, 55, 60, 65, 70, 75, 80, 85, 90, 100, 150, 200, 250, 500, 750, 1,000, or more millimeters long. The perovskite solar cells can be at most about 1,000, 750, 500, 250, 200, 150, 100, 90, 85, 80, 75, 70, 65, 60, 55, 50, 45, 40, 35, 30, 25, 20, 15, 14, 13, 12, 11, 10, 9, 8, 7, 6, 5, 4, 3, 2, or fewer millimeters long. The perovskite solar cells can be strips (e.g., solar cells that stretch up to the length of the module). The strips may be connected in series or parallel. In some cases, the perovskite solar cells may be connected to one another in series. The perovskite solar cells may be connected to one another in parallel. Similarly, FIG. 19 shows an example of a stacked tandem perovskite-silicon solar module. The silicon solar panel may be a top contact solar panel. For example, the silicon solar panel can include electrical contacts configured to extract electricity from the panel that are positioned on the side of the silicon solar cells that faces the sun. The module may include one or more encapsulant layers 1701. The one or more encapsulant layers may be as described elsewhere herein. The one or more encapsulant layers can be applied to a substrate, and subsequently the solar cells of the silicon solar module can be arranged onto the one or more encapsulant layers. An additional layer of encapsulant can be applied over the silicon solar cells, and the perovskite-on-glass can then be applied to the encapsulant layer. The encapsulant layer may be configured as to permit electrical connection between the silicon layer and the perovskite layer. FIG. 20 shows an example of a perovskite top module being electrically connected to an integrated back contact (IBC) silicon solar module. The silicon solar panel may be an integrated back contact solar panel. For example, the silicon solar panel can include electrical contacts configured to extract electricity from the panel that are positioned on the back of the silicon solar cells. FIG. 21 shows an example of a perovskite top module electrically connected to a shingled silicon solar module. The silicon solar panel may be a shingled solar panel. For example, a plurality of silicon solar cells can be stacked such that a back contact of one of the solar cells comes in contract with a front contact of an adjacent solar cell. In this example, the silicon solar cells can only partially overlap to provide a greater active area of the solar panel.

The arbitrary size of the perovskite solar cells may enable the arbitrary selection of the voltage output of the perovskite top module. For example, the perovskite solar cells can be formed such that the cells produce a predetermined voltage upon illumination. The perovskite solar cells can be configured to generate a total voltage that is substantially matched to the silicon solar module. For example, for a silicon solar cell with a 42 volt output, the perovskite solar cells can be configured to generate 44 volts. The perovskite top module may generate a voltage within at least about 5%, 10%, 20%, 30%, 40%, 50%, 60%, 70%, 80%, 90%, 99%, or more of the voltage of the silicon solar module. The perovskite top module may generate a voltage within at most about 99%, 90%, 80%, 70%, 60%, 50%, 40%, 30%, 20%, 10%, 5%, or less of the voltage of the silicon solar module. The matching or substation matching of the perovskite top module's voltage with the voltage of the silicon solar module can result in a voltage matched condition between the two modules. The voltage matched condition can produce a hybrid module with a higher current output than a hybrid module that is not voltage matched. The silicon solar panel and the perovskite solar panel may have a substantially similar area. For example, the perovskite layer can cover the entire silicon solar panel. In this example, the total power of the module can be maximized, as all of the area of available solar light is utilized. The perovskite solar panel may be at least about 5%, 10%, 20%, 30%, 40%, 50%, 60%, 70%, 80%, 90%, 99%, or more of the area of the silicon solar panel. The perovskite solar panel may be at most about 99%, 90%, 80%, 70%, 60%, 50%, 40%, 30%, 20%, 10%, 5%, or less of the area of the silicon solar panel.

### Perovskite Composition and Additives

The perovskite layer described herein may have a composition of MAₙ₁FAₙ₂Csₙ₃PbX₃, wherein MA is methylammonium and FA is formamidinium. n1, n2, and n3 may independently be greater than 0 and/or less than 1. n1+n2+n3 may equal 1. A perovskite solar cell including said perovskite layer may retain at least about 80% solar conversion efficiency after 300 hours of illumination under one sun conditions in an air atmosphere at 45° C. The perovskite layer may be used as described elsewhere herein (e.g., used as an absorbing layer for a perovskite photovoltaic).

In the above equation, X may be selected from the group consisting of fluorine, chlorine, bromine, and iodine. For example, X can be iodine. X may be a combination of two or more of fluorine, chlorine, bromine, and iodine. For example, X may be a mixture of chlorine and iodine. The combination may include individual components having a concentration of at least about 0.1, 0.5, 1, 2, 3, 4, 5, 6, 7, 8, 9, 10, 11, 12, 13, 14, 15, 20, 25, 30, 35, 40, 45, 50, 55, 60, 65, 70, 75, 80, 85, 90, 95, 96, 97, 98, 99, or more percent. The combination may include individual components having a concentration of at most about 99, 98, 97, 96, 95, 90, 85, 80, 75, 70, 65, 60, 55, 50, 45, 40, 35, 30, 25, 20, 15, 14, 13, 12, 11, 10, 9, 8, 7, 6, 5, 4, 3, 2, 1, 0.5, 0.1 or less percent. For example, the combination may be a mixture of about 1% chlorine and 99% iodine. The combination may include individual components having a concentration in a range as defined by any two of the previous values. For example, the combination can be a mixture of about 1%-5% bromine and about 95%-99% iodine.

In the proceeding formula, n1, n2, and n3 may individually be greater than at least about 0.0001, 0.0005, 0.001, 0.005, 0.01, 0.05, 0.1, 0.11, 0.12, 0.13, 0.14, 0.15, 0.2, 0.25, 0.3, 0.35, 0.4, 0.45, 0.5, 0.55, 0.6, 0.65, 0.7, 0.75, 0.8, 0.85, 0.9, 0.95, 0.96, 0.97, 0.98, 0.99, or more. In the proceeding formula, n1, n2, and n3 may individually be less than at most about 0.99, 0.98, 0.97, 0.96, 0.95, 0.9, 0.85, 0.8, 0.75, 0.7, 0.65, 0.6, 0.55, 0.5, 0.45, 0.4, 0.35, 0.3, 0.25, 0.2, 0.15, 0.14, 0.13, 0.12, 0.11, 0.1, 0.9, 0.8, 0.7, 0.6, 0.5, 0.4, 0.3, 0.2, 0.1, 0.05, 0.01, 0.005, 0.001, 0.0005, 0.0001, or less. In the proceeding formula, n1, n2, and n3 may individually have a range as defined by any two of the proceeding values. For example, n1 can be about 0.001 to about 0.05, n2 can be about 0.8 to about 0.989, and n3 can be about 0.01 to about 0.15.

The cations of the formula may be as described above (e.g., methylammonium, formamidinium, cesium, butylammonium). Examples of other cations that may be used include, but are not limited to, imidazolium, dimethylammonium, guanidinium, ammonium, methylformamidinium, tetramethylammonium, trimethylammonium, rubidium, copper, palladium, platinum, silver, gold, rhodium, ruthenium, sodium, potassium, iron, other inorganic cations, other organic cations, or the like, or any combination thereof. The perovskite layer may not include additional additives. For example, the perovskite layer may not include thiocyanate. In another example, the perovskite layer may not include carbamides. The perovskite layer may be configured to provide high performance and longevity without additional additives. The lack of additional additives may provide lower cost and easier manufacturing of the perovskite layer. The inclusion of the cesium cation (or an equivalent alternate cation) may improve the thermal stability of the perovskite layer. For example, the presence of cesium can increase the strength of the molecular bonds of the lead halide structure of the perovskite layer. The cesium ions may also have a lower vapor pressure than organic ions, which may contribute to the thermal stability of the perovskite layer. The inclusion of formamidinium may be more resilient to high temperatures due to their increased molecular weight as compared to other organic cations (e.g., methylammonium). Due to a possible intrinsic instability of a pure formamidinium perovskite, including cesium and/or methylammonium cations can improve the crystalline stability while maintaining thermal stability. Adding too many light organic cations (e.g., methylammonium) can reduce thermal stability. Adding a small percentage of butylammonium iodide can improve the quality of the perovskite layer due to the larger molecular structure of butylammonium being better able to fill the gaps in the perovskite crystalline structure to better passivate defects or imperfects within the crystal, which can in turn achieve higher quality or performance perovskite layers.

The perovskite solar cell may be a perovskite solar cell as described elsewhere herein. For example, the perovskite solar cell may be a solar cell formed on a top glass of a silicon solar cell. The perovskite layer may retain at least about 10, 11, 12, 13, 14, 15, 20, 25, 30, 35, 40, 45, 50, 55, 60, 65, 70, 75, 80, 85, 90, 95, 99, or more percent of the initial conversion efficiency value after 300 hours of illumination under one sun conditions in an air atmosphere at >25° C. and <100° C. The perovskite layer may retain at most about 99, 95, 90, 85, 80, 75, 70, 65, 60, 55, 50, 45, 40, 35, 30, 25, 20, 15, 14, 13, 12, 11, 10, or less percent of the initial conversion efficiency value after 300 hours of illumination under one sun conditions in an air atmosphere at >25° C. and <100° C. The perovskite layer may retain a percent of the initial conversion efficiency value after 300 hours of illumination under one sun conditions in an air atmosphere at >25° C. and <100° C. as defined by any two of the proceeding values.

In another aspect, the present disclosure provides a method. The method includes providing a substrate. A perovskite precursor may be applied to the substrate. The perovskite precursor may be annealed to form a perovskite layer. The perovskite layer may include a composition of MAₙ₁FAₙ₂CSₙ₃PbX₃. MA may be methylammonium. FA may be formamidinium. n1, n2, and n3 may independently be greater than 0 and/or less than 1. n1+n2+n3 may equal 1. A perovskite solar cell including said perovskite layer may retain at least about 80% solar conversion efficiency after 300 hours of illumination under one sun conditions in an air atmosphere at >25° C. and <100° C. The perovskite layer may be subjected to an encapsulation lamination process at a temperature of at least about 120° C. The method may be as described elsewhere herein. For example, the method can be process 300 of FIG. 2.

The temperature of the encapsulation lamination process may be at least about 15, 20, 25, 30, 35, 40, 45, 50, 55, 60, 65, 70, 75, 80, 85, 90, 95, 100, 105, 110, 115, 120, 125, 130, 135, 140, 145, 150, 160, 170, 180, 190, 200, or more degrees Celsius. The temperature of the encapsulation lamination process may be at a temperature of at most about 200, 190, 180, 170, 160, 150, 145, 140, 135, 130, 125, 120, 115, 110, 105, 100, 95, 90, 85, 80, 75, 70, 65, 60, 55, 50, 45, 40, 35, 30, 25, 20, 15, or less degrees Celsius. The temperature of the encapsulation lamination process may be in a temperature range as defined by any two of the proceeding values. The encapsulation may be as described elsewhere herein (e.g., with respect to encapsulant 135 of FIG. 1).

The perovskite solar cell may be a perovskite solar cell as described elsewhere herein. For example, the perovskite solar cell can be a solar cell formed on a top glass of a silicon solar cell. The perovskite layer may retain at least about 10, 11, 12, 13, 14, 15, 20, 25, 30, 35, 40, 45, 50, 55, 60, 65, 70, 75, 80, 85, 90, 95, 99, or more percent of the initial conversion efficiency value after 300 hours of illumination under one sun conditions in an air atmosphere at >25° C. and <100° C. The perovskite layer may retain at most about 99, 95, 90, 85, 80, 75, 70, 65, 60, 55, 50, 45, 40, 35, 30, 25, 20, 15, 14, 13, 12, 11, 10, or less percent of the initial conversion efficiency value after 300 hours of illumination under one sun conditions in an air atmosphere at >25° C. and <100° C. The perovskite layer may retain a percent of the initial conversion efficiency value after 300 hours of illumination under one sun conditions in an air atmosphere at >25° C. and <100° C. as defined by any two of the proceeding values. The perovskite layer may retain at least about 10, 11, 12, 13, 14, 15, 20, 25, 30, 35, 40, 45, 50, 55, 60, 65, 70, 75, 80, 85, 90, 95, 96, 97, 98, 99, or more percent of the initial conversion efficiency value after the encapsulation lamination process. The perovskite layer may retain at most about 99, 98, 97, 96, 95, 90, 85, 80, 75, 70, 65, 60, 55, 50, 45, 40, 35, 30, 25, 20, 15, 14, 13, 12, 11, 10, or less percent of the initial conversion efficiency value after the encapsulation lamination process. The perovskite layer may retain an efficiency of the initial conversion efficiency value after the encapsulation lamination process as defined by any two of the proceeding values.

The perovskite precursor may be applied as described elsewhere herein. For example, the perovskite precursor can be applied using an ultrasonic spray-on process. In this example, the precursors can be applied in different spray-on operations (e.g., lead (II) iodide can be applied to a substrate, and methylammonium iodide can be applied to the lead iodide). In another example, the perovskite precursors can be applied in a single operation. In this example, a solution including all of the precursors for the perovskite layer can be applied and annealed to form the perovskite layer. The annealing process may include heating the perovskite layer to at least about 15, 20, 25, 30, 35, 40, 45, 50, 55, 60, 65, 70, 75, 80, 85, 90, 95, 100, 105, 110, 115, 120, 125, 130, 135, 140, 145, 150, 160, 170, 180, 190, 200, or more degrees Celsius. The annealing process may include heating the perovskite layer to at most about 200, 190, 180, 170, 160, 150, 145, 140, 135, 130, 125, 120, 115, 110, 105, 100, 95, 90, 85, 80, 75, 70, 65, 60, 55, 50, 45, 40, 35, 30, 25, 20, 15, or less degrees Celsius. The annealing process may include heating the perovskite layer to a temperature range as defined by any two of the proceeding values.

The perovskite layer described herein can include a composition of MAₙ₁FAₙ₂CSₙ₃PbX₃, wherein MA is methylammonium and FA is formamidinium. n1 may be of a value from about 0.01 to 0.03. n2 may be of a value from about 0.82 to 0.94. n3 may be of a value from about 0.05 to 0.015. n1+n2+n3 may equal one. X can be iodine, bromine, or another halide.

### EXAMPLES

The following examples are illustrative of certain systems and methods described herein and are not intended to be limiting.

### Example 1—Preparation of a Perovskite Photovoltaic Cell Using a QUASAR

An incoming glass substrate is coated with a transparent conducting oxide followed by nickel (II) oxide in a pair of physical vapor deposition processes to generate a substrate including a transparent conductive layer and a hole transport layer. The transparent conducting oxide and nickel oxide is then laser scribed to generate templates of individual photovoltaic cells.

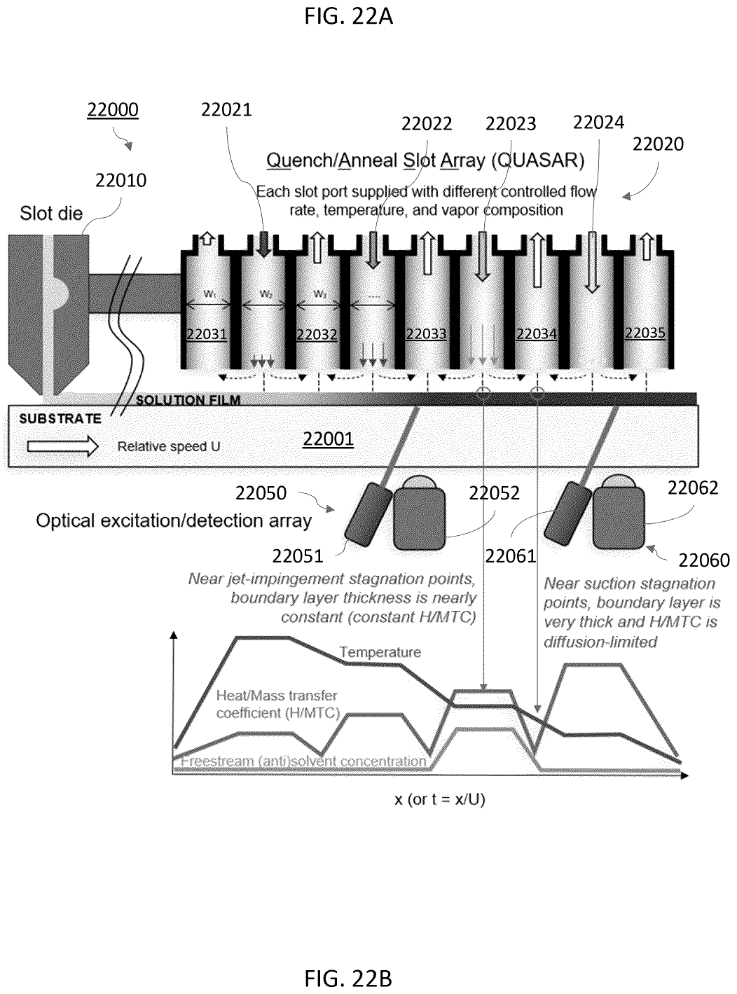

Subsequently, referring to FIG. 22A, a layer of a perovskite is formed on the substrate 22001 using a station 22000 composed of a slot die coater 22010 and a quench/anneal slot array (QUASAR) 22020. The QUASAR includes four gas slots 22021-22024 alternating with five suction channels 22031-22035. An optical monitoring module composed of optical excitation detection arrays 22050 and 22060 monitor the film from the opposite side of the substrate from QUASAR 22020. Each array includes a light source (22051, 22061) and a detector (22052, 22062) that detects light reflected from the film formed on the substrate.

During the coating and drying process, the substrate 22001 moves relative to the slot die 22010 and QUASAR 22020 at a relative velocity U. Lead (II) iodide and methylammonium iodide in a solution of dimethylformamide and dimethyl sulfoxide is applied to the hole transport layer via a slot die coating process using a slot die 22010. Using QUASAR 22020, the lead (II) iodide and the methylammonium iodide is annealed to permit reaction of the two perovskite precursors and evaporation of the solvents, thus forming a methylammonium lead iodide perovskite layer.

The suction pressure increases sequentially for each subsequent suction channel 22031-22035 and the temperature of the gas decreases for each subsequent slot jet 22021-22024. This is illustrated in FIG. 22B, which shows a plot of gas temperature, mass transfer coefficient, and anti-solvent concentration is the gas from the slot jets as a function of substrate position (or, equivalently, time). Anti-solvent is supplied in from the gas emitted by slot jet 22023. The mass transfer coefficient increases beneath each subsequent slot jet to a maximum beneath the last slot jet 22024.

To the newly formed perovskite layer, a phenyl-C61-butyric acid methyl ester (PCBM) hole transport layer is applied in a solution of dichlorobenzene by an ultrasonic spray process followed by drying. The hole transport layer is then laser scribed along the same pattern as the nickel oxide.

Subsequently, a second transparent conducting layer of IZTO is applied via physical vapor deposition, followed by application of silver electrodes by a similar physical vapor deposition process or in another embodiment, an attachment of charge collection tape directly to the IZTO layer can be done. The electrodes are cut via laser scribe to form the electrode assembly, and the individual photovoltaic cells are isolated from one another by laser scribe.

Subsequently, the as formed photovoltaic cells is investigated via various metrology techniques such as, for example, scanning electron microscopy (SEM), optical absorption/transmission, x-ray diffraction, atomic force microscopy, ellipsometry, electroluminescence spectroscopy, photoluminescence spectroscopy, time resolved optical spectroscopy, or the like, or any combination thereof.

After application of the second transparent conducting layer, an encapsulant is applied to the back of the photovoltaic cell. The encapsulant is applied prior to the isolation of the photovoltaic cells by laser scribe. A first encapsulant, such as a thermoplastic polyolefin, is applied across the back of the photovoltaic cell while a second encapsulant, such as butyl rubber, is applied to the edges of the photovoltaic cell. The back encapsulant can be optically transparent, while the side encapsulant can be optically transparent or opaque. For example, in certain cases, a higher quality (e.g., lower moisture and gas permeability) encapsulant is placed on the sides of the photovoltaic cell even though it is not optically transparent because the side of the cell does not absorb light, while the encapsulant for the back of the cell is transparent to allow light to pass through to a bottom junction.

### Example 2—Inline Generation of Perovskite Photovoltaic

In another example, a formulation composed of lead halide, methylammonium, formamidinium in a solution of dimethyl sulfoxide and methyl-2-pyrrolidinone (NMP) is applied as a single formulation via a 1-step ultrasonic spray process, following by a gas slot drying process step via applying a low vapor pressure chemical like diethyl ether chemical, before annealing. Within the annealing oven, the substrate is heated to form a perovskite layer with predetermined characteristics (e.g., grain size, thickness, elemental distribution, etc.). The annealing oven may be in line with the conveyor belt (e.g., the conveyor belt moves through the oven to perform the annealing). The annealing oven may be a batch annealing oven (e.g., multiple substrates can be loaded into the oven to be annealed at the same time). The type of annealing oven may be determined by the cycle time of the oven as compared to the anneal duration.

After formation of the perovskite layer, the substrate passes through another set of ultrasonic spray-on nozzles for application of the electron transport layer to the perovskite layer. A second transparent conductive layer is applied via physical vapor deposition to the electron transport layer, electrodes are applied via physical vapor deposition, and the individual photovoltaic cells are isolated via laser scribe. The entire inline process takes places on a single conveyor belt.

FIGS. 18-21 show examples of different electrical network connections for different types of silicon-perovskite hybrid solar modules. The detail inserts illustrate the electrical connectivity of example silicon-perovskite hybrid solar modules. The leads from the perovskite solar module can be connected to the leads of the silicon solar module. For example, the perovskite solar module can include multiple strips of perovskite solar cells connected in series. The silicon solar cells can be connected in a similar way. This can result in two leads coming from the silicon solar module and two leads coming from the perovskite solar module. These leads can then be connected together and to a junction box for transfer of the power out of the solar module. Such a scheme of connecting a silicon solar module and perovskite solar module to form a hybrid solar module can work for any geometry of silicon and perovskite solar cells. For example, the silicon module can include front contact silicon solar cells, integrated back contact silicon solar cells, shingled silicon solar cells, etc. In another example, the perovskite solar cells can be strip solar cells, tiled solar cells, front contact solar cells, etc. The perovskite solar cells may include a plurality of cells including a plurality of strips of perovskite solar cells connected in series. For example, a plurality of cells each including a plurality of strips of perovskite solar cells can be connected in parallel in a voltage matching scheme.

In an example of a hybrid module, a six by ten array of silicon solar cells was electrically connected in series to form a silicon solar module with an open circuit voltage of 0.7 V×60=42 V. A perovskite layer was cut via laser scribe to form 40 strip solar cells. Each strip was about 20 mm wide by 300 mm long. The 40 strips were connected in series. Each strip had an open circuit voltage of 1.1 V, and the 40 series-connected strip may have a total voltage of 1.1 V×40=44V. To achieve full coverage of the silicon solar panel, five units of the 40 strip solar cells can be tiled on the same glass sheet. The units can in turn be connected in parallel to maintain the voltage matching condition. This can result in a substantially voltage matched hybrid module.

### Example 3—Scalable Manufacturing Methods for Perovskite Solar Cells

A spray on precursor solution including lead (II) halides, methylammonium iodide, cesium, formamidinium iodide, dimethylformamide, dimethylsulfoxide, and N-methyl-2-pyrrolidone is formed as described elsewhere herein. For example, the precursors or salts thereof are mixed together, stirred, and slightly heated to improve homogeneity. The resultant precursor solution is applied to a substrate via an ultrasonic spray-on process. The substrate with the precursor layer is then soaked in an antisolvent to form the perovskite layer. Examples of soaking include substrate dipping into the antisolvent, mechanical spraying of the antisolvent, chemical showering of the antisolvent, or the like, or any combination thereof. A slow addition of the perovskite film to the antisolvent may be effective in reducing defects in the film and residue left on the film. For example, a back and forth movement of the film during addition to an antisolvent bath can produce defects at the contact line between the film and the antisolvent. The substrates can be slowly introduced to the solvent bath to avoid such defects. Alternatively, a controlled pour rinse followed by a gas slot dry can produce a high quality perovskite film.

Examples of antisolvent include, but are not limited to, diethyl ether, dibutyl ether, chlorobenzene, chloroform, or the like, or any combination thereof. Selection of the antisolvent may depend on miscibility of the antisolvent with the solvent (e.g., the solvent and antisolvent can be miscible), solubility of the perovskite in the antisolvent (e.g., the antisolvent may not effectively dissolve the perovskite), and the like. The quick removal of the solvent by way of the antisolvent may be important to the overall quality of the film. For example, if the antisolvent does not fully remove the solvent, an impenetrable skin can form on the top of the layer and inhibit further solvent removal. In another example, the quick removal of the solvent can result in a high quality film. The effluent from the soak can be recovered, refreshed (e.g., by removing solid particles), and reused for production of the next perovskite layer.

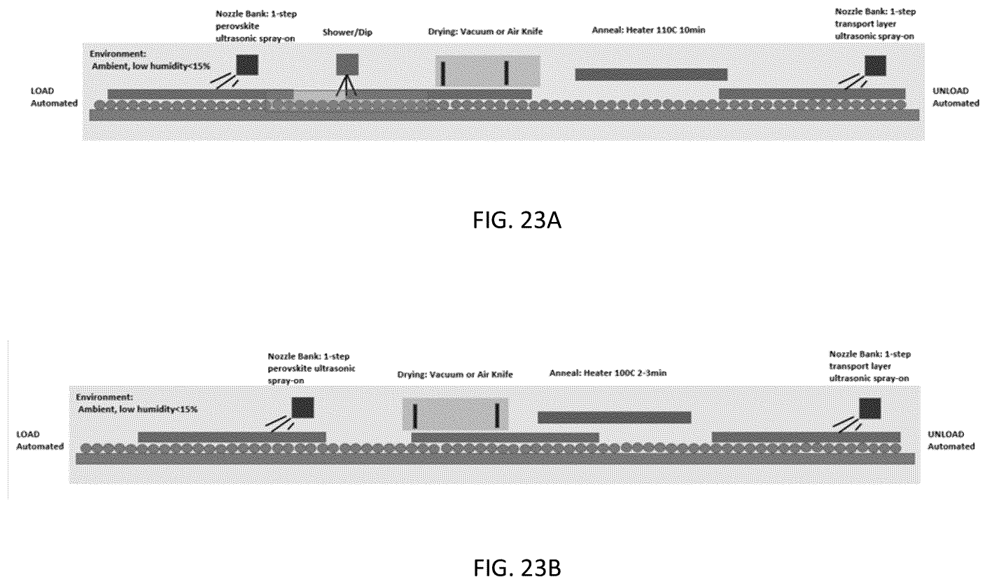

The perovskite layer is subsequently annealed as described elsewhere herein. For example, the perovskite layer can be annealed at a temperature between 90° C. and 110° C. for 5-15 minutes, and subsequently annealed at 110° C. for 10 minutes. FIG. 23A is an example of an apparatus for generating a perovskite layer including use of an antisolvent.

An antisolvent free method of preparing perovskite layers may include utilization of a precursor solution including lead (II) acetate, lead (II) halide, methylammonium halide, and dimethylformamide. Such a solution may not use application of an antisolvent to form the perovskite layer. For example, the solution can be applied to a substrate and allowed to dry for 5-15 minutes at room temperature to form the perovskite layer. The perovskite layer may be subsequently annealed as described elsewhere herein. FIG. 23B is an example of an apparatus for generating a perovskite layer without use of an antisolvent.

Such methods may be scalable due to a combination of facile atmospheric controls (e.g., ambient conditions with low humidity), one-operation perovskite spray-on formulations, scalable drying processes (e.g., vacuum, air-knife, etc.), scalable annealing processes, and scalable electron transport layer addition (e.g., ultrasonic spray-on formulations and apparatuses)

### Computer Systems

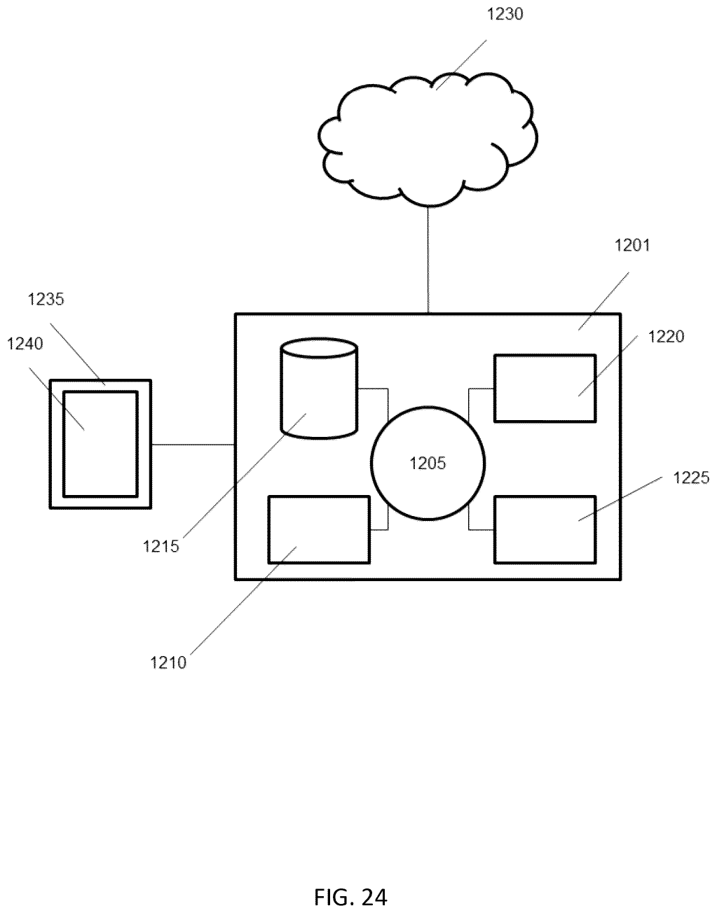

The present disclosure provides computer systems that are programmed to implement methods of the disclosure, e.g., to control the gas slot module during the crystallization process. FIG. 24 shows a computer system 1201 that is programmed or otherwise configured to direct the fabrication and manufacturing processes described herein (e.g., physical vapor deposition, ultrasonic spray-on, etc.) or control power electronics connected to the solar modules described herein.

The computer system 1201 includes a central processing unit (CPU, also “processor” and “computer processor” herein) 1205, which can be a single core or multi core processor, or a plurality of processors for parallel processing. The computer system 1201 also includes memory or memory location 1210 (e.g., random-access memory, read-only memory, flash memory), electronic storage unit 1215 (e.g., hard disk), communication interface 1220 (e.g., network adapter) for communicating with one or more other systems, and peripheral devices 1225, such as cache, other memory, data storage and/or electronic display adapters. The memory 1210, storage unit 1215, interface 1220 and peripheral devices 1225 are in communication with the CPU 1205 through a communication bus (solid lines), such as a motherboard. The storage unit 1215 can be a data storage unit (or data repository) for storing data. The computer system 1201 can be operatively coupled to a computer network (“network”) 1230 with the aid of the communication interface 1220. The network 1230 can be the Internet, an internet and/or extranet, or an intranet and/or extranet that is in communication with the Internet. The network 1230 in some cases is a telecommunication and/or data network. The network 1230 can include one or more computer servers, which can enable distributed computing, such as cloud computing. The network 1230, in some cases with the aid of the computer system 1201, can implement a peer-to-peer network, which may enable devices coupled to the computer system 1201 to behave as a client or a server.

The CPU 1205 can execute a sequence of machine-readable instructions, which can be embodied in a program or software. The instructions may be stored in a memory location, such as the memory 1210. The instructions can be directed to the CPU 1205, which can subsequently program or otherwise configure the CPU 1205 to implement methods of the present disclosure. Examples of operations performed by the CPU 1205 can include fetch, decode, execute, and writeback.

The CPU 1205 can be part of a circuit, such as an integrated circuit. One or more other components of the system 1201 can be included in the circuit. In some cases, the circuit is an application specific integrated circuit (ASIC).

The storage unit 1215 can store files, such as drivers, libraries and saved programs. The storage unit 1215 can store user data, e.g., user preferences and user programs. The computer system 1201 in some cases can include one or more additional data storage units that are external to the computer system 1201, such as located on a remote server that is in communication with the computer system 1201 through an intranet or the Internet.

The computer system 1201 can communicate with one or more remote computer systems through the network 1230. For instance, the computer system 1201 can communicate with a remote computer system of a user. Examples of remote computer systems include personal computers (e.g., portable PC), slate or tablet PC's (e.g., Apple® iPad, Samsung® Galaxy Tab), telephones, Smart phones (e.g., Apple® iphone, Android-enabled device, Blackberry®), or personal digital assistants. The user can access the computer system 1201 via the network 1230.

Methods as described herein can be implemented by way of machine (e.g., computer processor) executable code stored on an electronic storage location of the computer system 1201, such as, for example, on the memory 1210 or electronic storage unit 1215. The machine executable or machine-readable code can be provided in the form of software. During use, the code can be executed by the processor 1205. In some cases, the code can be retrieved from the storage unit 1215 and stored on the memory 1210 for ready access by the processor 1205. In some situations, the electronic storage unit 1215 can be precluded, and machine-executable instructions are stored on memory 1210.

The code can be pre-compiled and configured for use with a machine having a processer adapted to execute the code or can be compiled during runtime. The code can be supplied in a programming language that can be selected to enable the code to execute in a pre-compiled or as-compiled fashion.

Aspects of the systems and methods provided herein, such as the computer system 1201, can be embodied in programming. Various aspects of the technology may be thought of as “products” or “articles of manufacture” typically in the form of machine (or processor) executable code and/or associated data that is carried on or embodied in a type of machine readable medium. Machine-executable code can be stored on an electronic storage unit, such as memory (e.g., read-only memory, random-access memory, flash memory) or a hard disk. “Storage” type media can include any or all of the tangible memory of the computers, processors or the like, or associated modules thereof, such as various semiconductor memories, tape drives, disk drives and the like, which may provide non-transitory storage at any time for the software programming. All or portions of the software may at times be communicated through the Internet or various other telecommunication networks. Such communications, for example, may enable loading of the software from one computer or processor into another, for example, from a management server or host computer into the computer platform of an application server. Thus, another type of media that may bear the software elements includes optical, electrical and electromagnetic waves, such as used across physical interfaces between local devices, through wired and optical landline networks and over various air-links. The physical elements that carry such waves, such as wired or wireless links, optical links or the like, also may be considered as media bearing the software. As used herein, unless restricted to non-transitory, tangible “storage” media, terms such as computer or machine “readable medium” refer to any medium that participates in providing instructions to a processor for execution.

Hence, a machine readable medium, such as computer-executable code, may take many forms, including but not limited to, a tangible storage medium, a carrier wave medium or physical transmission medium. Non-volatile storage media include, for example, optical or magnetic disks, such as any of the storage devices in any computer(s) or the like, such as may be used to implement the databases, etc. shown in the drawings. Volatile storage media include dynamic memory, such as main memory of such a computer platform. Tangible transmission media include coaxial cables; copper wire and fiber optics, including the wires that include a bus within a computer system. Carrier-wave transmission media may take the form of electric or electromagnetic signals, or acoustic or light waves such as those generated during radio frequency (RF) and infrared (IR) data communications. Common forms of computer-readable media therefore include for example: a floppy disk, a flexible disk, hard disk, magnetic tape, any other magnetic medium, a CD-ROM, DVD or DVD-ROM, any other optical medium, punch cards paper tape, any other physical storage medium with patterns of holes, a RAM, a ROM, a PROM and EPROM, a FLASH-EPROM, any other memory chip or cartridge, a carrier wave transporting data or instructions, cables or links transporting such a carrier wave, or any other medium from which a computer may read programming code and/or data. Many of these forms of computer readable media may be involved in carrying one or more sequences of one or more instructions to a processor for execution.

The computer system 1201 can include or be in communication with an electronic display 1235 that includes a user interface (UI) 1240 for providing, for example, control over fabrication process parameter. Examples of UI's include, without limitation, a graphical user interface

(GUI) and web-based user interface.

Methods and systems of the present disclosure can be implemented by way of one or more algorithms. An algorithm can be implemented by way of software upon execution by the central processing unit 1205.

Various embodiments of the invention are described in the following numbered paragraphs.
1. A method for forming a layer of a perovskite material on a substrate, the method including: depositing a layer of a solution onto a surface of the substrate, the solution including a solvent and a perovskite precursor; after depositing the layer of solution, moving the substrate in a downstream direction relative to a gas slot; while causing relative movement between the substrate and the gas slot, blowing a curtain of gas towards the surface of the layer of the solution using the gas slot to provide conditions sufficient to facilitate mass transfer of the solvent from the layer of solution in a zone to crystallize a perovskite material from the perovskite precursor to form the layer of the perovskite downstream from the gas slot, wherein the gas slot is configured so that entrained or emitted gas flow upstream of the gas slot (at the undried upstream film) is at least twice as low (e.g., 3× or more lower, 4× or more lower, 5× or more lower, 10× or more lower, 20× or more lower) as entrained gas flow downstream from the gas slot.
2. A method for forming a layer of a crystalline material on a substrate, the method including: depositing a layer of a solution onto a surface of the substrate, the solution including a solvent and a precursor; after depositing the layer of solution, moving the substrate in a downstream direction relative to a gas slot; while causing relative movement between the substrate and the gas slot, blowing a curtain of gas towards the surface of the layer of the solution using the gas slot to provide conditions sufficient to facilitate mass transfer of the solvent from the layer of solution in a zone to crystallize the crystalline material from the precursor to form the layer of the crystalline material downstream from the gas slot, wherein the gas slot is configured so that entrained or emitted gas flow upstream of the gas slot (at the undried upstream film) is at least twice as low (e.g., 3× or more lower, 4× or more lower, 5× or more lower, 10× or more lower, 20× or more lower) as entrained gas flow downstream from the gas slot.
3. A method for forming a layer of a perovskite material on a substrate, the method including: depositing a layer of a solution onto a surface of the substrate, the solution including a solvent and a perovskite precursor; after depositing the layer of solution, moving the substrate in a downstream direction relative to a plurality of gas slots; while causing relative movement between the substrate and the gas slots, blowing curtains of gas towards the surface of the layer of the solution using the gas slots to provide conditions sufficient to facilitate mass transfer of the solvent from the layer of solution in a zone to crystallize a perovskite material from the perovskite precursor to form the layer of the perovskite downstream from the gas slot.
4. A method for forming a layer of a crystalline material on a substrate, the method including: depositing a layer of a solution onto a surface of the substrate, the solution including a solvent and a precursor; after depositing the layer of solution, moving the substrate in a downstream direction relative to a plurality of gas slots; while causing relative movement between the substrate and the gas slots, blowing curtains of gas towards the surface of the layer of the solution using the gas slots to provide conditions sufficient to facilitate mass transfer of the solvent from the layer of solution in a zone to crystallize the crystalline material from the precursor to form the layer of the crystalline material downstream from the gas slot.
5. A method for forming a layer of a perovskite material on a substrate, the method including: depositing a layer of a solution onto a surface of the substrate, the solution including a solvent and a perovskite precursor; after depositing the layer of solution, moving the substrate in a downstream direction relative to a gas slot and a suction channel adjacent the gas slot; while causing relative movement between the substrate and the gas slots, blowing a curtain of gas towards the surface of the layer of the solution using the gas slot and removing gas adjacent the surface to provide conditions sufficient to facilitate mass transfer of the solvent from the layer of solution in a zone to crystallize a perovskite material from the perovskite precursor to form the layer of the perovskite downstream from the gas slot.
6. A method for forming a layer of a crystalline material on a substrate, the method including: depositing a layer of a solution onto a surface of the substrate, the solution including a solvent and a precursor; after depositing the layer of solution, moving the substrate in a downstream direction relative to a gas slot and a suction channel adjacent the gas slot; while causing relative movement between the substrate and the gas slots, blowing a curtain of gas towards the surface of the layer of the solution using the gas slot and removing gas adjacent the surface to provide conditions sufficient to facilitate mass transfer of the solvent from the layer of solution in a zone to crystallize the crystalline material from the precursor to form the layer of the crystalline material downstream from the gas slot.
7. The method of any one of the preceding paragraphs, including providing a gap plate adjacent to and upstream from the gas slot to reduce gas flow upstream towards the layer of solution upstream from the gas slot, the channel having a thickness of 1 cm or less.
8. The method of any one of the preceding paragraphs, including providing one or more baffles adjacent to and upstream from the gas slot to cause turbulent flow of entrained gas proximate to the gas slot at the surface of the layer of solution.
9. The method of any one of the preceding paragraphs, further including applying a vacuum proximate to the gas slot.
10. The method of paragraph 9, wherein the vacuum is applied upstream from the gas slot.
11. The method of paragraph 9, wherein the vacuum is applied downstream from the gas slot.
12. The method of paragraph 9, wherein the vacuum is applied both upstream and downstream from the gas slot.
13. The method of paragraph 9, where the gas flow rate to the vacuum is within 50% (e.g., within 20%, within 10%, within 5%) of the gas flow rate to the gas slot
14. The method of any one of the previous paragraphs, wherein the gas slot is a first gas slot, and the method further includes blowing one or more additional curtains of gas towards the surface of the layer from one or more additional gas slots downstream from the first gas slot.
15. The method of paragraph 14, wherein the curtain of gas from the first gas slot has a temperature different from the curtain of gas from at least one of the one or more additional gas slots.
16. The method of paragraph 15, wherein the curtain of gas from the first gas slot is cooler than the curtain of gas from the at least one additional gas slots.
17. The method of paragraph 15, wherein the first gas slot is tilted in a different orientation relative to the substrate relative to the one or more additional gas slots.
18. The method of paragraph 15, further including at least one vacuum channel arranged between two of the plurality of gas slots.
19. The method of paragraph 14, wherein a gas composition from the first gas slot is different from a gas composition from the second gas slot.
20. The method of paragraph 14, wherein a gas pressure from the first slot is different from a gas pressure from the second gas slot.
21. The method of any one of the previous paragraphs, wherein a gas composition from at least one gas slot includes a solvent for the precursor.
22. The method of any one of the previous paragraphs, wherein a gas composition from at least one gas slot includes an anti-solvent for the precursor.
23. The method of any one of the previous paragraphs, further including optically monitoring the layer of the solution and/or layer of perovskite while blowing the curtain of gas.
24. The method of paragraph 23, wherein the optically monitoring includes directing light to the substrate from an opposite side of the substrate from the layer of the solution and monitoring light reflected or transmitted from the monitored layer.
25. The method of any one of the previous paragraphs, wherein the gas includes air, nitrogen, and/or argon.
26. The method of any one of the previous paragraphs, further including heating the substrate while blowing the curtain of gas.
27. The method of any one of the previous paragraphs, wherein substrate includes a substrate layer supporting a first electrically conducting layer and a hole transport layer.
28. The method of paragraph 27, wherein the surface of the substrate is a surface of the hole transport layer.
29. The method of paragraph 27, wherein the substrate layer is a glass layer.
30. The method of any one of the previous paragraphs, wherein the perovskite layer includes a compound having the chemical formula MAₙ₁FAₙ₂CSₙ₃PbX₃, wherein MA is methylammonium, FA is formamidinium, X is selected from the group consisting of fluorine, chlorine, bromine, and iodine, n1, n2, and n3 are independently greater than 0 and less than 1, and n1+n2+n3=1.
31. The method of paragraph 30, wherein n1 is from about 0.001 to 0.99, n2 is from about 0.001 to 0.99, and n3 is from about 0.005 to 0.5.
32. The method of paragraph 30, wherein the perovskite layer includes CH₃NH³PbX₃ or H₂NCHNH₂PbX₃.
33. A system, including: a platen for supporting a substrate; a coating module for coating a layer of a solution including a precursor and a solvent onto the substrate; a drying module including a gas slot, the drying module being position relative to the platen to deliver a curtain of gas to the layer of the solution during operation of the system; and an electronic controller arranged to control relative motion between the gas slot and the platen during operation of the system to provide conditions sufficient to facilitate mass transfer of the solvent from the layer of solution in a zone to crystallize a material from the precursor to form a layer of crystalline material downstream from the gas slot, wherein the drying module is configured so that entrained gas flow upstream of the gas slot is lower than entrained gas flow downstream from the gas slot.
34. A system, including: a platen for supporting a substrate; a coating module for coating a layer of a solution including a precursor and a solvent onto the substrate; a drying module including a plurality of gas slots, the drying module being position relative to the platen to deliver a curtain of gas to the layer of the solution during operation of the system; and an electronic controller arranged to control relative motion between the gas slots and the platen during operation of the system to provide conditions sufficient to facilitate mass transfer of the solvent from the layer of solution in a zone to crystallize a material from the precursor to form a layer of crystalline material downstream from the gas slot.
35. A system, including: a platen for supporting a substrate; a coating module for coating a layer of a solution including a precursor and a solvent onto the substrate; a drying module including a gas slot and a suction channel adjacent the gas slot, the drying module being position relative to the platen to deliver a curtain of gas to the layer of the solution and remove gas from adjacent the surface of the layer during operation of the system; and an electronic controller arranged to control relative motion between the gas slot and the platen during operation of the system to provide conditions sufficient to facilitate mass transfer of the solvent from the layer of solution in a zone to crystallize a material from the precursor to form a layer of crystalline material downstream from the gas slot.
36. The system of any one of the previous system paragraphs, wherein the gas slot is titled with respect to the surface of the substrate.
37. The system of paragraph 36, wherein the gas slot is tilted so that the curtain of gas has a velocity component in the downstream direction.
38. The system of any one of the previous paragraphs, wherein the drying module includes a gap plate adjacent to and upstream from the gas slot, the gap plate forming a channel having a thickness of 1 cm or less between a lower surface of the gap plate and the substrate.
39. The system of paragraph 38, wherein the channel has a length in a range from 1 cm to 20 cm.
40. The system of any one of the previous system paragraphs, wherein the drying module includes one or more baffles adjacent to and upstream from the gas slot, the baffles being configured to cause turbulent flow of entrained gas proximate to the gas slot at the surface of the layer of solution.
41. The system of any one of the previous system paragraphs, wherein the drying module includes a plurality of gas slots.
42. The system of paragraph 41, wherein the electronic controller is programmed to vary a composition of gas from each of the gas slots, the composition for at least two of the gas slots being different.
43. The system of paragraph 41 or paragraph 42, wherein the electronic controller is programmed to vary a temperature of gas from each of the gas slots, the temperature for at least two of the gas slots being different.
44. The system of paragraphs 41, 42, or 43, wherein the electronic controller is programmed to vary a pressure of gas from each of the gas slots, the pressure for at least two of the gas slots being different.
45. The system of any one of the previous system paragraphs, wherein in the drying module includes one or more suction channels configured to apply a vacuum to proximate to the gas slot.
46. The system of paragraph 45, wherein the suction channels include at least one suction channel upstream from the gas slot.
47. The system of paragraph 45 or paragraph 46, wherein the suction channels include at least one suction channel downstream from the gas slot.
48. The system of paragraph 45, wherein the electronic controller is programmed to vary a vacuum pressure to each of the suction channels, the pressure for at least two of the suction channels being different.
49. The system of any one of the previous system paragraphs, further including an optical monitoring module configured to monitor light reflected and/or transmitted by the layer on the substrate while the layer is adjacent the drying module.
50. The system of paragraph 49, wherein the optical monitoring system includes a light source positioned on the same side of the substrate as the gas slot.
51. The system of paragraph 49 or paragraph 50, wherein the optical monitoring system includes a light source positioned on the opposite side of the substrate as the gas slot.
52. The system of any one of paragraphs 49-51, wherein the optical monitoring system includes a detector positioned on the same side of the substrate as the gas slot.
53. The system of any one of paragraphs 49-52, wherein the optical monitoring system includes a detector positioned on the opposite side of the substrate as the gas slot.
54. The system of any one of paragraphs 49-53, wherein the electronic controller is programmed to adjust one or more operational parameters of the system based on information from the optical monitoring module, the one or more operational parameters including a relative velocity of the drying module and the substrate, a temperature of a gas from the gas slot, a composition of gas from the gas slot, a pressure of gas from the gas slot, a vacuum pressure at a suction channel, an ambient temperature, an ambient pressure, and an ambient gas composition.

While certain embodiments have been shown and described herein, it will be obvious to those skilled in the art that such embodiments are provided by way of example only. It is not intended that the invention be limited by the specific examples provided within the specification. For example, while the forgoing examples feature formation of perovskite layers, the techniques described here can be used to form non-perovskite films too. For instance, balancing solvent evaporation and a chemical reaction/crystallization of a solute in a thin film coating of the solvent using the described techniques can be applied to other chemistries/crystal structures beyond perovskites.

While the invention has been described with reference to the aforementioned specification, the descriptions and illustrations of the embodiments herein are not meant to be construed in a limiting sense. Numerous variations, changes, and substitutions will now occur to those skilled in the art without departing from the invention. Furthermore, it shall be understood that all aspects of the invention are not limited to the specific depictions, configurations or relative proportions set forth herein which depend upon a variety of conditions and variables. It should be understood that various alternatives to the embodiments of the invention described herein may be employed in practicing the invention. It is therefore contemplated that the invention shall also cover any such alternatives, modifications, variations or equivalents. It is intended that the following claims define the scope of the invention and that methods and structures within the scope of these claims and their equivalents be covered thereby.

What is claimed is:

1. A method for forming a layer of a perovskite material on a substrate, the method comprising:
depositing a layer of a solution onto a surface of the substrate, the solution comprising a solvent and a perovskite precursor;
after depositing the layer of solution, moving the substrate in a downstream direction relative to a gas slot;
while causing relative movement between the substrate and the gas slot, blowing a curtain of gas towards the surface of the layer of the solution using the gas slot to provide conditions sufficient to facilitate mass transfer of the solvent from the layer of solution in a zone to crystallize a perovskite material from the perovskite precursor to form the layer of the perovskite downstream from the gas slot,
wherein the gas slot is configured so that entrained or emitted gas flow upstream of the gas slot is at least twice as low as entrained gas flow downstream from the gas slot.

2. The method of claim 1, comprising providing a gap plate adjacent to and upstream from the gas slot to reduce gas flow upstream towards the layer of solution upstream from the gas slot, the channel having a thickness of 1 cm or less.

3. The method of claim 1, comprising providing one or more baffles adjacent to and upstream from the gas slot to cause turbulent flow of entrained gas proximate to the gas slot at the surface of the layer of solution.

4. The method of claim 1, further comprising applying a vacuum proximate to the gas slot.

5. The method of claim 4, wherein the vacuum is applied upstream and/or downstream from the gas slot.

6. The method of claim 4, where the gas flow rate to the vacuum is within 50% of the gas flow rate to the gas slot.

7. The method of claim 1, wherein the gas slot is a first gas slot, and the method further comprises blowing one or more additional curtains of gas towards the surface of the layer from one or more additional gas slots downstream from the first gas slot.

8. The method of claim 7, wherein the curtain of gas from the first gas slot has a temperature different from the curtain of gas from at least one of the one or more additional gas slots.

9. The method of claim 8, wherein the curtain of gas from the first gas slot is cooler than the curtain of gas from the at least one additional gas slots.

10. The method of claim 8, wherein the first gas slot is tilted in a different orientation relative to the substrate relative to the one or more additional gas slots.

11. The method of claim 8, further comprising at least one vacuum channel arranged between two of the plurality of gas slots.

12. The method of claim 7, wherein a gas composition from the first gas slot is different from a gas composition from the second gas slot.

13. The method of claim 7, wherein a gas pressure from the first slot is different from a gas pressure from the second gas slot.

14. The method of claim 1, wherein a gas composition from at least one gas slot comprises a solvent for the precursor.

15. The method of claim 1, wherein a gas composition from at least one gas slot comprises an anti-solvent for the precursor.

16. The method of claim 1, further comprising optically monitoring the layer of the solution and/or layer of perovskite while blowing the curtain of gas.

17. The method of claim 16, wherein the optically monitoring comprises directing light to the substrate from an opposite side of the substrate from the layer of the solution and monitoring light reflected or transmitted from the monitored layer.

18. The method of claim 1, further comprising heating the substrate while blowing the curtain of gas.

19. The method of claim 1, wherein substrate comprises a substrate layer supporting a first electrically conducting layer and a hole transport layer, wherein the surface of the substrate is a surface of the hole transport layer.

20. A system, comprising:
a platen for supporting a substrate;
a coating module for coating a layer of a solution comprising a precursor and a solvent onto the substrate;
a drying module comprising a gas slot, the drying module being position relative to the platen to deliver a curtain of gas to the layer of the solution during operation of the system; and
an electronic controller arranged to control relative motion between the gas slot and the platen during operation of the system to provide conditions sufficient to facilitate mass transfer of the solvent from the layer of solution in a zone to crystallize a material from the precursor to form a layer of crystalline material downstream from the gas slot,
wherein the drying module is configured so that entrained gas flow upstream of the gas slot is lower than entrained gas flow downstream from the gas slot.
